(19) United States
(12) Patent Application Publication
(10) Pub. No.: US 2024/0292641 A1
(43) Pub. Date: Aug. 29, 2024

(54) SEMICONDUCTOR ELEMENT AND SEMICONDUCTOR DEVICE

(71) Applicants: SONY GROUP CORPORATION, Tokyo (JP); SONY SEMICONDUCTOR SOLUTIONS CORPORATION, Kanagawa (JP)

(72) Inventors: Yasuharu UJIIE, Kanagawa (JP); Yuki NEGISHI, Kanagawa (JP); Yosuke SAITO, Kanagawa (JP); Mari ICHIMURA, Tokyo (JP)

(21) Appl. No.: 18/567,612

(22) PCT Filed: Jun. 22, 2022
(86) PCT No.: PCT/JP2022/024919

§ 371 Date: Dec. 6, 2023

(30) Foreign Application Priority Data
Jun. 30, 2021 (JP) 2021-109551

(51) Int. Cl. H10K 50/11; H10K 30/60; H10K 50/15; H10K 85/20; H10K 85/30; H10K 85/60; H10K 101/40

(52) U.S. Cl. CPC H10K 50/11; H10K 30/60; H10K 50/15; H10K 85/211; H10K 85/346; H10K 85/622; H10K 85/633; H10K 85/654; H10K 85/6572; H10K 85/6576; H10K 85/658; H10K 2101/40

(57) ABSTRACT

A first semiconductor element according to an embodiment of the present disclosure includes: a first electrode; a second electrode disposed to be opposed the first electrode; and an organic semiconductor layer that is provided between the first electrode and the second electrode, and including an organic semiconductor material, the organic semiconductor material having a crystal density of greater than 1.26 g/cm³ and less than 1.50 g/cm³ in powder form by X-ray structure analysis, and a molecular weight of 1200 or less, and being available for vacuum deposition film formation.

### TECHNICAL FIELD

The present disclosure relates to a semiconductor element that uses an organic semiconductor, and a semiconductor device including the semiconductor element.

### BACKGROUND ART

Recently, electronic apparatuses each using an organic semiconductor in place of an inorganic semiconductor have been developed. For example, NPTL 1 and PTL 1 describe organic semiconductors each including a combination of fluorene and carbazole. These organic semiconductors are used for a hole injection layer or a hole transport layer of an organic electroluminescent element, and are known as materials that are superior in hole transportability. In addition, NPTL 2 and PTL 2 each disclose an organic TFT (thin film transistor) element using a benzodithiophene derivative.

### CITATION LIST

### Non-Patent Literature

NPTL 1: Molecular Crystals and Liquid Crystals (2006), 444, 185-190
NPTL 2: J. AM. CHEM. SOC. 2004. 126. 5084-5085

### PATENT LITERATURE

PTL 1: Specification of European Patent application publication No. 2881446
PTL 2: International Publication No. WO2007/125671

### SUMMARY OF THE INVENTION

Incidentally, in a case where various semiconductor elements are fabricated with use of organic semiconductors, a further improvement is desired depending on usage. For example, for a photoelectric conversion element (specifically, an imaging element), in addition to photoelectric conversion characteristics, dark-current characteristics and afterimage characteristics are important element characteristics. However, there is an issue that it is difficult to achieve the above-described element characteristics at a high level in a well-balanced manner in a case where an organic semiconductor is simply used. In addition, for a light-emitting element, characteristics in which light is emitted at a low voltage with high efficiency are important. Even in this case, it is difficult to achieve respective characteristics in a well-balanced manner.

It is desirable to provide a semiconductor element and a semiconductor device that have superior element characteristics.

A first semiconductor element according to an embodiment of the present disclosure includes: a first electrode; a second electrode disposed to be opposed the first electrode; and an organic semiconductor layer that is provided between the first electrode and the second electrode, and including an organic semiconductor material, the organic semiconductor material having a crystal density of greater than 1.26 g/cm³ and less than 1.50 g/cm³ in powder form by X-ray structure analysis, and a molecular weight of 1200 or less, and being available for vacuum deposition film formation.

A semiconductor device according to an embodiment of the present disclosure includes one or a plurality of semiconductor elements, and includes, as the one or plurality of semiconductor elements, the first semiconductor element according to the embodiment of the present disclosure described above.

A second semiconductor element according to an embodiment of the present disclosure includes: a first electrode; a second electrode disposed to be opposed the first electrode; and an organic semiconductor layer that is provided between the first electrode and the second electrode, and includes at least one of a benzodithiophene derivative represented by the following general formula (1) or a naphthodithiophene derivative represented by the following general formula (2).

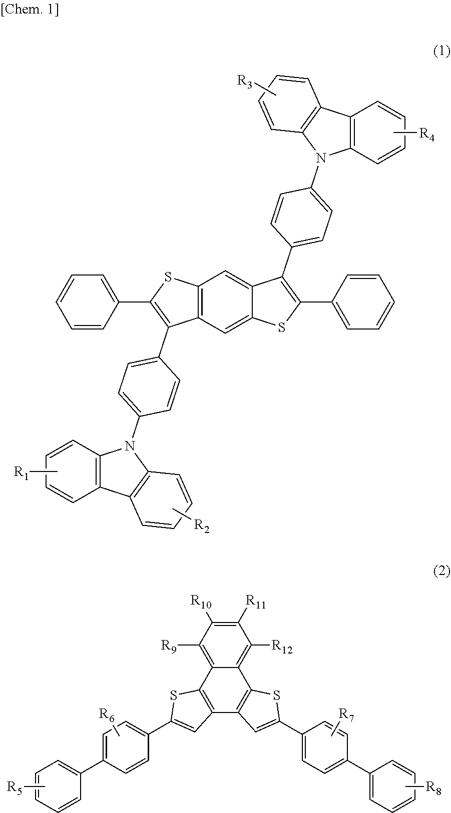

### R1 to R12 are each independently a hydrogen atom, a halogen atom, a straight-chain or branched alkyl group, a straight-chain or branched alkoxy group, an aryl group, an aryloxy group, a heteroaryl group, a heteroaryloxy group, or a derivative thereof, aryl sites of the aryl group and the aryloxy group are each one of a phenyl group, a biphenyl group, a naphthyl group, a naphthyl phenyl group, a phenyl naphthyl group, a tolyl group, a xylyl group, a terphenyl group, and a phenanthryl group that are unsubstituted or substituted by one of an alkyl group, a halogen atom, and a trifluoromethyl group; and heteroaryl sites of the heteroaryl group and the heteroaryloxy group are each one of a thienyl group, a thiazolyl group, an isothiazolyl group, a furanyl group, an oxazolyl group, an oxadiazolyl group, an isoxazolyl group, a benzothienyl group, a benzofuranyl group, a pyridinyl group, a quinolinyl group, an isoquinolyl group, an acridinyl group, an indole group, an imidazole group, a benzimidazol group, a carbazolyl group, a dibenzofuranyl group, and a dibenzothiophenyl group that are unsubstituted or substituted by one of an alkyl group, a halogen atom, and a trifluoromethyl group.)

In the first semiconductor element according to the embodiment of the present disclosure and the semiconductor device according to the embodiment of the present disclosure, the organic semiconductor layer includes the organic semiconductor material is formed. The organic semiconductor material has a crystal density of greater than 1.26 g/cm³ and less than 1.50 g/cm³ in powder form by X-ray structure analysis, and a molecular weight is 1200 or less, and is available for vacuum deposition film formation. In the second semiconductor element according to the embodiment of the present disclosure, as the organic semiconductor material provided between the first electrode and the second electrode, at least one of the benzodithiophene derivative represented by the above-described general formula (1) or the naphthodithiophene derivative represented by the above-described general formula (2) is used. Thus, the organic semiconductor layer having moderate intermolecular interaction is formed.

### BRIEF DESCRIPTION OF DRAWINGS

FIG. 1 is a schematic cross-sectional view of an example of a configuration of a photoelectric conversion element according to a first embodiment of the present disclosure.

FIG. 2 is a diagram illustrating an example of energy levels of materials included in respective layers of the photoelectric conversion element illustrated in FIG. 1.

FIG. 3 is a diagram describing carrier transfer occurring in the photoelectric conversion element illustrated in FIG. 1.

FIG. 4 is a schematic cross-sectional view of an example of a configuration of an imaging element using the photoelectric conversion element illustrated in FIG. 1.

FIG. 5 is a schematic plan view of an example of a pixel configuration of an imaging device including the imaging element illustrated in FIG. 1.

FIG. 6 is an equivalent circuit diagram of the imaging element illustrated in FIG. 4.

FIG. 7 is a schematic diagram illustrating disposition of a lower electrode and a transistor included in a controller in the imaging element illustrated in FIG. 4.

FIG. 8 is a cross-sectional view for describing a method of manufacturing the imaging element illustrated in FIG. 4.

FIG. 9 is a cross-sectional view of a process subsequent to FIG. 8.

FIG. 10 is a cross-sectional view of a process subsequent to FIG. 9.

FIG. 11 is a cross-sectional view of a process subsequent to FIG. 10.

FIG. 12 is a cross-sectional view of a process subsequent to FIG. 11.

FIG. 13 is a cross-sectional view of a step subsequent to FIG. 12.

FIG. 14 is a timing chart illustrating an operation example of the imaging element illustrated in FIG. 4.

FIG. 15 is a schematic cross-sectional view of an example of a configuration of an imaging element according to a modification example 1 of the present disclosure.

FIG. 16 is a schematic cross-sectional view of an example of a configuration of an imaging element according to a modification example 2 of the present disclosure.

FIG. 17A is a schematic cross-sectional view of an example of a configuration of an imaging element according to a modification example 3 of the present disclosure.

FIG. 17B is a schematic view of a planar configuration of the imaging element illustrated in FIG. 17A.

FIG. 18A is a schematic cross-sectional view of an example of a configuration of an imaging element according to a modification example 4 of the present disclosure.

FIG. 18B is a schematic view of a planar configuration of the imaging element illustrated in FIG. 18A.

FIG. 19 is a schematic cross-sectional view of an example of a configuration of a light-emitting element according to a second embodiment of the present disclosure.

FIG. 20 is a diagram describing a light emission principle of the light-emitting element illustrated in FIG. 19.

FIG. 21 is a diagram illustrating an example of energy levels of materials included in respective layers of the light-emitting element illustrated in FIG. 19.

FIG. 22 is a plan view of an example of a configuration of a display device using the light-emitting element illustrated in FIG. 19 and the like.

FIG. 23 is a diagram illustrating an example of a pixel drive circuit illustrated in FIG. 22.

FIG. 24 is a block diagram illustrating an entire configuration of the imaging element illustrated in FIG. 4 and the like.

FIG. 25 is a functional block diagram illustrating an example of an electronic apparatus (camera) using the imaging element illustrated in FIG. 24.

FIG. 26 is a plan view of a schematic configuration of a module including the display device described above.

FIG. 27A is a perspective view of an appearance of a smartphone in an application example 3 of the present disclosure as viewed from front side.

FIG. 27B is a perspective view of an appearance of the smartphone illustrated in FIG. 27A as viewed from back side.

FIG. 28A is a perspective view of an example of an appearance of a tablet terminal in an application example 4 of the present disclosure.

FIG. 28B is a perspective view of another example of the appearance of the tablet terminal in the application example 4 of the present disclosure.

FIG. 29 is a perspective view of an appearance of an application example 5 of the present disclosure.

FIG. 30 is a perspective view of an appearance of an application example 6.

FIG. 31A is a perspective view of an appearance of an application example 7 as viewed from front side.

FIG. 31B is a perspective view of an appearance of the application example 7 as viewed from back side.

FIG. 32 is a perspective view of an appearance of an application example 8.

FIG. 33 is a view depicting an example of a schematic configuration of an endoscopic surgery system.

FIG. 34 is a block diagram depicting an example of a functional configuration of a camera head and a camera control unit (CCU).

FIG. 35 is a block diagram depicting an example of schematic configuration of a vehicle control system.

FIG. 36 is a diagram of assistance in explaining an example of installation positions of an outside-vehicle information detecting section and an imaging section.

FIG. 37 is a schematic view of a configuration of an evaluation element in an experimental example 1 or the like.

FIG. 38 is a diagram illustrating energy levels of materials included in respective layers of evaluation elements formed in experimental examples 1 to 5.

FIG. 39 is a schematic cross-sectional view of a configuration of an evaluation element fabricated in an experiment 3.

FIG. 40 is a diagram illustrating energy levels of materials included in respective components of the evaluation element (light-emitting element) fabricated in the experiment 3.

FIG. 41 is a diagram describing a device in which a photoelectric conversion element and a light-emitting element are combined.

### MODES FOR CARRYING OUT THE INVENTION

Some embodiments of the present disclosure are described below in detail with reference to the drawings. The following description is a specific example of the present disclosure, and the present disclosure is not limited to the following embodiments. In addition, the present disclosure is not limited to arrangements, dimensions, dimension ratios, etc. of respective components illustrated in each drawing. It is to be noted that description is given in the following order.
1. First Embodiment (An example of a photoelectric conversion element including an organic semiconductor layer that is formed including at least one of a benzodithiophene derivative or a naphthodithiophene derivative having a predetermined molecular structure)
1-1. Configuration of Photoelectric Conversion Element
1-2. Configuration of Imaging Element
1-3. Method of Manufacturing Imaging Element
1-4. Signal Acquisition Operation of Imaging Element
1-5. Workings and Effects
2. Modification Examples
2-1. Modification Example 1 (An example of an imaging element in which a plurality of organic photoelectric converters is stacked)
2-2. Modification Example 2 (An example of an imaging element in which a plurality of organic photoelectric converters is stacked)
2-3. Modification Example 3 (An example of an imaging element in which an organic photoelectric converter disperses light with use of a color filter)
2-4. Modification Example 4 (An example of an imaging element in which an inorganic photoelectric converter disperses light with use of a color filter)
3. Second Embodiment (An example of a light-emitting element including an organic semiconductor layer that is formed including at least one of a benzodithiophene derivative or a naphthodithiophene derivative having a predetermined molecular structure)
3-1. Configuration of Light-emitting Element
3-2. Configuration of Display Device
3-3. Workings and Effects
4. Application Examples
5. Practical Application Examples
6. Examples

### 1. First Embodiment

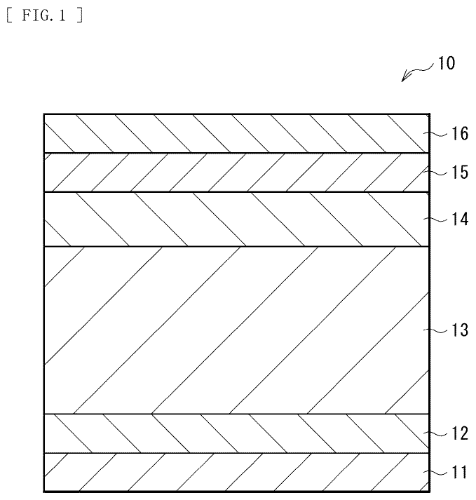

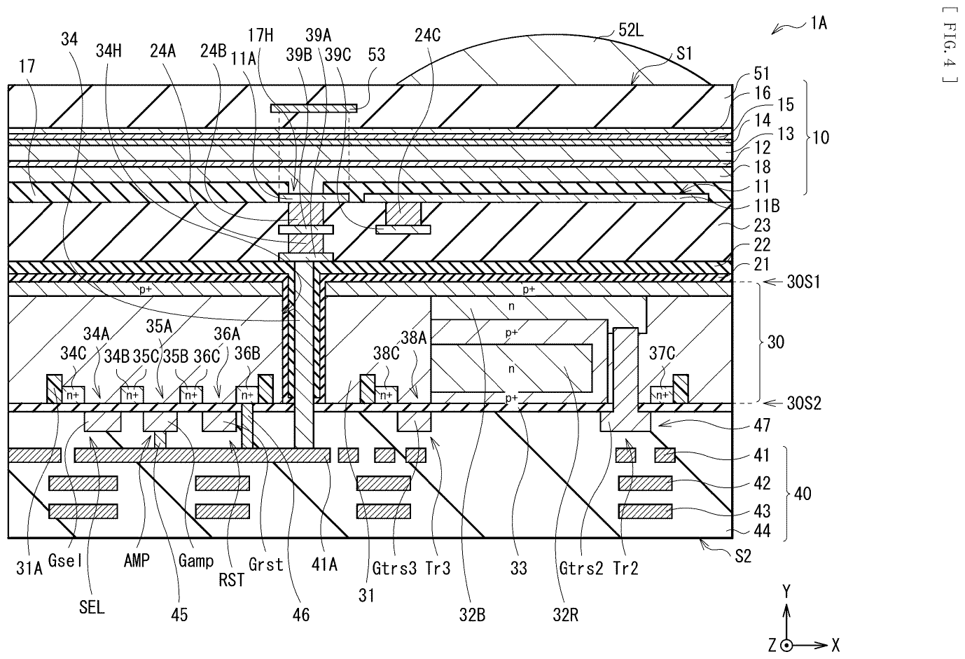

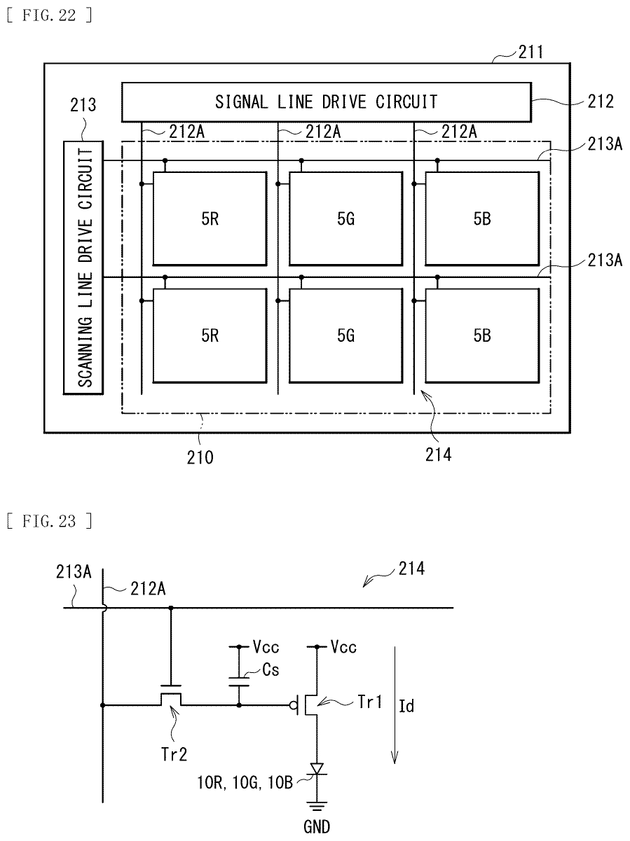

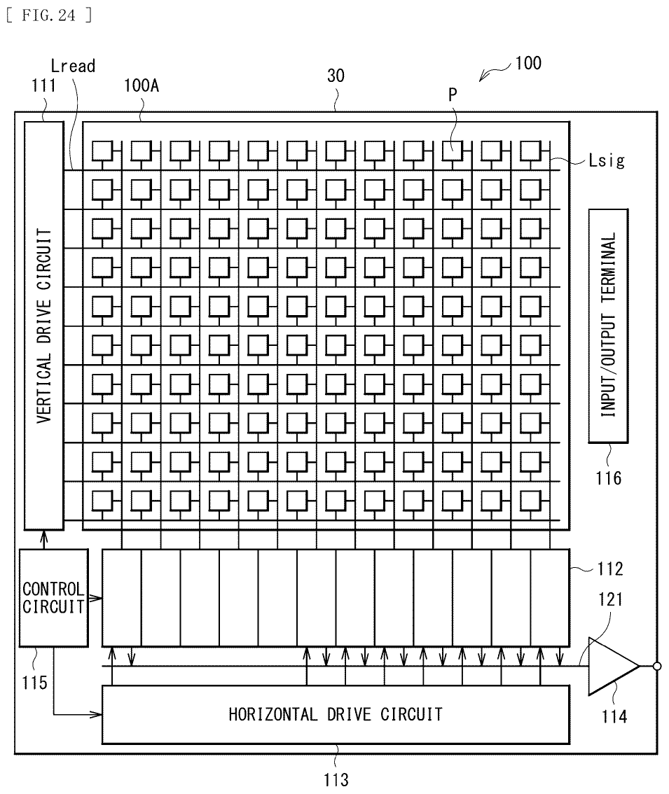

FIG. 1 schematically illustrates an example of a cross-sectional configuration of a photoelectric conversion element (photoelectric conversion element 10) according to a first embodiment of the present disclosure. The photoelectric conversion element 10 is used as an imaging element (imaging element 1A; see FIG. 4, for example) included in one pixel (unit pixel P) in an imaging device (imaging device 100; see FIG. 24, for example) such as a CMOS (Complementary Metal Oxide Semiconductor) image sensor. The imaging device is used for an electronic apparatus such as a digital still camera or a video camera. The photoelectric conversion element 10 according to the present embodiment corresponds to a specific example of a “semiconductor element” of the present disclosure, and includes an organic semiconductor layer (p-buffer layer 14) that is formed including at least one of a benzodithiophene derivative represented by the above-described general formula (1) or a naphthodithiophene derivative represented by the above-described general formula (2) that is to be described later.

### 1-1. Configuration of Photoelectric Conversion Element

The photoelectric conversion element 10 absorbs, for example, light corresponding to some or all of wavelengths in a selective wavelength range (e.g., a visible light region and a near-infrared region of 400 nm or more and less than 1300) and generates excitons (electron-hole pairs). The photoelectric conversion element 10 has, for example, a configuration in which a lower electrode 11, an n-buffer layer 12, a photoelectric conversion layer 13, the p-buffer layer 14, a work function adjustment layer 15, and an upper electrode 16 are stacked in this order. In the photoelectric conversion element 10, electrons of electron-hole pairs generated through photoelectric conversion are read out as signal electric charges in an imaging element (e.g., an imaging element 1A) to be described later. Configurations, materials, and the like of respective components in a case where electrons are read out as signal electric charges from side of the lower electrode 11 are described below as an example. In addition, in the present embodiment, description is given of a case where a lower electrode serves as a cathode and an upper electrode serves as an anode; however, a reverse case is also possible.

The lower electrode 11 (cathode) includes, for example, an electrically-conductive film having light transmissivity. Examples of a material included in the lower electrode 11 include indium tin oxide (ITO) that is In₂O₃ to which tin (Sn) is added as a dopant. The ITO thin film may have high crystallinity or low crystallinity (close to amorphous). In addition to the above-described material, examples of the material included in the lower electrode 11 include a tin oxide (SnO₂)-based material to which a dopant is added, for example, ATO to which Sb is added as a dopant, and FTO to which fluorine is added as a dopant. In addition, zinc oxide (ZnO) or a zinc oxide-based material obtained by adding a dopant may be used. Examples of the ZnO-based material include aluminum zinc oxide (AZO) to which aluminum (Al) is added as a dopant, gallium zinc oxide (GZO) to which gallium (Ga) is added, boron zinc oxide to which boron (B) is added, and indium zinc oxide (IZO) to which indium (In) is added. Furthermore, zinc oxides (IGZO, In—GaZnO₄) to which indium and gallium are added as dopants may be used. In addition, as the material included in the lower electrode 11, CuI, InSbO₄, ZnMgO, CuInO₂, MgIN₂O₄, CdO, ZnSnO₃, TiO₂, or the like may be used, and a spinel oxide or an oxide having a YbFe₂O₄ structure may be used.

In addition, in a case where the lower electrode 11 does not need light transmissivity (e.g., a case where light enters from side of the upper electrode 16), it is possible to use a single metal or an alloy having a low work function (e.g., ϕ=3.5 eV to 4.5 eV). Specific examples thereof include alkali metals (e.g., lithium (Li), sodium (Na), potassium (K), and the like) and fluorides or oxides thereof, alkaline earth metals (e.g., magnesium (Mg), calcium (Ca), and the like) and fluorides or oxides thereof. In addition, specific examples thereof include aluminum (Al), an Al—Si—Cu alloy, zinc (Zn), tin (Sn), thallium (Tl), an Na—K alloy, an Al—Li alloy, a Mg—Ag alloy, rare earth metals such as In and ytterbium (Yb), and alloys thereof.

Furthermore, examples of the material included in the lower electrode 11 include electrically-conductive materials, including metals such as platinum (Pt), gold (Au), palladium (Pd), chromium (Cr), nickel (Ni), aluminum (Al), silver (Ag), tantalum (Ta), tungsten (W), copper (Cu), titanium (Ti), indium (In), tin (Sn), iron (Fe), cobalt (Co), and molybdenum (Mo), alloys including these metal elements, electrically-conductive particles including these metals, electrically-conductive particles of alloys including these metals, polysilicon including impurities, carbon-based materials, oxide semiconductors, carbon nanotubes, graphene, and the like. In addition, examples of the material included in the lower electrode 11 include organic materials (electrically-conductive polymers) such as poly(3,4-ethylenedioxythiophene)/polystyrenesulfonic acid [PEDOT/PSS]. Furthermore, these materials may be mixed with a binder (polymer) into a paste or an ink, and the paste or the ink may be cured and used as an electrode.

It is possible to form the lower electrode 11 as a single layer film or a stacked film including any of the above-described materials. The lower electrode 11 has, for example, a film thickness in a stacking direction (hereinafter simply referred to as thickness) of 20 nm or more and 200 nm or less, preferably 30 nm or more and 150 nm or less.

The n-buffer layer 12 is a so-called hole block layer that selectively transports electrons of electric charges generated in the photoelectric conversion layer 13 to the lower electrode 11, and blocks transfer of holes to side of the lower electrode 11. As a material included in the n-buffer layer 12, it is preferable to use a material having a work function larger than that of a material used for the p-buffer layer 14, that is, a material having a Highest Occupied Molecular Orbital (HOMO) level and a Lowest Unoccupied Molecular Orbital (LUMO) level that are deeper than those of the material used for the p-buffer layer 14. Examples of such a material include an organic molecule and an organic metal complex including, as a part of a molecular framework, a heterocyclic ring including nitrogen (N), such as pyridine, pyrazine, pyrimidine, triazine, quinoline, quinoxaline, isoquinoline, acridine, phenazine, indole, imidazole, benzimidazol, phenanthroline, tetrazole, naphthalenetetracarboxdiimide, naphthalenedicarboxylic acid monoimide, hexaazatriphenylene, and hexaazatrinaphthylene. It is preferable to use a material having small absorption in the visible light region and the near-infrared region.

In addition, in a case where a hole blocking layer of about 5 nm or more and about 20 nm or less is separately formed between the lower electrode 11 and the n-buffer layer 12, the n-buffer layer 12 may be formed using fullerene and a derivative thereof having absorption in the visible light region.

The n-buffer layer 12 has, for example, a thickness of 5 nm or more and 500 nm or less, preferably 5 nm or more and 100 nm or less.

The photoelectric conversion layer 13 absorbs, for example, 60% or more of a predetermined wavelength included in at least a range from the visible light region to the near-infrared region to perform electric charge separation. The photoelectric conversion layer 13 absorbs, for example, light of some or all wavelengths in the visible light region and the near-infrared region of 400 nm or more and less than 1300 nm. The photoelectric conversion layer 13 includes, for example, two or more types of organic materials each functioning as a p-type semiconductor or an n-type semiconductor, and has a junction surface (p/n junction surface) therein between the p-type semiconductor and the n-type semiconductor. In addition, the photoelectric conversion layer 13 may include a stacked structure (a p-type semiconductor layer/an n-type semiconductor layer) of a layer including a p-type semiconductor (p-type semiconductor layer) and a layer including an n-type semiconductor (n-type semiconductor layer), a stacked structure (p-type semiconductor layer/bulk hetero layer) of a p-type semiconductor layer and a mixed layer (bulk hetero structure) of a p-type organic semiconductor and an n-type organic semiconductor, or a stacked structure (n-type semiconductor layer/bulk hetero layer) of an n-type semiconductor layer and a bulk hetero layer. In addition, the photoelectric conversion layer 13 may include, only a mixed layer (bulk hetero layer) of a p-type semiconductor and an n-type semiconductor.

The p-type semiconductor is a hole transport material that relatively functions as an electron donor, and the n-type semiconductor is an electron transport material that relatively functions as an electron acceptor. The photoelectric conversion layer 13 provides a field in which excitons (electron-hole pairs) generated in absorbing light are separated into electrons and holes. Specifically, electron-hole pairs are separated into electrons and holes at an interface (p/n junction surface) between the electron donor and the electron acceptor.

Examples of the p-type semiconductor include thienoacene-based materials typified by a naphthalene derivative, an anthracene derivative, a phenanthrene derivative, a pyrene derivative, a perylene derivative, a tetracene derivative, a pentacene derivative, a quinacridone derivative, a thiophene derivative, a thienothiophene derivative, a benzothiophene derivative, a benzothienobenzothiophene (BTBT) derivative, a dinaphthothienothiophene (DNTT) derivative, a dianthracenothienothiophene (DATT) derivative, a benzobisbenzothiophene (BBBT) derivative, a thienobisbenzothiophene (TBBT) derivative, a dibenzothienobisbenzothiophene (DBTBT) derivative, a dithienobenzodithiophene (DTBDT) derivative, a dibenzothienodithiophene (DBTDT) derivative, a benzodithiophene (BDT) derivative, a naphthodithiophene (NDT) derivative, an anthracenodithiophene (ADT) derivative, a tetracenodithiophene (TDT) derivative, and a pentacenodithiophene (PDT) derivative. In addition, examples of the p-type semiconductor include a triarylamine derivative, a carbazole derivative, a picene derivative, a chrysene derivative, for example, a fluoranthene derivative, a phthalocyanine derivative, a subphthalocyanine derivative, a subporphyrazine derivative, a metal complex including a heterocyclic compound as a ligand, a polythiophene derivative, a polybenzothiadiazole derivative, a polyfluorene derivative, and the like.

Examples of the n-type semiconductor include a fullerene and a fullerene derivative typified by higher fullerene, such as fullerere C₆₀, fullerene C₇₀, and fullerene C₇₄, endohedral fullerene, and the like. Examples of a substituent group included in the fullerene derivative include a halogen atom, a straight-chain, branched, or cyclic alkyl group or phenyl group, a group including a straight-chain or condensed aromatic compound, a group including a halide, a partial fluoroalkyl group, a perfluoroalkyl group, a silyl alkyl group, a silyl alkoxy group, an aryl silyl group, an aryl sulfanyl group, an alkyl sulfanyl group, an aryl sulfonyl group, an alkyl sulfonyl group, an aryl sulfide group, an alkyl sulfide group, an amino group, an alkyl amino group, an aryl amino group, a hydroxy group, an alkoxy group, an acyl amino group, an acyloxy group, a carbonyl group, a carboxy group, a carboxamide group, a carboalkoxy group, an acyl group, a sulfonyl group, a cyano group, a nitro group, a group including a chalcogenide, a phosphine group, a phosphone group, and derivatives thereof. Examples of a specific fullerene derivative include fullerene fluoride, a PCBM fullerene compound, a fullerene multimer, and the like. In addition, examples of the n-type semiconductor include an organic semiconductor having a HOMO level and a LUMO level larger (deeper) than the p-type organic semiconductor, and an inorganic metal oxide having light transmissivity.

Examples of the n-type organic semiconductor include a heterocyclic compound containing a nitrogen atom, an oxygen atom, or a sulfur atom. Specific examples thereof include organic molecules including, as a part of a molecular framework, a pyridine derivative, a pyrazine derivative, a pyrimidine derivative, a triazine derivative, a quinoline derivative, a quinoxaline derivative, an isoquinoline derivative, an acridine derivative, a phenazine derivative, a phenanthroline derivative, a tetrazole derivative, a pyrazole derivative, an imidazole derivative, a thiazole derivative, an oxazole derivative, an imidazole derivative, a benzimidazol derivative, a benzotriazole derivative, a benzoxazole derivative, a benzoxazole derivative, a carbazole derivative, a benzofuran derivative, a dibenzofuran derivative, a subporphyrazine derivative, a polyphenylene vinylene derivative, a polybenzothiadiazole derivative, a polyfluorene derivative, and the like, an organic metal complex, a subphthalocyanine derivative, a quinacridone derivative, a cyanine derivative, and a merocyanine derivative.

The photoelectric conversion layer 13 may further include an organic material that absorbs light in a predetermined wavelength range and allows light in another wavelength range to pass therethrough, that is, a so-called dye material, in addition to the p-type semiconductor and the n-type semiconductor. In a case where the photoelectric conversion layer 13 is formed using the p-type semiconductor, the n-type semiconductor, and the dye material, the p-type semiconductor and the n-type semiconductor are preferably materials having light transmissivity in the visible light region. This allows the photoelectric conversion layer 13 to selectively photoelectrically convert light in a wavelength range that is absorbed by the dye material.

The photoelectric conversion layer 13 has, for example, a thickness of 10 nm or more and 500 nm or less, preferably 25 nm or more and 300 nm or less, more preferably 25 nm or more and 200 nm or less, and still more preferably 100 nm or more and 180 nm or less.

The p-buffer layer 14 is a so-called electron block layer that selectively transports holes of electric charges generated in the photoelectric conversion layer 13 to the upper electrode 16 and inhibits transfer of electrons to side of the upper electrode 16. In addition, the p-buffer layer 14 is for improving electrical coupling between the photoelectric conversion layer 13 and the upper electrode 16 and adjusting capacitance of the photoelectric conversion element 10. In the present embodiment, it is possible to form the p-buffer layer 14 using at least one of a benzodithiophene derivative represented by the following general formula (1) or a naphthodithiophene derivative represented by the following general formula (2).

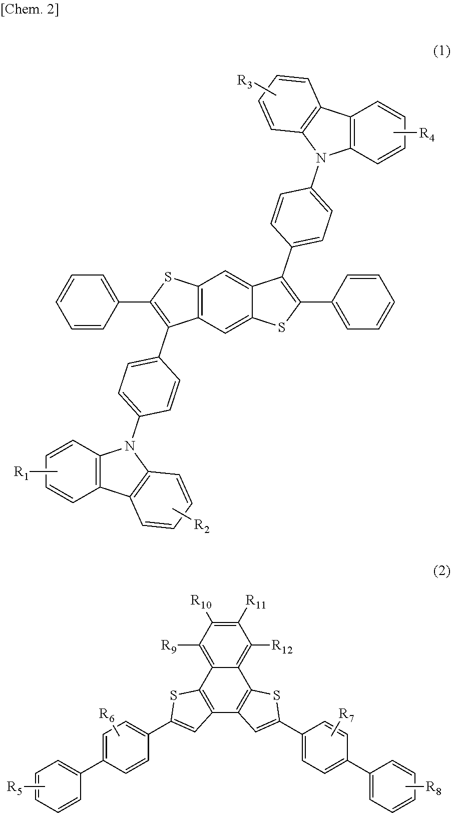

### R1 to R12 are each independently a hydrogen atom, a halogen atom, a straight-chain or branched alkyl group, a straight-chain or branched alkoxy group, an aryl group, an aryloxy group, a heteroaryl group, a heteroaryloxy group, or a derivative thereof, aryl sites of the aryl group and the aryloxy group are each one of a phenyl group, a biphenyl group, a naphthyl group, a naphthyl phenyl group, a phenyl naphthyl group, a tolyl group, a xylyl group, a terphenyl group, and a phenanthryl group that are unsubstituted or substituted by one of an alkyl group, a halogen atom, and a trifluoromethyl group; and heteroaryl sites of the heteroaryl group and the heteroaryloxy group are each one of a thienyl group, a thiazolyl group, an isothiazolyl group, a furanyl group, an oxazolyl group, an oxadiazolyl group, an isoxazolyl group, a benzothienyl group, a benzofuranyl group, a pyridinyl group, a quinolinyl group, an isoquinolyl group, an acridinyl group, an indole group, an imidazole group, a benzimidazol group, a carbazolyl group, a dibenzofuranyl group, and a dibenzothiophenyl group that are unsubstituted or substituted by one of an alkyl group, a halogen atom, and a trifluoromethyl group.)

The benzodithiophene derivative represented by the above-described general formula (1) or the naphthodithiophene derivative represented by the general formula (2) has a crystal density of greater than 1.26 g/cm³ and less than 1.50 g/cm³ in a case where powder thereof is subjected to X-ray structural analysis. More preferably, the benzodithiophene derivative represented by the above-described general formula (1) or the naphthodithiophene derivative represented by the general formula (2) has a crystal density of greater than 1.30 g/cm³ and less than 1.40 g/cm³ in a case where powder thereof is subjected to X-ray structural analysis. In addition, in a case where powder thereof is subjected to X-ray structural analysis, the benzodithiophene derivative represented by the above-described general formula (1) or the naphthodithiophene derivative represented by the general formula (2) has a broad peak with a half width of greater than 1° in a case where an organic film including the powder is subjected to X-ray diffraction measurement with use of CuKαradiation. More preferably, the benzodithiophene derivative represented by the above-described general formula (1) or the naphthodithiophene derivative represented by the general formula (2) has a broad peak with a half width of greater than 3° in a case where the organic film including the powder is subjected to X-ray diffraction measurement with use of CuKαradiation. Alternatively, the benzodithiophene derivative represented by the above-described general formula (1) or the naphthodithiophene derivative represented by the general formula (2) satisfies both the above-described crystal density and the peak in the case where the organic film including the powder is subjected to X-ray diffraction measurement. Furthermore, the p-buffer layer 14 has, for example, a film density of 1.20 g/cm³ or more. A difference between the HOMO level of the p-buffer layer 14 and the HOMO level of the photoelectric conversion layer 13 is preferably within a range of ±0.4 eV, for example.

It is to be noted that, in general, a material having higher crystallinity tends to have a larger particle diameter, and in consideration of the following equation (1) (the Scherrer's equation), a material having a larger half width tends to have a smaller particle diameter, which means that crystallinity is decreased.

$$\begin{matrix}( Math . 1 ) & \\ D = K λ / B cos θ & ( 1 )\end{matrix}$$

(D: crystallite size, K: Scherrer constant, λ: X-ray wavelength, B: half width, θ: Bragg angle)

It is preferable that the benzodithiophene derivative represented by the general formula (1) or the naphthodithiophene derivative represented by the general formula (2) described above further have a HOMO level of 6.0±0.5 eV. In addition, benzodithiophene derivative represented by the general formula (1) or the naphthodithiophene derivative represented by the general formula (2) described above more preferably has 6.0±0.2 eV, more preferably 6.0±0.1 eV. This reduces change in element characteristics due to a difference in energy level between the photoelectric conversion layer 13 and the work function adjustment layer 15.

Examples of the benzodithiophene derivative represented by the general formula (1) that satisfies the above-described conditions include a compound represented by the following formula (1-1) (3,7-bis[4-(9H-carbazole-9-yl)phenyl]-2,6-diphenylbenzo[1,2-b:4,5-b′]dithiophene: Cz-BDT). Examples of the naphthodithiophene derivative represented by the general formula (2) that satisfies the above-described conditions include a compound represented by the following formula (2-1) (2,5-bis([1,1′-biphenyl]-4-yl)naphtho[1,2-b:4,3-b′]dithiophene).

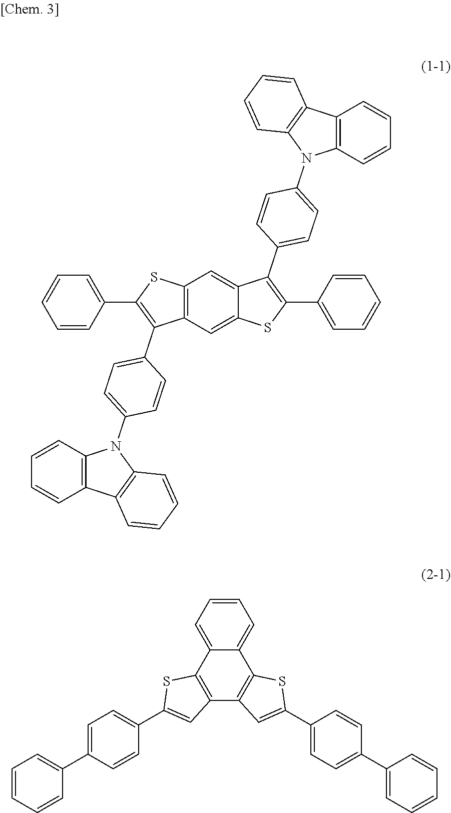

It is possible to form the p-buffer layer 14 including only the benzodithiophene derivative represented by the general formula (1) or the naphthodithiophene derivative represented by the general formula (2) described above, but this is not limitative. The p-buffer layer 14 may include a single-layer film or a stacked film using one kind or two or more kinds of the following materials together with the benzodithiophene derivative represented by the general formula (1) or the naphthodithiophene derivative represented by the general formula (2) described above. Examples of another material included in the p-buffer layer 14 include an aromatic amine-based material, a carbazole derivative, an indolocarbazole derivative, a naphthalene derivative, an anthracene derivative, a phenanthrene derivative, a pyrene derivative, a perylene derivative, a tetracene derivative, a pentacene derivative, a perylene derivative, a picene derivative, a chrysene derivative, a fluoranthene derivative, a phthalocyanine derivative, a subphthalocyanine derivative, a hexaazatriphenylene derivative, a metal complex including a heterocyclic compound as a ligand, a thiophene derivative, a thienothiophene derivative, a benzothiophene derivative, a thienoacene-based material, poly(3,4-ethylenedioxythiophene)/polystyrenesulfonic acid [PEDOT/PSS], and polyaniline. In addition, examples of another material included in the p-buffer layer 14 include metal oxides such as molybdenum oxide (MoOₓ), ruthenium oxide (RuOₓ), vanadium oxide (VOₓ), and tungsten oxide (WOₓ). Examples of the aromatic amine-based material include a triarylamine compound, a benzidine compound, and a styrylamine compound. Examples of the thienoacene-based material include a benzothienobenzothiophene (BTBT) derivative, a dinaphthothienothiophene (DNTT) derivative, a dianthracenthienothhenophene (DATT) derivative, a benzobisbenzothiophene (BBBT) derivative, a thienobisbenzothiophene (TBBT) derivative, a dibenzothienobisbenzothiophene (DBTBT) derivative, a dithienobenzodithiophene (DTBDT) derivative, a dibenzothienodithiophene (DBTDT) derivative, a benzodithiophene (BDT) derivative, a naphthodithiophene (NDT) derivative, an anthracenodithiophene (ADT) derivative, a tetracenodithiophene (TDT) derivative, and a pentacenodithiophene (PDT) derivative. Among the materials described above, the thienoacene-based material is preferably used as another material included in the p-buffer layer 14. This makes it possible to increase the thickness of the p-buffer layer 14 and reduce the capacitance of the photoelectric conversion element 10. Furthermore, among the materials, a material having small absorption in the visible light region and the near-infrared region is preferably used.

The p-buffer layer 14 is not limited to a single layer film including the material described above, but may be formed as a stacked film including two or more layers. The p-buffer layer 14 has, for example, of a thickness of 5 nm or more and 500 nm or less, preferably 5 nm or more and 200 nm or less, and more preferably 5 nm or more and 100 nm or less.

The work function adjustment layer 15 has electron affinity or a work function larger than the work functions of the lower electrode 11 and the upper electrode 16, and is for improving electrical coupling between the p-buffer layer 14 and the upper electrode 16. Examples of a material included in the work function adjustment layer 15 include dipyrazino[2,3-f.2′,3′v-h]quinoxaline-2,3,6,7,10,11-hexacarbonitrile (HAT-CN) represented by the following formula (3). In addition, examples of the material included in the work function adjustment layer 15 include PEDOT/PSS, polyaniline, and metal oxides such as MoOₓ, RuOₓ, VOₓ, and WOₓ. For example, while an ITO thin film used as the lower electrode 11 and the upper electrode 16 has a work function of about 4.6 eV to about 4.8 eV, HAT-CN and MoO₃ respectively have electron affinity of about 5.2 eV and a work function of about 6.9 eV, which are larger values.

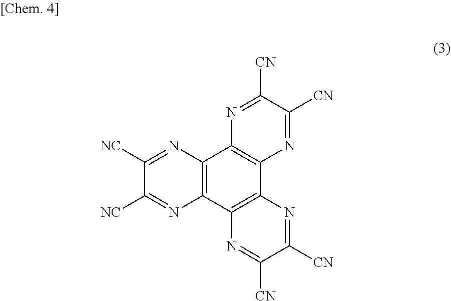 [SMILES: N#Cc1nc2c3nc(C#N)c(C#N)nc3c3nc(C#N)c(C#N)nc3c2nc1C#N]

The upper electrode 16 (anode) includes, for example, an electrically-conductive film having light transmissivity, as with the lower electrode 11. Examples of a material included in the upper electrode 16 include indium tin oxide (ITO) that is In₂O₃ to which tin (Sn) is added as a dopant. The ITO thin film may have high crystallinity or low crystallinity (close to amorphous). In addition to the above-described material, examples of the material included in the lower electrode 11 include a tin oxide (SnO₂)-based material to which a dopant is added, for example, ATO to which Sb is added as a dopant, and FTO to which fluorine is added as a dopant. In addition, zinc oxide (ZnO) or a zinc oxide-based material obtained by adding a dopant may be used. Examples of the ZnO-based material include aluminum zinc oxide (AZO) to which aluminum (Al) is added as a dopant, gallium zinc oxide (GZO) to which gallium (Ga) is added, boron zinc oxide to which boron (B) is added, and indium zinc oxide (IZO) to which indium (In) is added. Furthermore, zinc oxides (IGZO, In—GaZnO₄) to which indium and gallium are added as dopants may be used. In addition, as the material included in the lower electrode 11, CuI, InSbO₄, ZnMgO, CuInO₂, MgIN₂O₄, CdO, ZnSnO₃, TiO₂, or the like may be used, and a spinel oxide or an oxide having a YbFe₂O₄ structure may be used.

In addition, in a case where the upper electrode 16 does not need light transmissivity, it is possible to use a single metal or an alloy having a high work function (e.g., ϕ=4.5 eV to 5.5 eV). Specific examples thereof include Au, Ag, Cr, Ni, Pd, Pt, Fe, iridium (Ir), germanium (Ge), osmium (Os), rhenium (Re), tellurium (Te), and alloys thereof.

Furthermore, examples of the material included in the upper electrode 16 include electrically-conductive materials, including metals such as Pt, Au, Pd, Cr, Ni, Al, Ag, Ta, W, Cu, Ti, In, Sn, Fe, Co, and Mo, alloys including these metal elements, electrically-conductive particles including these metals, electrically-conductive particles of alloys including these metals, polysilicon including impurities, carbon materials, oxide semiconductors, carbon nanotubes, graphene, and the like. In addition, examples of the material included in the upper electrode 16 include organic materials (electrically-conductive polymers) such as PEDOT/PSS. Furthermore, these materials may be mixed with a binder (polymer) into a paste or an ink, and the paste or the ink may be cured and used as an electrode.

It is possible to form the upper electrode 16 as a single layer film or a stacked film including any of the above-described materials. The upper electrode 16 has, for example, a thickness of 20 nm or more and 200 nm or less, preferably 30 nm or more and 150 nm or less.

It is to be noted that, in addition to the n-buffer layer 12, the photoelectric conversion layer 13, the p-buffer layer 14, and the work function adjustment layer 15, another layer may be further provided between the lower electrode 11 and the upper electrode 16. For example, in addition to the n-buffer layer 12, an undercoating layer may be provided between the lower electrode 11 and the photoelectric conversion layer 13.

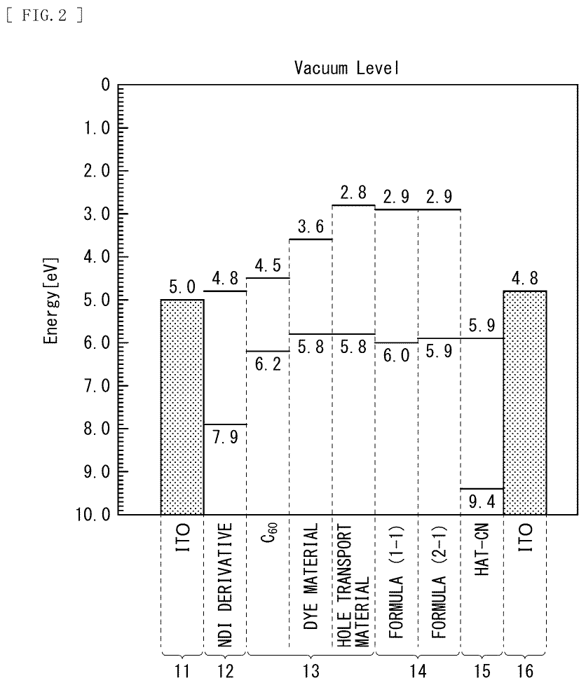

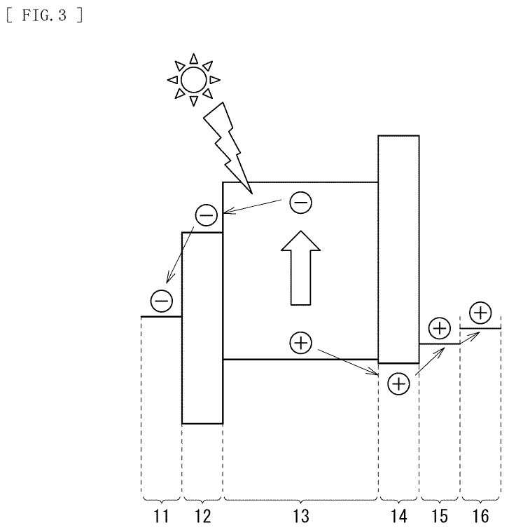

FIG. 2 illustrates a an example of energy levels of materials included in respective layers (the lower electrode 11, the n-buffer layer 12, the photoelectric conversion layer 13, the p-buffer layer 14, the work function adjustment layer 15, and the upper electrode 16) of the photoelectric conversion element 10 illustrated in FIG. 1. FIG. 3 illustrates, for example, carrier transfer in the photoelectric conversion element including the materials having the energy levels illustrated in FIG. 2. Light having entered the photoelectric conversion element 10 is absorbed by the photoelectric conversion layer 13. Excitons (electron-hole pairs) thereby generated move to an interface between the p-type semiconductor and the n-type semiconductor included in the photoelectric conversion layer 13 and undergo exciton separation. In other words, the excitons are dissociated into electrons and holes. Carriers (electrons and holes) generated here is transported to different electrodes by diffusion due to a carrier concentration difference and an internal electric field caused by a work function difference between the anode and the cathode. The transported electric charges are detected as photocurrent. Specifically, electrons separated at the p/n junction surface are taken out from the lower electrode 11 through the n-buffer layer 12. Holes separated at the p/n junction surface are taken out from the upper electrode 16 through the p-buffer layer 14 and the work function adjustment layer 15. It is to be noted that applying a potential between the lower electrode 11 and the upper electrode 16 makes it possible to control the transport directions of electrons and holes.

### 1-2. Configuration of Imaging Element

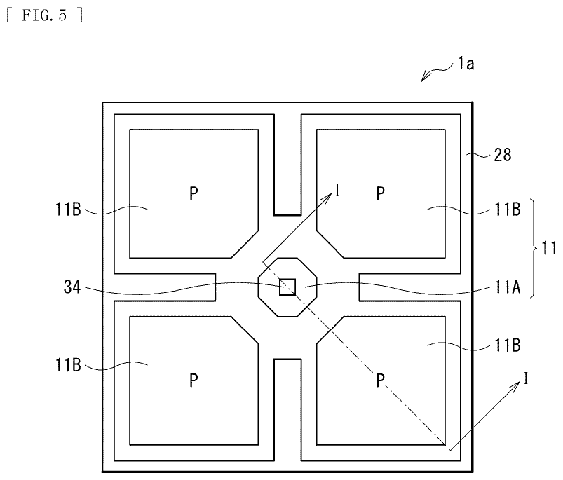

FIG. 4 schematically illustrates an example of a cross-sectional configuration of an imaging element (imaging element 1A) using the photoelectric conversion element 10 described above. FIG. 5 schematically illustrates an example of a planar configuration of the imaging element 1A illustrated in FIG. 4. FIG. 4 illustrates a cross section taken along a line I-I illustrated in FIG. 5. The imaging element 1A is included, for example, in one of pixels (unit pixels P) that are repeatedly disposed in an array in a pixel section 100A of an imaging device 100 illustrated in FIG. 24. In the pixel section 100A, pixel units 1a are repeatedly disposed as repeating units in an array having a row direction and a column direction. Each of the pixel units 1a includes the four pixels P that are disposed, for example, in two rows and two columns as illustrated in FIG. 5.

The imaging element 1A is a so-called longitudinal spectral type imaging element in which one organic photoelectric converter and two inorganic photoelectric converters 32B and 32R are stacked in a longitudinal direction. The organic photoelectric converter and the two inorganic photoelectric converters 32B and 32R perform photoelectric conversion by selectively detecting respective pieces of light in different wavelength ranges. It is possible to use the photoelectric conversion element 10 described above as the organic photoelectric converter. Hereinafter, the organic photoelectric converter has a configuration similar to that of the photoelectric conversion element 10 described above, and is described with the same reference numeral 10.

In the imaging element 1A, the organic photoelectric converter 10 is provided on side of a back surface (first surface 30S1) of a semiconductor substrate 30. The inorganic photoelectric converters 32B and 32R are formed to be buried in the semiconductor substrate 30 and stacked in a thickness direction of the semiconductor substrate 30.

The organic photoelectric converter 10 and the inorganic photoelectric converters 32B and 32R perform photoelectric conversion by selectively detecting respective pieces of light in different wavelength ranges. For example, the organic photoelectric converter 10 acquires a color signal of green (G). The inorganic photoelectric converters 32B and 32R respectively acquire a color signal of blue (B) and a color signal of red (R) by using a difference between absorption coefficients. This allows the imaging element 1A to acquire a plurality of types of color signals in one pixel without using any color filter.

It is to be noted that, in the imaging element 1A, a case is described where electrons of electron-hole pairs generated through photoelectric conversion are read out as signal electric charges. In addition, in the drawings, “+(plus)” attached to “p” and “n” indicates a high p-type or n-type impurity concentration.

The semiconductor substrate 30 includes, for example, an n-type silicon (Si) substrate and includes a p-well 31 in a predetermined region. A second surface (a front surface of the semiconductor substrate) 30S2 of the p-well 31 is provided with, for example, various floating diffusions (floating diffusion layers) FD (e.g., FD1, FD2, and FD3), and various transistors Tr1 (e.g., a vertical transistor (transfer transistor) Tr2, a transfer transistor Tr3, an amplifier transistor (modulation element) AMP, and a reset transistor RST). The second surface 30S2 of the semiconductor substrate 30 is further provided with a multilayer wiring layer 40 with a gate insulating layer 33 interposed therebetween. The multilayer wiring layer 40 is provided. The multilayer wiring layer 40 has, for example, a configuration in which wiring layers 41, 42, and 43 are stacked in an insulating layer 44. In addition, a peripheral portion of the semiconductor substrate 30 is provided with a peripheral circuit (not illustrated) including a logic circuit and the like.

A protective layer 51 is provided above the organic photoelectric converter 10. A wiring line is provided in the protective layer 51. The wiring line electrically couples the upper electrode 16 and a peripheral circuit portion, for example, around a light-shielding film 53 and the pixel section 100A. An optical member such as a planarization layer (not illustrated) or an on-chip lens 52L is further provided above the protective layer 51.

It is to be noted that FIG. 4 illustrates side of the first surface 30S1 of the semiconductor substrate 30 as light incidence side Si, and side of the second surface 30S2 thereof as wiring layer side S2.

Configurations, materials, and the like of the respective components are described in detail below.

In the organic photoelectric converter 10, the n-buffer layer 12, the photoelectric conversion layer 13, the p-buffer layer 14, and the work function adjustment layer 15 are stacked in this order between the lower electrode 11 and the upper electrode 16 that are disposed to be opposed to each other. In the imaging element 1A, the lower electrode 11 includes a plurality of electrodes (e.g., two electrodes including a readout electrode 11A and an accumulation electrode 11B). For example, an insulating layer 17 and a semiconductor layer 18 are stacked in this order between the lower electrode 11 and the n-buffer layer 12. In the lower electrode 11, the readout electrode 11A is electrically coupled to the semiconductor layer 18 through an opening 17H provided in the insulating layer 17.

The readout electrode 11A is for transferring electric charges generated in the photoelectric conversion layer 13 to the floating diffusion FD1. The readout electrode 11A is coupled to the floating diffusion FD1, for example, through an upper second contact 24B, a pad section 39B, an upper first contact 29A, a pad section 39A, a through electrode 34, a coupling section 41A, and a lower second contact 46. The accumulation electrode 11B is for accumulating electrons of the electric charges generated in the photoelectric conversion layer 13, for example, in the semiconductor layer 18 as signal electric charges. The accumulation electrode 11B is provided in a region that is opposed to light receiving surfaces of the inorganic photoelectric converters 32B and 32R formed in the semiconductor substrate 30 and covers these light receiving surfaces. It is preferable that the accumulation electrode 11B be larger than the readout electrode 11A. This makes it possible to accumulate more electric charges. As illustrated in FIG. 7, a voltage application circuit 54 is coupled to the accumulation electrode 11B through, for example, wiring lines such as an upper third contact 24C and a pad section 39C.

The insulating layer 17 is for electrically separating the accumulation electrode 11B and the semiconductor layer 18. The insulating layer 17 is provided, for example, above an interlayer insulating layer 23 to cover the lower electrode 11. The insulating layer 17 includes, for example, a single layer film including one kind of silicon oxide (SiOₓ), silicon nitride (SiNₓ), silicon oxynitride (SiOₓN_{y}), and the like or a stacked film including two or more kinds of them. The insulating layer 17 has, for example, a thickness of 20 nm or more and 500 nm or less.

The semiconductor layer 18 is for accumulating the electric charges generated by the photoelectric conversion layer 13. It is preferable that the semiconductor layer 18 be formed by using a material having higher electric charge mobility and having a wider band gap than those of the photoelectric conversion layer 13. It is preferable that the band gap of the material included in the semiconductor layer 18 be 3.0 eV or more, for example. Examples of such a material include an oxide semiconductor such as IGZO, an organic semiconductor, and the like. Examples of the organic semiconductor include transition metal dichalcogenide, silicon carbide, diamond, graphene, carbon nanotubes, a fused polycyclic hydrocarbon compound, a fused heterocyclic compound, and the like. The semiconductor layer 18 has, for example, a thickness of 10 nm or more and 300 nm or less. The semiconductor layer 18 including the material described above is provided between the lower electrode 11 and the photoelectric conversion layer 13. This makes it possible to prevent electric charge recombination during electric charge accumulation and enhance transfer efficiency.

It is to be noted that FIG. 4 illustrates an example in which the semiconductor layer 18, the n-buffer layer 12, the photoelectric conversion layer 13, the p-buffer layer 14, the work function adjustment layer 15, and the upper electrode 16 are provided as continuous layers that are common to a plurality of pixels (unit pixels P; see FIG. 24), but this is not limitative. The semiconductor layer 18, the n-buffer layer 12, the photoelectric conversion layer 13, the p-buffer layer 14, the work function adjustment layer 15, and the upper electrode 16 may be separately formed for each unit pixel P, for example.

For example, a layer (fixed electric charge layer) 21 having fixed electric charges, a dielectric layer 22 having an insulation property, and an interlayer insulating layer 23 are provided in this order from side of the first surface 30S1 of the semiconductor substrate 30 between the semiconductor substrate 30 and the lower electrode 11.

The fixed electric charge layer 21 may be a film having positive fixed electric charges or a film having negative fixed electric charges. It is preferable that a semiconductor material or an electrically-conductive material having a wider band gap than that of the semiconductor substrate 30 be used as a material included in the fixed electric charge layer 21. This makes it possible to suppress generation of a dark current at an interface of the semiconductor substrate 30. Examples of a material included in the fixed electric charge layer 21 include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), aluminum oxynitride (AlOₓN_{y}), and the like.

The dielectric layer 22 is for preventing reflection of light caused by a refractive index difference between the semiconductor substrate 30 and the interlayer insulating layer 23. It is preferable that a material included in the dielectric layer 22 be a material having a refractive index between the refractive index of the semiconductor substrate 30 and the refractive index of the interlayer insulating layer 23. Examples of the material included in the dielectric layer 22 include SiOₓ, TEOS, SiNₓ, SiOₓN_{y}, and the like.

The interlayer insulating layer 23 includes, for example, a single layer film including one kind of SiOₓ, SiNₓ, SiOₓN_{y}, and the like or a stacked film including two or more kinds of them.

The inorganic photoelectric converters 32B and 32R each include, for example, a PIN (Positive Intrinsic Negative) photodiode, and each have a pn junction in a predetermined region in the semiconductor substrate 30. The inorganic photoelectric converters 32B and 32R each enable dispersion of light in the longitudinal direction with use of a difference in absorbed wavelength range depending on a depth of light incidence in the silicon substrate.

The inorganic photoelectric converter 32B selectively detects blue light to accumulate a signal electric charge corresponding to blue. The inorganic photoelectric converter 32B is formed at a depth that allows the blue light to be photoelectrically converted efficiently. The inorganic photoelectric converter 32R selectively detects red light to accumulate a signal electric charge corresponding to red. The inorganic photoelectric converter 32R is formed at a depth that allows the red light to be photoelectrically converted efficiently. It is to be noted that blue (B) is a color corresponding to, for example, a wavelength range of 400 nm or more and less than 495 nm and red (R) is a color corresponding to, for example, a wavelength range of 620 nm or more and less than 750 nm. It is sufficient if each of the inorganic photoelectric converters 32B and 32R is able to detect light in a portion or the entirety of the corresponding wavelength range.

Specifically, as illustrated in FIG. 4, the inorganic photoelectric converter 32B and the inorganic photoelectric converter 32R each include, for example, a p+ region serving as a hole accumulation layer and an n region serving as an electron accumulation layer (have a p-n-p stacked structure). The n region of the inorganic photoelectric converter 32B is coupled to the vertical transistor Tr2. The p+ region of the inorganic photoelectric converter 32B is bent along the vertical transistor Tr2 and leads to the p+ region of the inorganic photoelectric converter 32R.

The gate insulating layer 33 includes, for example, a single layer film including one kind of SiOₓ, SiNₓ, SiOₓN_{y}, and the like or a stacked film including two or more kinds of them.

The through electrode 34 is provided between the first surface 30S1 and the second surface 30S2 of the semiconductor substrate 30. The through electrode 34 has a function as a connector between the organic photoelectric converter 10 and each of a gate Gamp of the amplifier transistor AMP and the floating diffusion FD1, and serves as a transmission path for the electric charges generated by the organic photoelectric converter 10. A reset gate Grst of the reset transistor RST is disposed next to the floating diffusion FD1 (one source/drain region 36B of the reset transistor RST). This allows the reset transistor RST to reset electric charges accumulated in the floating diffusion FD1.

An upper end of the through electrode 34 is coupled to the readout electrode 11A, for example, through the pad section 39A, the upper first contact 24A, the pad electrode 38B, and the upper second contact 24B provided in the interlayer insulating layer 23. A lower end of the through electrode 34 is coupled to the coupling section 41A in the wiring layer 41, and the coupling section 41A and the gate Gamp of the amplifier transistor AMP are coupled through the lower first contact 45. The coupling section 41A and the floating diffusion FD1 (region 36B) are coupled, for example, through the lower second contact 46.

It is possible to form the upper first contact 24A, the upper second contact 24B, the upper third contact 24C, the pad sections 39A, 39B, and 39C, the wiring layer 41, 42, and 43, the lower first contact 45, the lower second contact 46, and a gate wiring layer 47 by using, for example, a doped silicon material such as PDAS (Phosphorus Doped Amorphous Silicon) or a metal material such as Al, W, Ti, Co, Hf, and Ta.

The insulating layer 44 includes, for example, a single layer film including one kind of SiOₓ, SiNₓ, SiOₓN_{y}, and the like or a stacked film including two or more kinds of them.

The protective layer 51 and the on-chip lens 52L each include a material having light transmissivity, and each include, for example, a single layer film including one kind of SiOₓ, SiNₓ, SiOₓN_{y}, and the like or a stacked film including two or more kinds of them. The protective layer 51 has, for example, a thickness of 100 nm or more and 30000 nm or less.

The light-shielding film 53 is provided not to overlap with at least the accumulation electrode 111B, but to cover a region of the readout electrode 21A that is in direct contact with the semiconductor layer 18. It is possible to form the light-shielding film 53 by using, for example, W, Al, an alloy of Al and Cu, and the like.

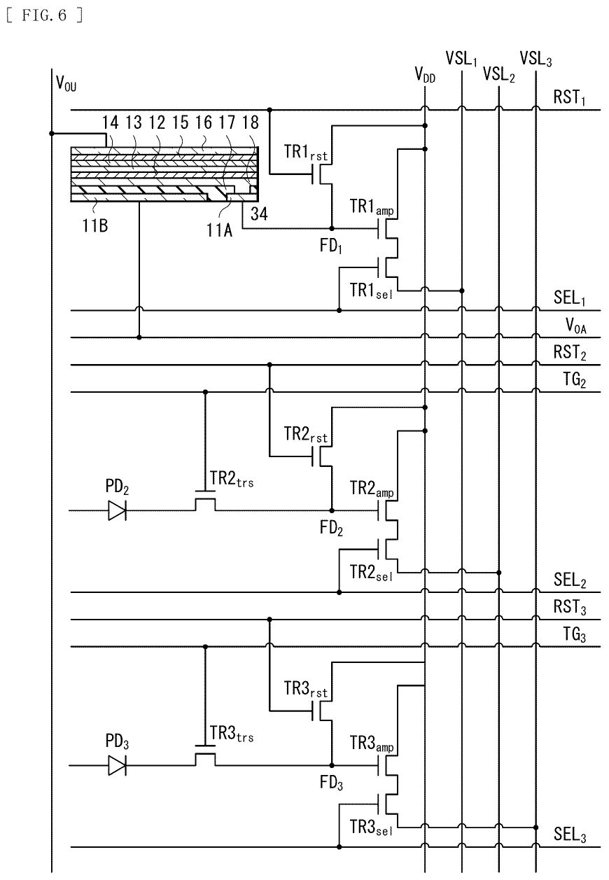

FIG. 6 is an equivalent circuit diagram of the imaging element 1A illustrated in FIG. 4. FIG. 7 schematically illustrates disposition of the lower electrode 11 and a transistor included in a controller in the imaging element 1A illustrated in FIG. 4.

The reset transistor RST (reset transistor TR1rst) is for resetting electric charges transferred from the organic photoelectric converter 10 to the floating diffusion FD1, and includes, for example, a MOS transistor. Specifically, the reset transistor TR1rst includes the reset gate Grst, a channel formation region 36A, and source/drain regions 36B and 36C. The reset gate Grst is coupled to a reset line RST1. The one source/drain region 36B of the reset transistor TR1rst also serves as the floating diffusion FD1. The other source/drain region 36C included in the reset transistor TR1rst is coupled to a power supply line VDD.

The amplifier transistor AMP is a modulation element that modulates, to a voltage, the amount of electric charges generated by the organic photoelectric converter 10, and includes, for example, a MOS transistor. Specifically, the amplifier transistor AMP includes the gate Gamp, a channel formation region 35A, and the source/drain regions 35B and 35C. The gate Gamp is coupled to the readout electrode 11A and the one source/drain region 36B (floating diffusion FD1) of the reset transistor TR1rst through the lower first contact 45, the coupling section 41A, the lower second contact 46, the through electrode 34, and the like. In addition, the one source/drain region 35B shares a region with the other source/drain region 36C included in the reset transistor TR1rst, and is coupled to the power supply line VDD.

A selection transistor SEL (selection transistor TR1sel) includes a gate Gsel, a channel formation region 34A, and source/drain regions 34B and 34C. The gate Gsel is coupled to a selection line SEL1. One source/drain region 34B shares a region with the other source/drain region 35C included in the amplifier transistor AMP, and the other source/drain region 34C is coupled to a signal line (data output line) VSL1.

A transfer transistor TR2 (transfer transistor TR2trs) is for transferring, to the floating diffusion FD2, the signal electric charge corresponding to blue that has been generated and accumulated in the inorganic photoelectric converter 32B. The inorganic photoelectric converter 32B is formed at a deep position from the second surface 30S2 of the semiconductor substrate 30, and it is thus preferable that the transfer transistor TR2trs of the inorganic photoelectric converter 32B include a vertical transistor. The transfer transistor TR2trs is coupled to a transfer gate line TG2. The floating diffusion FD2 is provided in a region 37C near a gate Gtrs2 of the transfer transistor TR2trs. The electric charge accumulated in the inorganic photoelectric converter 32B is read out to the floating diffusion FD2 through a transfer channel formed along the gate Gtrs2.

A transfer transistor TR3 (transfer transistor TR3trs) is for transferring, to the floating diffusion FD3, the signal electric charge corresponding to red that has been generated and accumulated in the inorganic photoelectric converter 32R. The transfer transistor TR3 (transfer transistor TR3trs) includes, for example, a MOS transistor. The transfer transistor TR3trs is coupled to a transfer gate line TG3. The floating diffusion FD3 is provided in a region 38C near a gate Gtrs3 of the transfer transistor TR3trs. The electric charge accumulated in the inorganic photoelectric converter 32R is read out to the floating diffusion FD3 through a transfer channel formed along the gate Gtrs3.

A reset transistor TR2rst, an amplifier transistor TR2amp, and a selection transistor TR2sel included in a controller of the inorganic photoelectric converter 32B are further provided on side of the second surface 30S2 of the semiconductor substrate 30. A reset transistor TR3rst, an amplifier transistor TR3amp, and a selection transistor TR3sel included in a controller of the inorganic photoelectric conversion section 32R are further provided.

The reset transistor TR2rst includes a gate, a channel formation region, and source/drain regions. The gate of the reset transistor TR2rst is coupled to a reset line RST2 and one source/drain region of the reset transistor TR2rst is coupled to the power supply line VDD. Another source/drain region of the reset transistor TR2rst also serves as the floating diffusion FD2.

The amplifier transistor TR2amp includes a gate, a channel formation region, and source/drain regions. The gate is coupled to the other source/drain region (floating diffusion FD2) of the reset transistor TR2rst. One source/drain region included in the amplifier transistor TR2amp shares a region with the one source/drain region included in the reset transistor TR2rst and is coupled to the power supply line VDD.

The selection transistor TR2sel includes a gate, a channel formation region, and source/drain regions. The gate is coupled to a selection line SEL2. One source/drain region included in the selection transistor TR2sel shares a region with another source/drain region included in the amplifier transistor TR2amp. Another source/drain region included in the selection transistor TR2sel is coupled to a signal line (data output line) VSL2.

The reset transistor TR3rst includes a gate, a channel formation region, and source/drain regions. The gate of the reset transistor TR3rst is coupled to a reset line RST3, and one source/drain region included in the reset transistor TR3rst is coupled to the power supply line VDD. Another source/drain region included in the reset transistor TR3rst also serves as the floating diffusion FD3.

The amplifier transistor TR3amp includes a gate, a channel formation region, and source/drain regions. The gate is coupled to the other source/drain region (floating diffusion FD3) included in the reset transistor TR3rst. One source/drain region included in the amplifier transistor TR3amp shares a region with the one source/drain region included in the reset transistor TR3rst, and is coupled to the power supply line VDD.

The selection transistor TR3sel includes a gate, a channel formation region, and source/drain regions. The gate is coupled to a selection line SEL3. One source/drain region included in the selection transistor TR3sel shares a region with the other source/drain region included in the amplifier transistor TR3amp. Another source/drain region included in the selection transistor TR3sel is coupled to a signal line (data output line) VSL3.

The reset lines RST1, RST2, and RST3, the selection lines SEL1, SEL2, and SEL3, and the transfer gate lines TG2 and TG3 are each coupled to a vertical drive circuit included in a drive circuit. The signal lines (data output lines) VSL1, VSL2, and VSL3 are coupled to a column signal processing circuit 112 included in the drive circuit.

### 1-3. Method of Manufacturing Imaging Element

It is possible to manufacture the imaging element 1A according to the present embodiment, for example, as follows.

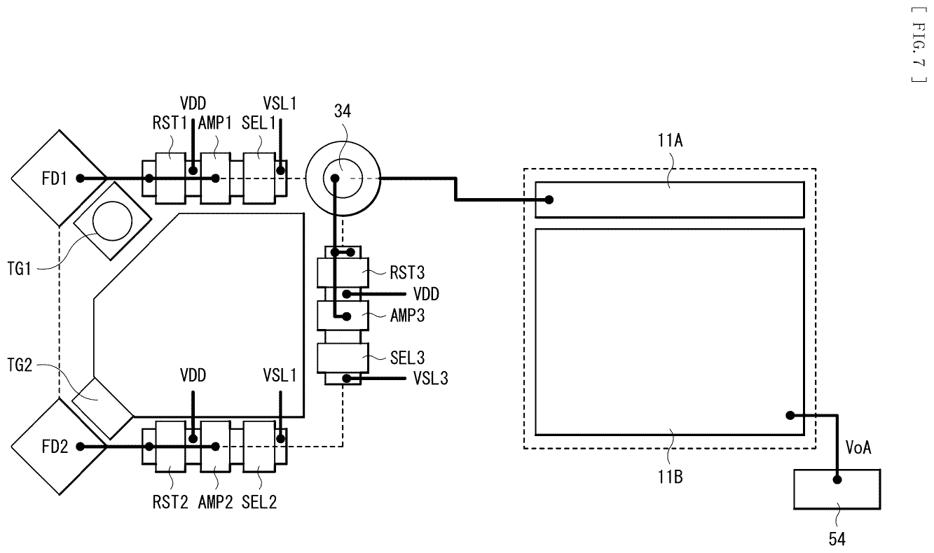

FIGS. 8 to 13 illustrate a method of manufacturing the imaging element 1A in order of processes. First, as illustrated in FIG. 8, for example, the p-well 31 is formed in the semiconductor substrate 30. For example, the n-type inorganic photoelectric converters 32B and 32R are formed in this p-well 31. A p+ region is formed near the first surface 30S1 of the semiconductor substrate 30.

As also illustrated in FIG. 8, for example, n+ regions that serve as the floating diffusions FD1 to FD3 are formed on the second surface 30S2 of the semiconductor substrate 30, and the gate insulating layer 33 and the gate wiring layer 47 are then formed. The gate wiring layer 47 includes the respective gates of the transfer transistor Tr2, the transfer transistor Tr3, the selection transistor SEL, the amplifier transistor AMP, and the reset transistor RST. Thus, the transfer transistor Tr2, the transfer transistor Tr3, the selection transistor SEL, the amplifier transistor AMP, and the reset transistor RST are formed. Further, the multilayer wiring layer 40 is formed on the second surface 30S2 of the semiconductor substrate 30. The multilayer wiring layer 40 includes the wiring layers 41 to 43 and the insulating layer 44. The wiring layers 41 to 43 include the lower first contact 45, the lower second contact 46, and the coupling section 41A.

As a base of the semiconductor substrate 30, for example, an SOI (Silicon on Insulator) substrate is used in which the semiconductor substrate 30, a buried oxide film (not illustrated), and a holding substrate (not illustrated) are stacked. Although not illustrated in FIG. 8, the buried oxide film and the holding substrate are joined to the first surface 30S1 of the semiconductor substrate 30. After ion implantation, annealing treatment is performed.

Next, a support substrate (not illustrated), another semiconductor base, or the like is joined onto the multilayer wiring layer 40 provided on side of the second surface 30S2 of the semiconductor substrate 30 and flipped vertically. Subsequently, the semiconductor substrate 30 is separated from the buried oxide film and the holding substrate of the SOI substrate to expose the first surface 30S1 of the semiconductor substrate 30. It is possible to perform the processes described above with technology used in a normal CMOS process including ion implantation, a CVD (Chemical Vapor Deposition) method, and the like.

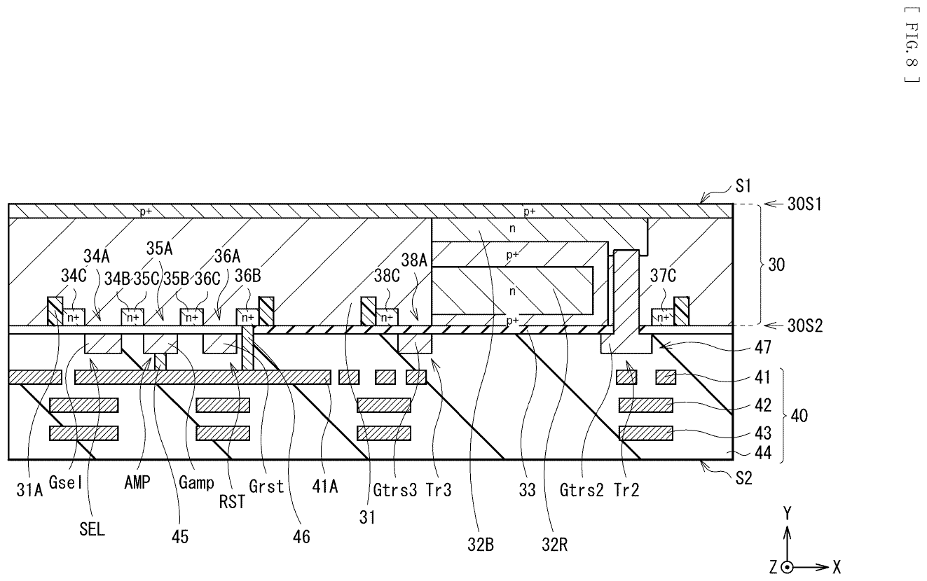

Next, as illustrated in FIG. 9, the semiconductor substrate 30 is processed from side of the first surface 30S1, for example, by dry etching to form, for example, an annular opening 34H. The depth of the opening 34H penetrates from the first surface 30S1 to the second surface 30S2 of the semiconductor substrate 30 and reaches, for example, the coupling section 41A, as illustrated in FIG. 10.

Subsequently, for example, the negative fixed electric charge layer 21 and the dielectric layer 22 are formed in order on the first surface 30S1 of the semiconductor substrate 30 and a side surface of the opening 34H. It is possible to form the fixed electric charge layer 21 by forming a HfOₓ film with use of, for example, an atomic layer deposition method (ALD method). It is possible to form the dielectric layer 22 by forming a SiOₓ film with use of, for example, a plasma CVD method. Next, the pad section 39A is formed at a predetermined position on the dielectric layer 22. In the pad section 39A, a barrier metal including, for example, a stacked film (Ti/TiN film) of titanium and titanium nitride and a W film are stacked. After that, the interlayer insulating layer 23 is formed on the dielectric layer 22 and the pad section 39A, and a surface of the interlayer insulating layer 23 is planarized with use of a CMP (Chemical Mechanical Polishing) method.

Subsequently, as illustrated in FIG. 10, an opening 23H1 is formed above the pad section 39A. After that, the opening 23H1 is filled, for example, with an electrically-conductive material such as Al to form the upper first contact 24A. Next, as illustrated in FIG. 10, the pad sections 39B and 39C are formed as with the pad section 39A, and then the interlayer insulating layer 23, and the upper second contact 24B and the upper third contact 24C are formed in order.

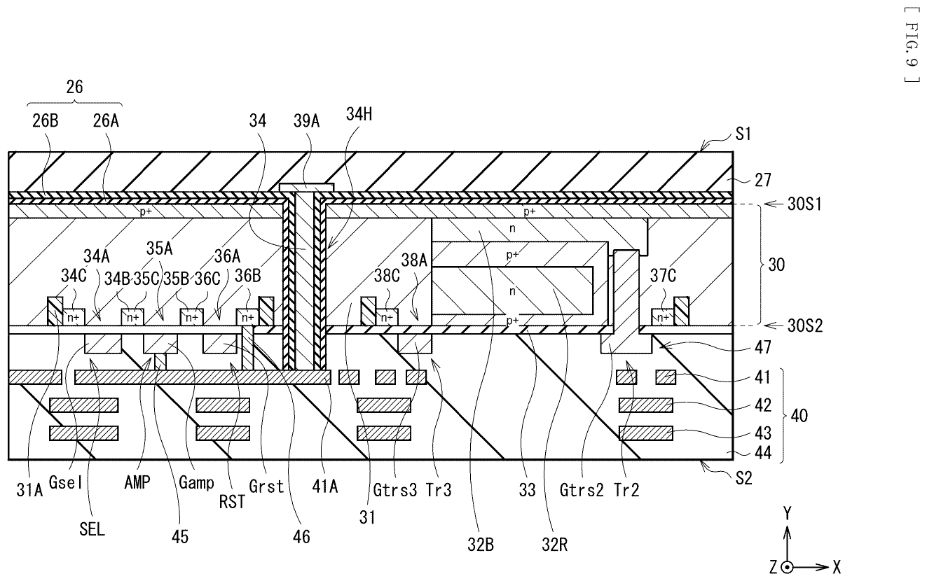

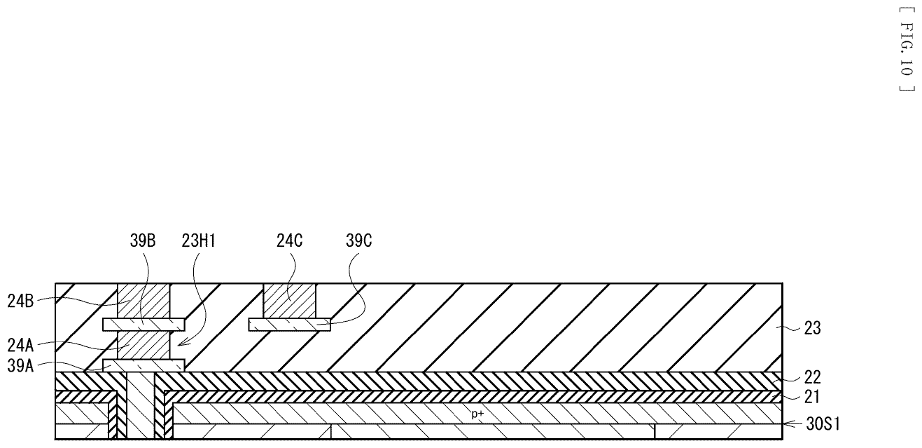

Subsequently, as illustrated in FIG. 11, an electrically-conductive film 11X is formed on the interlayer insulating layer 23 with use of, for example, a sputtering method, and patterning is then performed with use of photolithography technology. Specifically, a photoresist PR is formed at a predetermined position in the electrically-conductive film 11X, and the electrically-conductive film 11X is then processed with use of dry etching or wet etching. After that, the readout electrode 11A and the accumulation electrode 11B are formed as illustrated in FIG. 12 by removing the photoresist PR.

Next, as illustrated in FIG. 13, the insulating layer 17, the semiconductor layer 18, the n-buffer layer 12, the photoelectric conversion layer 13, the p-buffer layer 14, the work function adjustment layer 15, and the upper electrode 16 are formed in order. For example, a SiOₓ film is formed for the insulating layer 17 with use of, for example, an ALD method. After that, a surface of the insulating layer 17 is planarized with use of a CMP method. After that, the opening 17H is formed on the readout electrode 11A with use of, for example, wet etching. It is possible to form the semiconductor layer 18 with use of, for example, a sputtering method. The n-buffer layer 12, the photoelectric conversion layer 13, the p-buffer layer 14, and the work function adjustment layer 15 are formed with use of, for example, a vacuum deposition method. The upper electrode 16 is formed with use of, for example, a sputtering method, as with the lower electrode 11. Finally, the protective layer 51, the light-shielding film 53, and the on-chip lens 52L are provided on the upper electrode 16. Thus, the imaging element 1A illustrated in FIG. 4 is completed.

It is to be noted that it is desirable to form the n-buffer layer 12, the photoelectric conversion layer 13, the p-buffer layer 14, and the work function adjustment layer 15 continuously (in an in-situ vacuum process) in a vacuum process. In addition, it is possible to form organic layers such as the n-buffer layer 12, the photoelectric conversion layer 13, the p-buffer layer 14, and the work function adjustment layer 15, and electrically conductive films such as the lower electrode 11 and the upper electrode 16 with use of a dry film formation method or a wet film formation method. Examples of the dry film formation method include an electron beam (EB) deposition method, various sputtering methods (a magnetron sputtering method, an RF-DC coupled bias sputtering method, an ECR sputtering method, a facing-target sputtering method, and a high frequency sputtering method), an ion plating method, a laser ablation method, a molecular beam epitaxy method, and a laser transfer method, in addition to a vacuum deposition method using resistance heating or high frequency heating. In addition, examples of the dry film formation method include chemical vapor deposition methods such as a plasma CVD method, a thermal CVD method, an MOCVD method, and an optical CVD method. Examples of the wet film formation method include a spin coating method, an ink jet method, a spray coating method, a stamping method, a micro contact printing method, a flexographic printing method, an offset printing method, a gravure printing method, a dipping method, and the like.

As patterning, it is possible to use, in addition to photolithography technology, chemical etching such as a shadow mask and laser transfer, physical etching by ultraviolet light or laser, or the like. As planarization technology, it is possible to use a laser planarization method, a reflow method, or the like in addition to the CMP method.

### 1-4. Signal Acquisition Operation of Imaging Element

In a case where light enters the organic photoelectric converter 10 through the on-chip lens 52L in the imaging element 1A, the light passes through the organic photoelectric converter 10 and the inorganic photoelectric converters 32B and 32R in this order. While the light passes through the organic photoelectric converter 10 and the inorganic photoelectric converters 32B and 32R, the light is photoelectrically converted for each of green light, blue light, and red light. The following describes operations of acquiring signals of the respective colors.

### (Acquisition of Green Color Signal by Organic Photoelectric Converter 10)

First, the green light of light having entered the imaging element 1A is selectively detected (absorbed) and photoelectrically converted by the organic photoelectric converter 10.

The organic photoelectric converter 10 is coupled to the gate Gamp of the amplifier transistor AMP and the floating diffusion FD1 through the through electrode 34. Thus, electrons of excitons generated by the organic photoelectric converter 10 are taken out from side of the lower electrode 11, transferred to side of the second surface 30S2 of the semiconductor substrate 30 through the through electrode 34, and accumulated in the floating diffusion FD1. At the same time, the amplifier transistor AMP modulates the amount of electric charges generated by the organic photoelectric converter 10 to a voltage.

In addition, the reset gate Grst of the reset transistor RST is disposed next to the floating diffusion FD1. This causes the reset transistor RST to reset the electric charges accumulated in the floating diffusion FD1.

The organic photoelectric converter 10 is coupled not only to the amplifier transistor AMP, but also to the floating diffusion FD1 through the through electrode 34, which allows the reset transistor RST to easily reset the electric charges accumulated in the floating diffusion FD1.

In contrast, in a case where the through electrode 34 and the floating diffusion FD1 are not coupled, it is difficult to reset the electric charges accumulated in the floating diffusion FD1, which causes the electric charges to be drawn to side of the upper electrode 16 by application of a large voltage. This may damage the photoelectric conversion layer 24. In addition, a structure that allows for resetting in a short period of time causes an increase in dark time noise, thereby resulting in a trade-off; therefore, this structure is difficult.

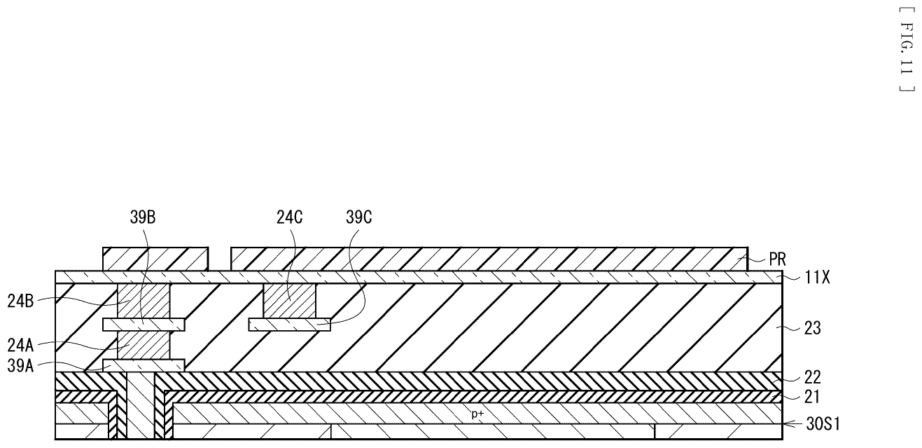

FIG. 14 illustrates an operation example of the imaging element 1A, where (A) indicates a potential at the accumulation electrode 11B, (B) indicates a potential at the floating diffusion FD1 (readout electrode 11A), and (C) indicates a potential at the gate (Gsel) of the reset transistor TR1rst. In the imaging element 1A, voltages are individually applied to the readout electrode 11A and the accumulation electrode 111B.

In the imaging element 1A, the drive circuit applies a potential V1 to the readout electrode 11A and applies a potential V2 to the accumulation electrode 11B in an accumulation period. Here, it is assumed that the potentials V1 and V2 satisfy V2>V1. This causes electric charges (signal electric charges; electrons) generated through photoelectric conversion to be drawn to the accumulation electrode 11B and accumulated in a region of the semiconductor layer 18 opposed to the accumulation electrode 11B (accumulation period). Additionally, the value of the potential in the region of the semiconductor layer 18 opposed to the accumulation electrode 11B becomes more negative with the passage of time of photoelectric conversion. It is to be noted that holes are sent from the upper electrode 16 to the drive circuit.

In the imaging element 1A, a reset operation is performed in the latter half of the accumulation period. Specifically, at a timing t1, a scanning section changes the voltage of a reset signal RST from a low level to a high level. This turns on the reset transistor TR1rst in the unit pixel P. As a result, the voltage of the floating diffusion FD1 is set to a power supply voltage and the voltage of the floating diffusion FD1 is reset (reset period).

After the reset operation is completed, electric charges are read out. Specifically, the drive circuit applies a potential V3 to the readout electrode 11A and applies a potential V4 to the accumulation electrode 11B at a timing t2. Here, it is assumed that the potentials V3 and V4 satisfy V3<V4. This causes the electric charges accumulated in a region corresponding to the accumulation electrode 11B to be read out from the readout electrode 11A to the floating diffusion FD1. In other words, the electric charges accumulated in the semiconductor layer 18 are read out to the controller (transfer period).

The drive circuit applies the potential V1 to the readout electrode 11A and applies the potential V2 to the accumulation electrode 11B again after the readout operation is completed. This causes electric charges generated through photoelectric conversion to be drawn to the accumulation electrode 11B and accumulated in a region of the photoelectric conversion layer 24 opposed to the accumulation electrode 11B (accumulation period).

### Acquisition of Blue Color Signal and Red Color Signal by Inorganic Photoelectric Converters 32B and 32R

Subsequently, blue light (B) and red light (R) of the light having passed through the organic photoelectric converter 10 are respectively absorbed and photoelectrically converted in order by the inorganic photoelectric converter 32B and the inorganic photoelectric converter 32R. In the inorganic photoelectric converter 32B, electrons corresponding to the incident blue light (B) are accumulated in the n region of the inorganic photoelectric converter 32B and the accumulated electrons are transferred to the floating diffusion FD2 by the transfer transistor Tr2. Similarly, in the inorganic photoelectric converter 32R, electrons corresponding to the incident red light (R) are accumulated in the n region of the inorganic photoelectric converter 32R and the accumulated electrons are transferred to the floating diffusion FD3 by the transfer transistor Tr3.

### 1-5. Workings and Effects

In the photoelectric conversion element 10 according to the present embodiment, the p-buffer layer 14 is formed using at least one of the benzodithiophene derivative represented by the above-described general formula (1) or the naphthodithiophene derivative represented by the above-described general formula (2). Thus, the p-buffer layer 14 having moderate intermolecular interaction is formed. This is described below.

Electronic apparatuses have been remarkably developed since inorganic semiconductors were found and transistors were invented, and have provided people with many benefits. An advantage of the inorganic semiconductors is that the inorganic semiconductors make it possible to form an electric circuit in an extremely small area and an extremely small volume and exhibit various functions such as light emission, electric power generation, imaging, or recording.

Recently, as described above, electronic apparatuses each using an organic semiconductor in place of an inorganic semiconductor have been developed. In a case where various semiconductor elements are fabricated with use of organic semiconductors, a further improvement is desired depending on usage. For example, in order to put an electronic apparatus into practical use, it is desired to optimize a plurality of characteristics of a semiconductor element typified by a photoelectric conversion element (specifically, an imaging element) and a light-emitting element in accordance with a product need. As one example, in the photoelectric conversion element (specifically, the imaging element), in addition to photoelectric conversion characteristics, dark-current characteristics and afterimage characteristics are important element characteristics. However, there is an issue that it is difficult to achieve the above-described element characteristics at a high level in a well-balanced manner in a case where an organic semiconductor is simply used. In addition, for the light-emitting element, characteristics in which light is emitted at a low voltage with high efficiency are important. Even in this case, it is difficult to achieve respective characteristics in a well-balanced manner.

For example, an organic semiconductor having high crystallinity has high intermolecular interaction, and has a superior potential for electric charge transportability. However, in a case where a thin film is formed by using the organic semiconductor having high crystallinity alone or by mixing the organic semiconductor with another material, aggregation occurs, and it is difficult to form a high-quality thin film, which does not make it possible to take full advantage of the potential. As a result, the semiconductor element using a thin film that includes the organic semiconductor having high crystallinity has an issue that favorable electrical characteristics are not obtainable.

Meanwhile, an organic semiconductor having low intermolecular interaction makes it possible to form a high-quality thin film having superior flatness, but has low electric charge mobility. Accordingly, many semiconductor elements using the organic semiconductor having low intermolecular interaction are not able to obtain expected electrical characteristics.

In contrast, in the present embodiment, at least one of the benzodithiophene derivative represented by the above-described general formula (1) or the naphthodithiophene derivative represented by the above-described general formula (2) is used to form the p-buffer layer 14. The benzodithiophene derivative represented by the above-described general formula (1) and the naphthodithiophene derivative represented by the above-described general formula (2) have a moderate crystal density in a case where organic semiconductor powder that forms the thin film is subjected to X-ray structural analysis, and have a broad peak in a case where a thin film formed using only one of them is subjected to XRD measurement. Thus, the p-buffer layer 14 having moderate intermolecular interaction is formed, and it is possible to form a favorable thin film having less aggregation and less film defects. This leads to an improvement in carrier (hole) mobility in the thin film.

As described above, in the photoelectric conversion element 10 according to the present embodiment, the p-buffer layer 14 is formed using at least one of the benzodithiophene derivative represented by the above-described general formula (1) or the naphthodithiophene derivative represented by the above-described general formula (2) that has moderate interaction between molecules in a layer, which improves carrier (hole) mobility in the p-buffer layer 14. This makes it possible to improve, for example, external quantum efficiency and element characteristics such as afterimage characteristics.

In addition, in the photoelectric conversion element 10 according to the present embodiment, by using the benzodithiophene derivative represented by the above-described general formula (1) and the naphthodithiophene derivative represented by the above-described general formula (2) that have a HOMO level of 6.0±0.5 eV, more preferably a HOMO level of 6.0±0.2 eV, and still more preferably a HOMO level of 6.0±0.1 eV, carriers are transported between the photoelectric conversion layer 13 and the work function adjustment layer 15 more smoothly. This makes it possible to further improve the element characteristics.

Next, description is given of modification examples 1 to 4 of the first embodiment described above, and a second embodiment. It is to be noted that components corresponding to the photoelectric conversion element 10 and the imaging element 1A according to the first embodiment described above are denoted by same reference numerals and description thereof is omitted.

### 2. Modification Examples

### 2-1. Modification Example 1

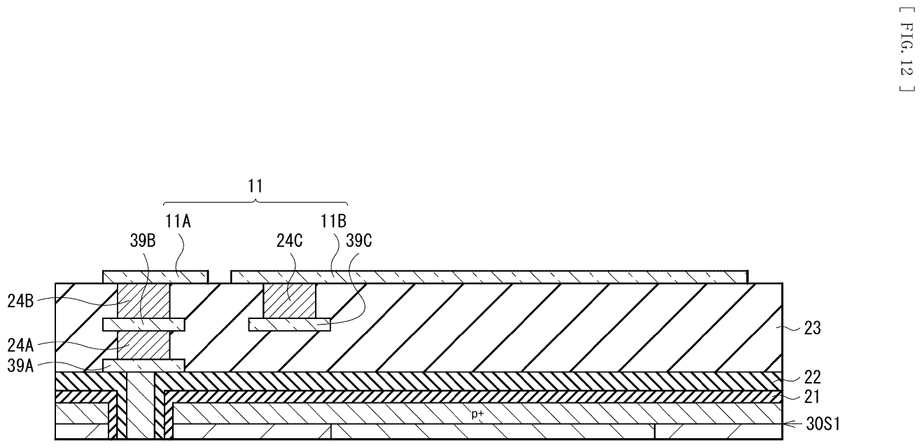

FIG. 15 schematically illustrates a cross-sectional configuration of an imaging element 1B according to the modification example 1 of the present disclosure. The imaging element 1B is, for example, an imaging element such as a CMOS image sensor used for an electronic apparatus such as a digital still camera or a video camera, as with the imaging element 1A according to the first embodiment described above. The imaging element 1B according to the present modification example includes two organic photoelectric converters 10 and 80, and one inorganic photoelectric converter 32 that are stacked in the longitudinal direction.

The organic photoelectric converters 10 and 80 and the inorganic photoelectric converter 32 perform photoelectric conversion by selectively detecting respective pieces of light in different wavelength ranges. For example, the organic photoelectric converter 10 acquires a color signal of green (G). For example, the organic photoelectric converter 80 acquires a color signal of blue (B). For example, the inorganic photoelectric converter 32 acquires a color signal of red (R). This allows the imaging element 1B to acquire a plurality of types of color signals in one pixel without using any color filter.

The organic photoelectric converters 10 and 80 each have a configuration similar to that of the imaging element 1A according to the first embodiment described above. Specifically, in the organic photoelectric converter 10, the lower electrode 11, the n-buffer layer 12, the photoelectric conversion layer 13, the p-buffer layer 14, the work function adjustment layer 15, and the upper electrode 16 are stacked in this order, as with the imaging element 1A. The lower electrode 11 includes a plurality of electrodes (e.g., the readout electrode 11A and the accumulation electrode 11B). The insulating layer 17 and the semiconductor layer 18 are stacked in this order between the lower electrode 11 and the n-buffer layer 12. In the lower electrode 11, the readout electrode 11A is electrically coupled to the semiconductor layer 18 through the opening 17H provided in the insulating layer 17. In the organic photoelectric converter 80, as with the organic photoelectric converter 10, a lower electrode 81, an n-buffer layer 82, a photoelectric conversion layer 83, a p-buffer layer 84, a work function adjustment layer 85, and an upper electrode 86 are stacked in this order. The lower electrode 81 includes a plurality of electrodes (e.g., a readout electrode 81A and an accumulation electrode 81B). An insulating layer 87 and a semiconductor layer 88 are stacked in this order between the lower electrode 81 and the n-buffer layer 82. In the lower electrode 81, the readout electrode 81A is electrically coupled to the semiconductor layer 88 through an opening 87H provided in the insulating layer 87.

A through electrode 34Y is coupled to the readout electrode 81A. The through electrode 34Y penetrates through an interlayer insulating layer 89 and the organic photoelectric converter 10, and is electrically coupled to the readout electrode 11A of the organic photoelectric converter 10. Furthermore, the readout electrode 81A is electrically coupled to the floating diffusion FD provided in the semiconductor substrate 30 via through electrodes 34X and 34Y, and is allowed to temporarily accumulate electric charges generated in the photoelectric conversion layer 83. Furthermore, the readout electrode 81A is electrically coupled to the amplifier transistor AMP and the like provided in the semiconductor substrate 30 through the through electrodes 34X and 34Y.

### 2-2. Modification Example 2

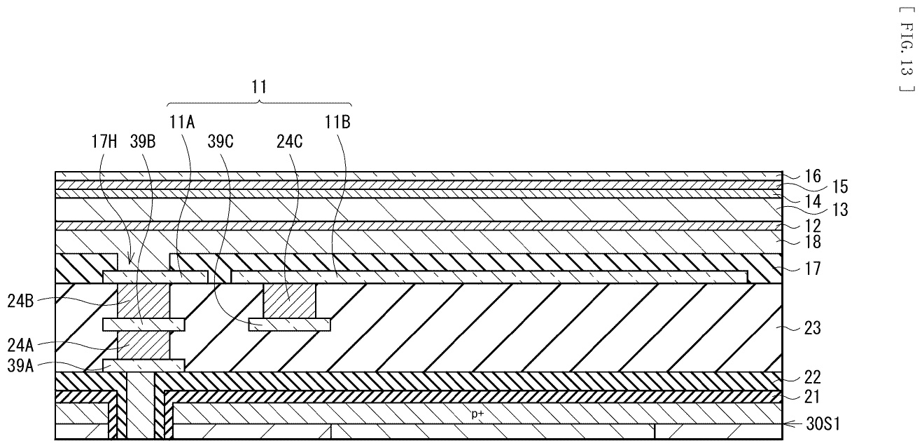

FIG. 16 illustrates a cross-sectional configuration of an imaging element 1C according to the modification example 2 of the present disclosure. The imaging element 1C is, for example, an imaging element such as a CMOS image sensor used for an electronic apparatus such as a digital still camera or a video camera, as with the imaging element 1A according to the first embodiment described above. The imaging element 1C according to the present modification example has a configuration in which a red photoelectric converter 70R, a green photoelectric converter 70G, and a blue photoelectric converter 70B are stacked in this order above the semiconductor substrate 30.

The red photoelectric converter 70R, the green photoelectric converter 70G, and the blue photoelectric converter 70B each have a configuration similar to that of the organic photoelectric converter 10 according to the first embodiment described above. Specifically, the red photoelectric converter 70R, the green photoelectric converter 70G, and the blue photoelectric converter 70B respectively include photoelectric conversion layers 73R, 73G, and 73B between a pair of electrodes, specifically, between an lower electrode 71R and an upper electrode 76R, between a lower electrode 71G and an upper electrode 76G, and between a lower electrode 71B and an upper electrode 76B. The red photoelectric converter 70R, the green photoelectric converter 70G, and the blue photoelectric converter 70B respectively include n-buffer layers 72R, 72G, and 72B between the lower electrode 71R and the photoelectric conversion layer 73R, between the lower electrode 71G and the photoelectric conversion layer 73G, and between the lower electrode 71B and the photoelectric conversion layer 73B, as with the first embodiment described above. The red photoelectric converter 70R, the green photoelectric converter 70G, and the blue photoelectric converter 70B respectively include p-buffer layers 74R, 74G, and 74B and work function adjustment layers 75R, 75G, and 75B between the upper electrode 76R and the photoelectric conversion layer 73R, between the upper electrode 76G and the photoelectric conversion layer 73G, and between the upper electrode 76B and the photoelectric conversion layer 73B, as with the first embodiment described above.

In the imaging element 1C, as described above, the red photoelectric converter 70R, the green photoelectric converter 70G, and the blue photoelectric converter 70B are stacked in this order above the semiconductor substrate 30. Accordingly, light of a shorter wavelength is efficiently absorbed at an incident surface.

The red photoelectric converter 70R is stacked on the semiconductor substrate 30 with an insulating layer 77 interposed therebetween. The green photoelectric converter 70G is stacked on the red photoelectric converter 70R with an insulating layer 78 interposed therebetween. The blue photoelectric converter 70B is stacked on the green photoelectric converter 70G with an insulating layer 79 interposed therebetween. The protective layer 51 and an on-chip lens layer 52 having the on-chip lens 52L are provided in this order on the blue photoelectric converter 70B.

A red electricity storage layer 310R, a green electricity storage layer 310G, and a blue electricity storage layer 310B are provided in the semiconductor substrate 30. Light having entered the on-chip lens 52L is photoelectrically converted by the red photoelectric converter 70R, the green photoelectric converter 70G, and the blue photoelectric converter 70B, and signal electric charges are transmitted from the red photoelectric converter 70R to the red electricity storage layer 310R, from the green photoelectric converter 70G to the green electricity storage layer 310G, and from the blue photoelectric converter 70B to the blue electricity storage layer 310B.

The semiconductor substrate 30 includes, for example, a p-type silicon substrate. The red electricity storage layer 310R, the green electricity storage layer 310G, and the blue electricity storage layer 310B provided in this semiconductor substrate 30 each include an n-type semiconductor region and signal electric charges (electrons) supplied from the red photoelectric converter 70R, the green photoelectric converter 70G, and the blue photoelectric converter 70B are accumulated in these n-type semiconductor regions. The n-type semiconductor regions of the red electricity storage layer 310R, the green electricity storage layer 310G, and the blue electricity storage layer 310B are formed, for example, by doping the semiconductor substrate 30 with an n-type impurity such as phosphorus (P) or arsenic (As). It is to be noted that the semiconductor substrate 30 may be provided on a support substrate (not illustrated) including glass or the like.

The semiconductor substrate 30 is provided with a pixel transistor for reading out electrons from each of the red electricity storage layer 310R, the green electricity storage layer 310G, and the blue electricity storage layer 310B and transferring the electrons, for example, to a vertical signal line (e.g., a vertical signal line Lsig in FIG. 24 to be described below). A floating diffusion of this pixel transistor is provided in the semiconductor substrate 30, and this floating diffusion is coupled to the red electricity storage layer 310R, the green electricity storage layer 310G, and the blue electricity storage layer 310B. The floating diffusion includes an n-type semiconductor region.

The insulating layers 77, 78, and 79 each include, for example, silicon oxide, silicon nitride, silicon oxynitride, hafnium oxide, or the like. The insulating layers 77, 78, and 79 may each include a stacked film in which a plurality of kinds of insulating films is stacked. The insulating layer 77 may be formed using an organic insulating material. The insulating layer 77 is provided with respective plugs and respective electrodes for coupling the red electricity storage layer 310R and the red photoelectric converter 70R, coupling the green electricity storage layer 310G and the green photoelectric converter 70G, and coupling the blue electricity storage layer 310B and the blue photoelectric converter 70B. The insulating layers 78 and 79 may be formed using a metal oxide, a metal sulfide, or an organic substance, in addition to the material described above. Examples of the metal oxide include aluminum oxide, zirconium oxide, titanium oxide, zinc oxide, tungsten oxide, magnesium oxide, niobium oxide, tin oxide, gallium oxide, and the like. Examples of the metal sulfide include zinc sulfide, magnesium sulfide, and the like. It is preferable that the band gap of materials included in the insulating layers 78 and 79 be 3.0 eV or more.

As described above, the present technology is not limited to an element structure in which one organic photoelectric converter 10 and two inorganic photoelectric converters 32B and 32R are stacked in the longitudinal direction as with the imaging element 1A according to the first embodiment described above. The present technology is applicable to the imaging element 1B in which two organic photoelectric converters 10 and 80 and one inorganic photoelectric converter 32 are stacked in the longitudinal direction, and the imaging element 1C in which three organic photoelectric converters (the red photoelectric converter 70R, the green photoelectric converter 70G, and the blue photoelectric converter 70B) are stacked in the longitudinal direction as with the modification examples 1 and 2, which makes it possible to achieve effects similar to those in the first embodiment described above.

### 2-2. Modification Example 3

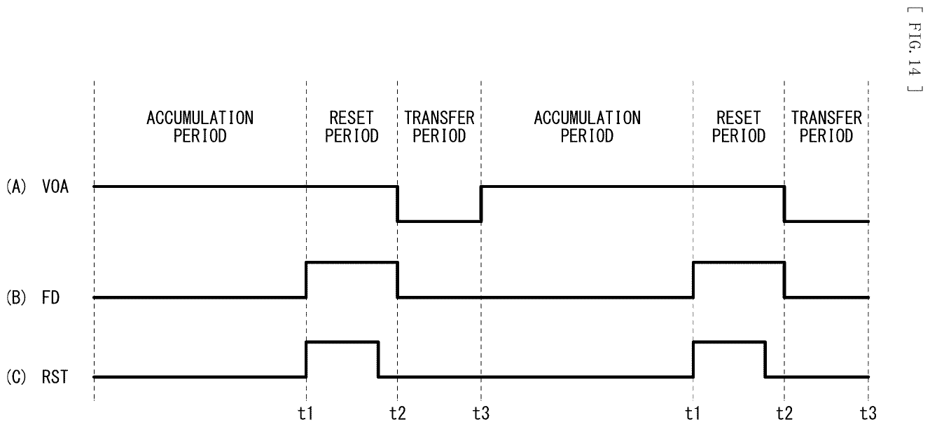

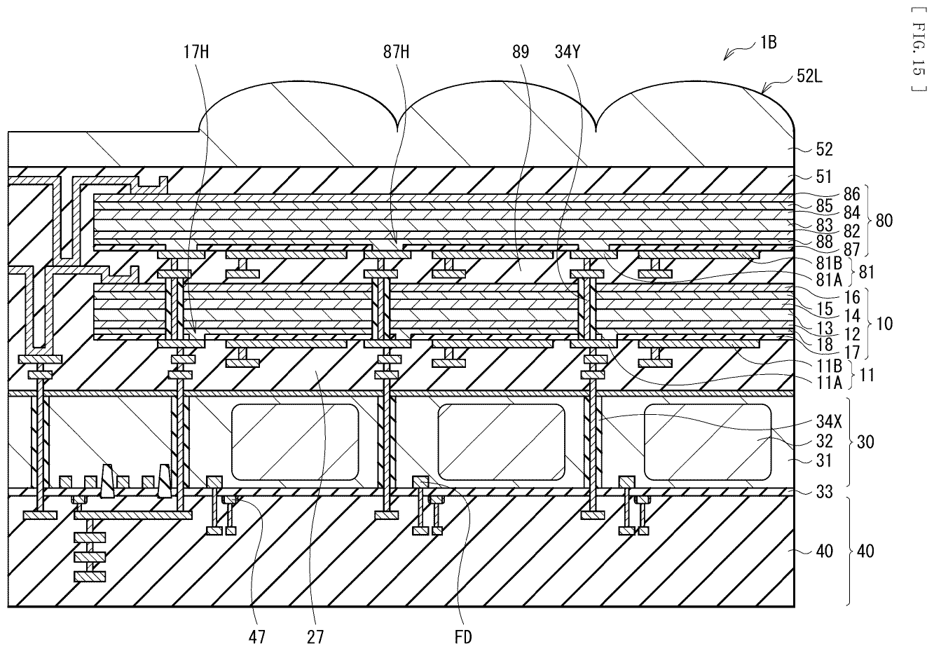

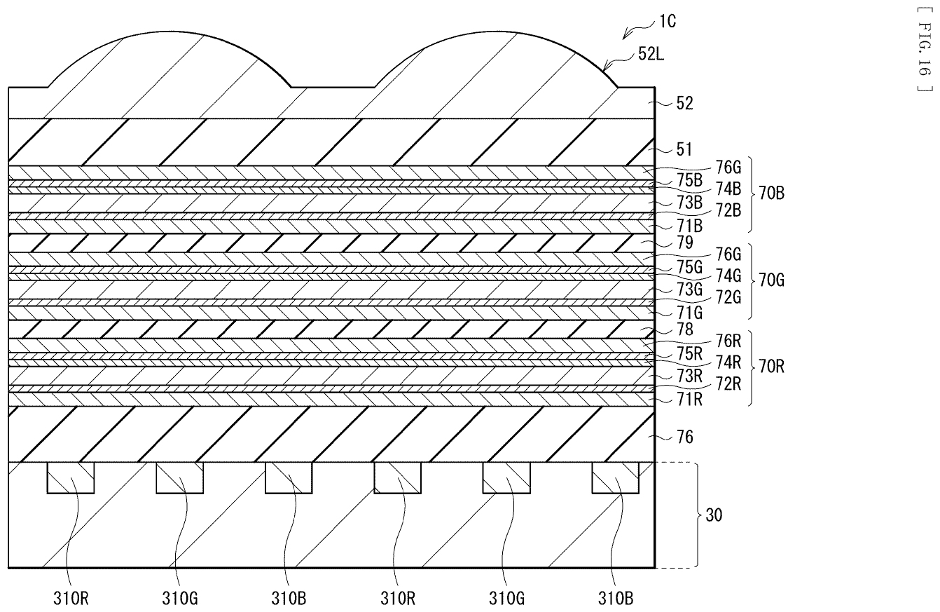

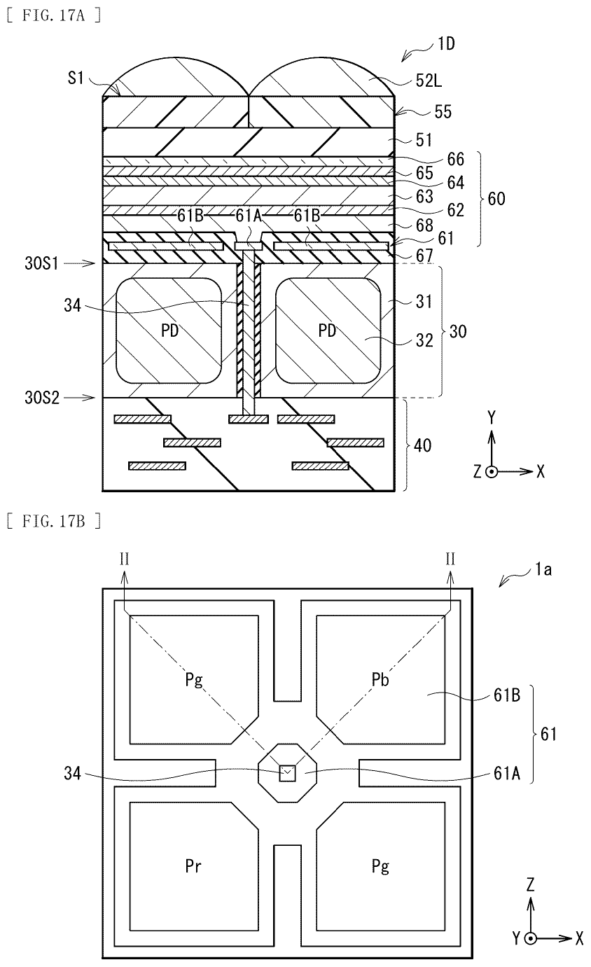

FIG. 17A schematically illustrates a cross-sectional configuration of an imaging element 1D according to the modification example 3 of the present disclosure. FIG. 17B schematically illustrates an example of a planar configuration of the imaging element 1D illustrated in FIG. 17A. FIG. 17A illustrates a cross section taken along a line II-II illustrated in FIG. 17B. The imaging element 1D is, for example, a stacked imaging element in which an inorganic photoelectric converter 32 and an organic photoelectric converter 60 are stacked. In the pixel section 100A of an imaging device (e.g., the imaging device 100) including this imaging element 1D, the pixel units 1a are repeatedly disposed as repeating units in an array having the row direction and the column direction. Each of the pixel units 1a includes four pixels that are disposed, for example, in two rows and two columns as illustrated in FIG. 17B.

The imaging element 1D according to the present modification example is provided with color filters 55 above the organic photoelectric converter 60 (light incidence side Si) for the respective unit pixels P. The color filters 55 allow the red light (R), green light (G), and the blue light (B) to selectively pass therethrough. Specifically, in the pixel unit 1a including four pixels disposed in two rows and two columns, two color filters each of which allows the green light (G) to selectively pass therethrough are disposed on a diagonal line and one color filter that allows the red light (R) to selectively pass therethrough and one color filter that allows the blue light (B) to selectively pass therethrough are disposed on a diagonal line orthogonal to the diagonal line. In each of the unit pixels (Pr, Pg, and Pb) each provided with a corresponding one of the color filters, corresponding color light is detected, for example, in the organic photoelectric converter 60. In other words, the pixels (Pr, Pg, and Pb) that respectively detect the red light (R), the green light (G), and the blue light (B) are arranged in a Bayer pattern in the pixel section 100A.

The organic photoelectric converter 60 absorbs, for example, light corresponding to some or all of wavelengths in the visible light region of 400 nm or more and less than 750 nm and generates excitons (electron-hole pairs). The organic photoelectric converter 60 includes a lower electrode 61, an insulating layer (interlayer insulating layer 67), a semiconductor layer 68, an n-buffer layer 62, a photoelectric conversion layer 63, a p-buffer layer 64, a work function adjustment layer 65, and an upper electrode 66 that are stacked in this order. The lower electrode 61, the interlayer insulating layer 67, the semiconductor layer 68, the n-buffer layer 62, the photoelectric conversion layer 63, the p-buffer layer 64, the work function adjustment layer 65, and the upper electrode 66 respectively have configurations similar to the lower electrode 11, the insulating layer 17, the semiconductor layer 18, the n-buffer layer 12, the photoelectric conversion layer 13, the p-buffer layer 14, the work function adjustment layer 15, and the upper electrode 16 of the imaging element 1A according to the first embodiment described above. The lower electrode 61 includes, for example, a readout electrode 61A and an accumulation electrode 61B independently of each other, and the readout electrode 61A is shared by, for example, four pixels.

The inorganic photoelectric converter 32 detects, for example, an infrared region of 750 nm or more and 1300 nm or less.

In the imaging element 1D, each light (the red light (R), the green light (G), and the blue light (B)) in the visible light region of light having passing through the color filter 55 is absorbed by the organic photoelectric converter 60 of a corresponding one of the unit pixels (Pr, Pg, and Pb) provided with the color filters, and light other than the light, for example, infrared light (IR) passes through the organic photoelectric converter 60. The infrared light (IR) having passed through the organic photoelectric converter 60 is detected by the inorganic photoelectric converter 32 of a corresponding one of the unit pixels Pr, Pg, and Pb. Each of the unit pixels Pr, Pg, and Pb generates signal electric charges corresponding to the infrared light (IR). In other words, the imaging device 100 including the imaging element 1D is able to concurrently generate both a visible light image and an infrared light image.

In addition, in the imaging element 1D, the pixels (Pr, Pg, and Pb) that detect the red light (R), the green light (G), and the blue light (B) are arranged in the Bayer pattern, which makes it possible to ease spectral characteristics of the red light (R), the green light (G), and the blue light (B) desired by respective photoelectric converters, as compared with the longitudinal spectral type imaging element (e.g., the imaging elements 1A, 1B, and 1C) according to the first embodiment described above and the like. Thus, it is possible to improve mass productivity.

### 2-4. Modification Example 4

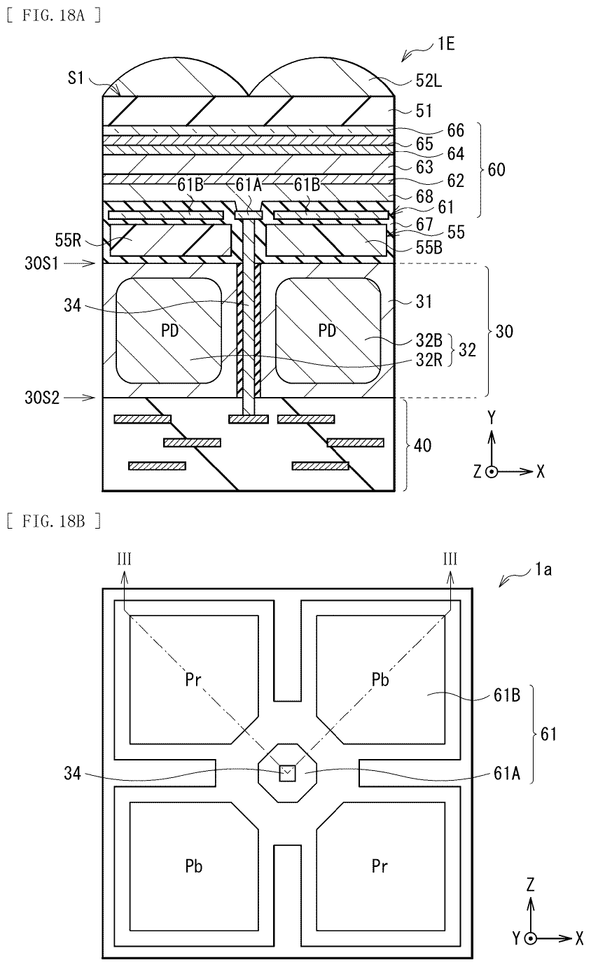

FIG. 18A schematically illustrates a cross-sectional configuration of an imaging element 1E according to the modification example 4 of the present disclosure. FIG. 18B schematically illustrates an example of a planar configuration of the imaging element 1E illustrated in FIG. 18A. FIG. 18A illustrates a cross section taken along a line III-III illustrated in FIG. 18B. In the modification example 3 described above, an example has been described in which the color filter 55 is provided above the organic photoelectric converter 60 (light incidence side Si); however, the color filter 55 may be provided, for example, between inorganic photoelectric converter 32 and the organic photoelectric converter 60, as illustrated in FIG. 18A.

In the imaging element 1E, the color filter 55 has a configuration in which color filters (color filters 55R) that allow at least the red light (R) to selectively pass therethrough and color filters (color filters 55B) that allow at least the blue light (B) to selectively pass therethrough are disposed diagonally to each other in the pixel unit 1a. The organic photoelectric converter 60 (photoelectric conversion layer 63) is configured to selectively absorb, for example, a wavelength corresponding to the green light (G). This allows the organic photoelectric converters 60 and the inorganic photoelectric converters 32 (inorganic photoelectric converters 32R and 32G) respectively disposed below the color filters 55R and 55B to acquire a signal corresponding to the red light (R), the green light (G), or the blue light (B). The imaging element 1E according to the present modification example allows the respective photoelectric converters of R, G, and B to each have a larger area than that in a photoelectric conversion element having a typical Bayer arrangement. This makes it possible to increase an S/N ratio.

It is to be noted that in the modification examples 3 and 4 described above, an example has been described in which the lower electrode 61 included in the organic photoelectric converter 60 includes a plurality of electrodes (the readout electrode 61A and the accumulation electrode 61B); however, the present modification example is applicable to a case where the lower electrode includes one electrode for each unit pixel P, and it is possible to achieve effects similar to those in the present modification example.

### 3. Second Embodiment

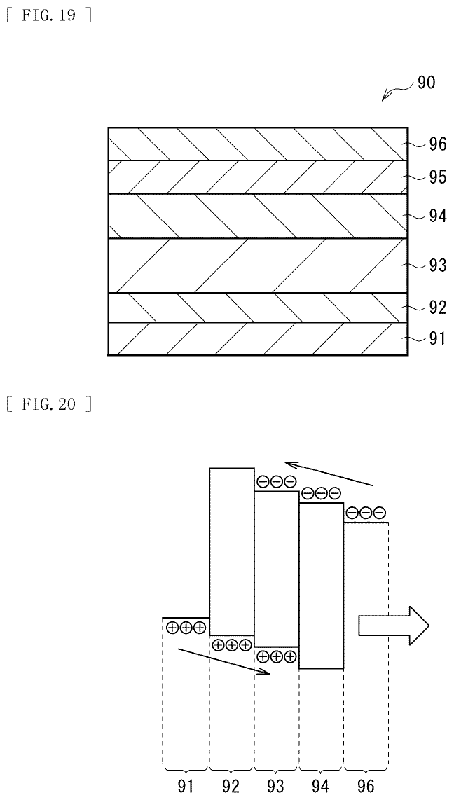

FIG. 19 schematically illustrates an example of a cross-sectional configuration of a light-emitting element (light-emitting element 90) according to a second embodiment of the present disclosure. The light-emitting element 90 is, for example, a so-called organic electroluminescent element (organic EL element) used as a light source in an organic EL television device or the like. The light-emitting element 90 according to the present embodiment corresponds to a specific example of a “semiconductor element” of the present disclosure, and includes an organic semiconductor layer (a hole transport layer 92 or a light-emitting layer 93, or both) formed including at least one of the benzodithiophene derivative represented by the general formula (1) or the naphthodithiophene derivative represented by the general formula (2) described in the first embodiment described above.

### 3-1. Configuration of Light-emitting Element

For example, as illustrated in FIG. 20, in the light-emitting element 90, an organic stacked film including the light-emitting layer 93 is sandwiched between a pair of electrodes opposed to each other, and the light-emitting element 90 is caused to recombine holes and electrons in the light-emitting layer 93 by voltage application, thereby emitting light. The light-emitting element 90 has, for example, a configuration in which an anode 91, the hole transport layer 92, the light-emitting layer 93, an electron transport layer 94, an electron injection layer 95, and a cathode 96 are stacked in this order.

The anode 91 is for injecting holes into the light-emitting layer 93. The anode 91 includes, for example, an electrically conductive film having light transmissivity. Examples of a material included in the anode 91 include indium tin oxide (ITO) that is In₂O₃ to which tin (Sn) is added as a dopant. The ITO thin film may have high crystallinity or low crystallinity (close to amorphous). In addition to the above-described material, examples of the material included in the anode 91 include a tin oxide (SnO₂)-based material to which a dopant is added, for example, ATO to which Sb is added as a dopant, and FTO to which fluorine is added as a dopant. In addition, zinc oxide (ZnO) or a zinc oxide-based material obtained by adding a dopant may be used. Examples of the ZnO-based material include aluminum zinc oxide (AZO) to which aluminum (Al) is added as a dopant, gallium zinc oxide (GZO) to which gallium (Ga) is added, boron zinc oxide to which boron (B) is added, and indium zinc oxide (IZO) to which indium (In) is added. Furthermore, zinc oxides (IGZO, In—GaZnO₄) to which indium and gallium are added as dopants may be used. In addition, as the material included in the anode 91, CuI, InSbO₄, ZnMgO, CuInO₂, MgIN₂O₄, CdO, ZnSnO₃, TiO₂, or the like may be used, and a spinel oxide or an oxide having a YbFe₂O₄ structure may be used. In addition, examples of the material included in the anode 91 include an electrically-conductive material containing gallium oxide, titanium oxide, niobium oxide, nickel oxide, or the like as a main component.

In addition, in a case where the anode 91 does not need light transmissivity (e.g., a case where light is extracted from side of the cathode 96), it is possible to use a single metal or an alloy having a high work function (e.g., ϕ=4.5 eV to 5.5 eV). Specific examples thereof include Al—Nd (an alloy of aluminum and neodymium) and ASC (an ally of aluminum, samarium, and copper). In addition, examples of the material included in the anode 91 include Au, Ag, Cr, Ni, Pd, Pt, Fe, Ir, Ge, Os, Re, Te, and alloys thereof.

Furthermore, examples of the material included in the anode 91 include electrically-conductive materials, including metals such as Pt, Au, Pd, Cr, Ni, Al, Ag, Ta, W, Cu, Ti, In, Sn, Fe, Co, and Mo, alloys including these metal elements, electrically-conductive particles including these metals, electrically-conductive particles of alloys including these metals, polysilicon including impurities, carbon-based materials, oxide semiconductors, carbon nanotubes, graphene, and the like.

The anode 91 has, for example, a thickness of 2×10⁻⁸ m or more and 2×10⁻⁷ m or less, preferably 3×10⁻⁸ m or more and 1.5×10⁻⁷ m or less.

The hole transport layer 92 is for improving electrical coupling between the anode 91 and the light-emitting layer 93. In addition, the hole transport layer 92 is for adjusting light interference of the light-emitting element 90. It is possible to form the hole transport layer 92 using at least one of the benzodithiophene derivative represented by the general formula (1) or the naphthodithiophene derivative represented by the general formula (2) described in the first embodiment described above.

The hole transport layer 92 may include a single layer film or a stacked film including one kind or two or more kinds of the following materials together with the benzodithiophene derivative represented by the general formula (1) and the naphthodithiophene derivative represented by the general formula (2). Examples of another material included in the hole transport layer 92 include an aromatic amine-based material, a carbazole derivative, an indolocarbazole derivative, a naphthalene derivative, an anthracene derivative, a phenanthrene derivative, a pyrene derivative, a perylene derivative, a tetracene derivative, a pentacene derivative, a perylene derivative, a picene derivative, a chrysene derivative, a fluoranthene derivative, a phthalocyanine derivative, a subphthalocyanine derivative, a hexaazatriphenylene derivative, a metal complex including a heterocyclic compound as a ligand, a thiophene derivative, a thienothiophene derivative, a benzothiophene derivative, a thienoacene-based material, poly(3,4-ethylenedioxythiophene)/polystyrenesulfonic acid [PEDOT/PSS], and polyaniline. In addition, examples of another material included in the hole transport layer 92 include metal oxides such as molybdenum oxide (MoOₓ), ruthenium oxide (RuOₓ), vanadium oxide (VOₓ), and tungsten oxide (WOₓ). Examples of the aromatic amine-based material include a triarylamine compound, a benzidine compound, and a styrylamine compound. Examples of the thienoacene-based material include a benzothienobenzothiophene (BTBT) derivative, a dinaphthothienothiophene (DNTT) derivative, a dianthracenthienothhenophene (DATT) derivative, a benzobisbenzothiophene (BBBT) derivative, a thienobisbenzothiophene (TBBT) derivative, a dibenzothienobisbenzothiophene (DBTBT) derivative, a dithienobenzodithiophene (DTBDT) derivative, a dibenzothienodithiophene (DBTDT) derivative, a benzodithiophene (BDT) derivative, a naphthodithiophene (NDT) derivative, an anthracenodithiophene (ADT) derivative, a tetracenodithiophene (TDT) derivative, and a pentacenodithiophene (PDT) derivative. Among the materials described above, the thienoacene-based material is preferably used as another material included in the hole transport layer 92.

It is to be noted that the hole transport layer 92 may be formed using a material other than the benzodithiophene derivative represented by the general formula (1) and the naphthodithiophene derivative represented by the general formula (2). In this case, it is preferable to use the materials described as another material described above.

The hole transport layer 92 has, for example, a thickness of 5×10⁻⁹ m or more and 5×10⁻⁷ m or less, preferably 5×10⁻⁹ m or mor and 2×10⁻⁷ m or less, and still more preferably 5×10⁻⁹ m or more and 1×10⁻⁷ m or less.

The light-emitting layer 93 is a region in which holes injected from the anode 91 and electrons injected from the cathode 96 are recombined upon application of an electric field to the anode 91 and the cathode 96. The light-emitting layer 93 may include, for example, one kind of material or a combination of two or more kinds of materials. Two kinds included in the light-emitting layer 93 refer to a host material and a dopant material. In the typical light-emitting layer 93, it is possible to obtain desired light emission by recombining holes and electrons in the host material and transferring energy generated at that time to the dopant material. The light-emitting layer 93 has, for example, a film density of 1.20 g/cm³ or more.

Examples of a specific host material include the benzodithiophene derivative represented by the general formula (1) and the naphthodithiophene derivative represented by the general formula (2) described in the first embodiment described above. It is preferable to use the compound represented by the formula (1-1) and the compound represented by the formula (2-1) among them.

In addition, it is possible to use a p-type organic semiconductor (hereinafter referred to as a p-type semiconductor) as the host material. Examples of the p-type semiconductor include thienoacene-based materials typified by a naphthalene derivative, an anthracene derivative, a phenanthrene derivative, a pyrene derivative, a perylene derivative, a tetracene derivative, a pentacene derivative, a quinacridone derivative, a thiophene derivative, a thienothiophene derivative, a benzothiophene derivative, a benzothienobenzothiophene (BTBT) derivative, a dinaphthothienothiophene (DNTT) derivative, a dianthracenthienothhenophene (DATT) derivative, a benzobisbenzothiophene (BBBT) derivative, a thienobisbenzothiophene (TBBT) derivative, a dibenzothienobisbenzothiophene (DBTBT) derivative, a dithienobenzodithiophene (DTBDT) derivative, a dibenzothienodithiophene (DBTDT) derivative, a benzodithiophene (BDT) derivative, a naphthodithiophene (NDT) derivative, an anthracenodithiophene (ADT) derivative, a tetracenodithiophene (TDT) derivative, and a pentacenodithiophene (PDT) derivative. In addition, examples of the p-type semiconductor include a triarylamine derivative, a carbazole derivative, a picene derivative, a chrysene derivative, for example, a fluoranthene derivative, a phthalocyanine derivative, a subphthalocyanine derivative, a subporphyrazine derivative, a metal complex including a heterocyclic compound as a ligand, a polythiophene derivative, a polybenzothiadiazole derivative, a polyfluorene derivative, and the like.

In addition, as the host material, it is possible to use an n-type organic semiconductor (hereinafter referred to as an n-type semiconductor). Examples of the n-type semiconductor include fullerenes typified by higher fullerenes such as fullerene C₆₀, fullerene C₇₀, and fullerene C₇₄, endohedral fullerene, and the like, and derivatives thereof. Examples of a substituent group included in fullerene derivatives include a halogen atom, a straight-chain, branched, or cyclic alkyl group or phenyl group, a group including a straight-chain or condensed aromatic compound, a group including a halide, a partial fluoroalkyl group, a perfluoroalkyl group, a silyl alkyl group, a silyl alkoxy group, an aryl silyl group, an aryl sulfanyl group, an alkyl sulfanyl group, an aryl sulfonyl group, an alkyl sulfonyl group, an aryl sulfide group, an alkyl sulfide group, an amino group, an alkyl amino group, an aryl amino group, a hydroxy group, an alkoxy group, an acyl amino group, an acyloxy group, a carbonyl group, a carboxy group, a carboxamide group, a carboalkoxy group, an acyl group, a sulfonyl group, a cyano group, a nitro group, a group including a chalcogenide, a phosphine group, a phosphone group, and derivatives thereof. Examples of specific fullerene derivatives include fullerene fluoride, a PCBM fullerene compound, a fullerene multimer, and the like. In addition, examples of the n-type semiconductor include an organic semiconductor having a HOMO level and a LUMO level that are larger (deeper) than those of the p-type organic semiconductor, and an inorganic metal oxide having light transmissivity.

Examples of the n-type organic semiconductor include a heterocyclic compound containing a nitrogen atom, an oxygen atom, or a sulfur atom. Specific examples thereof include organic molecules including, as a part of a molecular framework, a pyridine derivative, a pyrazine derivative, a pyrimidine derivative, a triazine derivative, a quinoline derivative, a quinoxaline derivative, an isoquinoline derivative, an acridine derivative, a phenazine derivative, a phenanthroline derivative, a tetrazole derivative, a pyrazole derivative, an imidazole derivative, a thiazole derivative, an oxazole derivative, an imidazole derivative, a benzimidazol derivative, a benzotriazole derivative, a benzoxazole derivative, a benzoxazole derivative, a carbazole derivative, a benzofuran derivative, a dibenzofuran derivative, a subporphyrazine derivative, a polyphenylene vinylene derivative, a polybenzothiadiazole derivative, and a polyfluorene derivative, an organic metal complex, a subphthalocyanine derivative, a quinacridone derivative, a cyanine derivative, and a merocyanine derivative.

It is to be noted that the organic semiconductor is frequently classified into p-type and n-type. The p-type means that holes are easily transported, and the n-type means that electrons are easily transported. Accordingly, the p-type semiconductor and the n-type semiconductor described above is not limited to an interpretation that the p-type semiconductor and the n-type semiconductor have holes or electrons as majority carriers of thermal excitation like inorganic semiconductors.

In addition, changing a molecular structure of the dopant material makes it possible to emit light of various wavelengths from the visible light region to the near-infrared region. Examples of the dopant material include a styrylbenzene derivative, an oxazole derivative, a perylene derivative, a coumarin derivative, an acridine derivative, an anthracene derivative, a naphthacene derivative, a pentacene derivative, a chrysene derivative, a diketopyrrolopyrrole derivative, a pyrromethene framework compound, a metal complex, a quinacridone derivative, a cyanomethylenepyran-based derivative (DCM, DCJTB), a benzothiazole derivative, a benzoimidazol derivative, a metal chelated oxinoid compound, and the like. In addition, examples of the dopant material include a phosphorescent compound (phosphorescent dopant). The phosphorescent compound is a compound that is able to emit light from a triplet exciton. The phosphorescent compound is not specifically limited as long as the phosphorescent compound emits light from a triplet exciton, but is preferably a metal complex including at least one kind of metal selected from a group including Ir, Ru, Pd, Pt, Os, and Re. Specifically, a porphyrin metal complex or an ortho-metallized metal complex is more preferable. Examples of the porphyrin metal complex include a porphyrin platinum complex. A single phosphorescent compound may be used, or a combination of two or more kinds of phosphorescent compounds may be used.

The light-emitting layer 93 has, for example, a thickness of 1×10⁻⁸ m or more and 2×10⁻⁷ m or less, preferably 1×10⁻⁸ m or more and 1×10⁻⁷ m or less, and still more preferably 2.5×10⁻⁸ m or more and 1×10⁻⁷ m or less.

The electron transport layer 94 may be provided between the light-emitting layer 93 and the cathode 96. As a material included in the electron transport layer 94, a material having a work function larger (deeper) than a material used for the hole transport layer 92 is preferable. Examples of such a material include an organic molecule and an organic metal complex including, as a part of a molecular framework, a heterocyclic ring including nitrogen (N), such as pyridine, quinoline, acridine, indole, imidazole, benzimidazol, phenanthroline, naphthalenetetracarboxdiimide, naphthalenedicarboxylic acid monoimide, hexaazatriphenylene, and hexaazatrinaphthylene. Furthermore, it is preferable to use a material having small absorption in the visible light region. In addition, in a case where the electron transport layer 94 is formed with a thin film of about 5×10⁻⁹ m or more and about 2×10⁻⁸ m or less, it is possible to use a fullerene typified by fullerene C₆₀ or fullerene C₇₀ having absorption in the visible light region of 400 nm or more and 700 nm or less, or a derivative thereof.

The electron transport layer 94 has, for example, a thickness of 5×10⁻⁹ m or more and 5×10⁻⁷ m or less, preferably 5×10⁻⁹ m or more and 2×10⁻⁷ m or less, and still more preferably 5×10⁻⁹ m or more and 1×10⁻⁷ m or less.

The electron injection layer 95 is for improving electrical coupling between the electron transport layer 94 and the cathode 96. Examples of a material included in the electron injection layer 95 include poly(3,4-ethylenedioxythiophene)/polystyrenesulfonic acid [PEDOT/PSS], polyaniline, and metal oxides such as MoOₓ, RuOₓ, VOₓ, and WOₓ.

The cathode 96 is for injecting electrons into the light-emitting layer 93. The cathode 96 includes, for example, an electrically-conductive film having light transmissivity, as with the anode 91. Examples of a material included in the cathode 96 include indium tin oxide (ITO) that is In₂O₃ to which tin (Sn) is added as a dopant. The ITO thin film may have high crystallinity or low crystallinity (close to amorphous). In addition to the above-described material, examples of the material included in the cathode 96 include a tin oxide (SnO₂)-based material to which a dopant is added, for example, ATO to which Sb is added as a dopant, and FTO to which fluorine is added as a dopant. In addition, zinc oxide (ZnO) or a zinc oxide-based material obtained by adding a dopant may be used. Examples of the ZnO-based material include aluminum zinc oxide (AZO) to which aluminum (Al) is added as a dopant, gallium zinc oxide (GZO) to which gallium (Ga) is added, boron zinc oxide to which boron (B) is added, and indium zinc oxide (IZO) to which indium (In) is added. Furthermore, zinc oxides (IGZO, In—GaZnO₄) to which indium and gallium are added as dopants may be used. In addition, as the material included in the cathode 96, CuI, InSbO₄, ZnMgO, CuInO₂, MgIN₂O₄, CdO, ZnSnO₃, TiO₂, or the like may be used, and a spinel oxide or an oxide having a YbFe₂O₄ structure may be used. In addition, examples of the material included in the cathode 96 include an electrically-conductive material containing gallium oxide, titanium oxide, niobium oxide, nickel oxide, or the like as a main component. The cathode 96 has, for example, a thickness of 2×10⁻⁸ m or more and 2 ×10⁻⁷ m or less, preferably 3×10⁻⁸ m or more and 1.5×10⁻⁷ m or less.

In addition, the cathode 96 does not need light transmissivity (e.g., a case where light is extracted from side of the anode 91), it is possible to use a single metal or an alloy having a low work function (e.g., ϕ=3.5 eV to 4.5 eV). Specific examples thereof include alkali metals (e.g., Li, Na, K, and the like) and fluorides or oxides thereof, alkaline earth metals (e.g., Mg, Ca, and the like) and fluorides or oxides thereof. In addition, specific examples thereof include Al, an Al—Si—Cu alloy, Zn, Sn, Tl, an Na—K alloy, an Al—Li alloy, a Mg—Ag alloy, rare earth metals such as In and ytterbium (Yb), and alloys thereof.

Furthermore, examples of the material included in the cathode 96 include electrically-conductive materials, including metals such as Pt, Au, Pd, Cr, Ni, Al, Ag, Ta, W, Cu, Ti, In, Sn, Fe, Co, or Mo, alloys including these metal elements, electrically-conductive particles including these metals, electrically-conductive particles of alloys including these metals, polysilicon including impurities, carbon-based materials, oxide semiconductors, carbon nanotubes, graphene, and the like.

It is possible to form the organic layers (the hole transport layer 92, the light-emitting layer 93, the electron transport layer 94, and the electron injection layer 95) included in the light-emitting element 90 described above with use of, for example, a dry film formation method and a wet film formation method. Examples of the dry film formation method include a vacuum deposition method using resistance heating or high frequency heating, and an electron beam (EB) deposition method. In addition, examples of the dry film formation method include various sputtering methods such as a magnetron sputtering method, an RF-DC coupled bias sputtering method, an ECR sputtering method, a facing-target sputtering method, and a high frequency sputtering method, an ion plating method, a laser ablation method, a molecular beam epitaxy method, and a laser transfer method. Furthermore, examples of the dry film formation method include chemical vapor deposition methods such as a plasma CVD method, a thermal CVD method, an MOCVD method, and an optical CVD method. Examples of the wet film formation method include a spin coating method, an ink jet method, a spray coating method, a stamping method, a micro contact printing method, a flexographic printing method, an offset printing method, a gravure printing method, a dipping method, and the like. As patterning, it is possible to use chemical etching such as a shadow mask, laser transfer, and photolithography, and physical etching by ultraviolet light, laser, or the like. As planarization technology, it is possible to use a laser planarization method, a reflow method, or the like.

It is possible to use, for example, the dry film formation method or the wet film formation method for the electrodes (the anode 91 and the cathode 96) included in the light-emitting element 90 described above. Examples of the dry film formation method include a PVD method and a CVD method. Examples of a film formation method using the principle of the PVD method includes a vacuum deposition method, an EB deposition method, various sputtering methods described above, an ion plating method, a laser ablation method, a molecular beam epitaxy method, a laser transfer method, and the like. In addition, examples of the film formation method include various CVD methods described above. Examples of the wet film formation method include an electroplating method and an electroless plating method, in addition to the methods described above. For patterning and the planarization technology, it is possible to use, for example, a CMP method or the like in addition to the methods described above.

It is to be noted that, in addition to the hole transport layer 92, the electron transport layer 94, and the electron injection layer 95, any other layer may be provided between the anode 91 and the light-emitting layer 93 and between the light-emitting layer 93 and the cathode 96. For example, a hole injection layer for facilitating injection of holes from the anode 91 to the hole transport layer 92 may be provided between the anode 91 and the hole transport layer 92. In addition, a second hole transport layer and a second electron transport layer may be respectively provided between the anode 91 and the light-emitting layer 93 and between the light-emitting layer 93 and the cathode 96.

FIG. 21 illustrates an example of energy levels of materials included in respective layers (the anode 91, the hole transport layer 92, the light-emitting layer 93, the electron transport layer 94, the electron injection layer 95, and the cathode 96) of the light-emitting element 90 illustrated in FIG. 19. In the light-emitting element 90, the anode 91 and the cathode 96 respectively inject holes and electrons into the light-emitting layer 93 by voltage application to the anode 91 and the cathode 96, and light is emitted upon recombination of holes and electrons in the light-emitting layer 93.

In order to adjust electrical coupling between the light-emitting layer 93 and each of the anode 91 and the cathode 96 and carrier balance of holes and electrons to be injected into the light-emitting layer 93, it is preferable to respectively provide the hole transport layer 92 and the electron transport layer 94 between the anode 91 and the light-emitting layer 93 and between the cathode 96 and the light-emitting layer 93. For carrier balance adjustment, making the HOMO level of the electron transport layer 94 deeper makes it possible to prevent transfer of holes to side of the cathode 96. In addition, making the LUMO level of the hole transport layer 92 shallower makes it possible to prevent transfer of electrons to side of the anode 91. This makes it possible to increase a recombination rate by confining holes and electrons in the light-emitting layer 93, and improve light emission efficiency.

### 3-2. Configuration of Display Device

FIG. 22 schematically illustrates an example of a planar configuration of a display device (display device 2) using the light-emitting element 90 described above. The display device 2 is, for example, an organic EL television device, and is a top light emission system (top emission system) display device that extracts emitted light generated in the light-emitting layer 93 from side opposite to a drive substrate 211. The display device 2 uses, for example, the light-emitting element 90 that emits white light and a color filter, which makes it possible to extract color light of R (red), G (green), or B (blue).

The display device 2 includes, as a display region 110, a plurality of light-emitting elements 90 arranged in a matrix on the drive substrate 211. A signal line drive circuit 212 and a scanning line drive circuit 213 that are drivers for image display are provided around the display region 110.

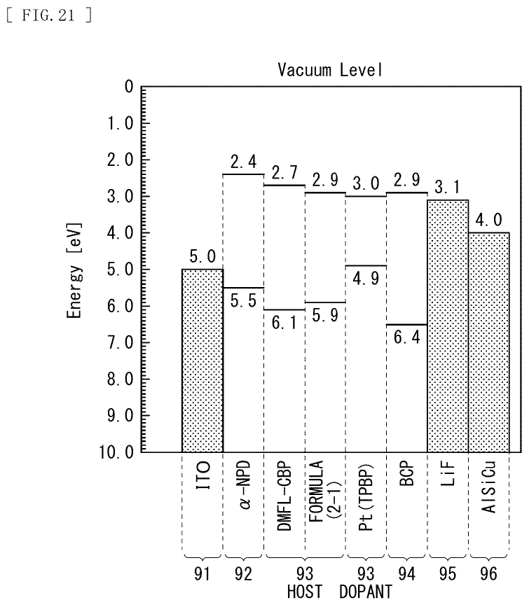

A pixel drive circuit 214 is provided in the display region 110. FIG. 23 illustrates an example of the pixel drive circuit 214. The pixel drive circuit 214 is an active drive circuit formed below the anode 91. In other words, the pixel drive circuit 214 includes a drive transistor Tr1, a write transistor Tr2, a capacitor (retentive capacitor) Cs between the transistors Tr1 and Tr2, and the light-emitting element 90 coupled in series to the drive transistor Tr1 between a first power line (Vcc) and a second power line (GND). The drive transistor Tr1 and the write transistor Tr2 each include a typical thin film transistor (TFT), and a configuration thereof may have, for example, an inverted staggered structure (so-called bottom gate type) or a staggered structure (top gate type), and is not specifically limited.

In the pixel drive circuit 214, a plurality of signal lines 212A is disposed in the column direction, and a plurality of scanning lines 213A is disposed in the row direction. An intersection between each signal line 212A and each scanning line 213A corresponds to one (sub-pixel) of the light-emitting elements 90. Each signal line 212A is coupled to the signal line drive circuit 212, and an image signal is supplied from the signal line drive circuit 212 to a source electrode of the write transistor tr2 through the signal line 212A. Each scanning line 213A is coupled to the scanning line drive circuit 213, and a scanning signal is sequentially supplied from the scanning line drive circuit 213 to a gate electrode of the write transistor Tr2 through the scanning line 213A.

In this display device 2, the scanning signal is supplied from the scanning line drive circuit 213 to each pixel through the gate electrode of the write transistor Tr2, and the image signal is held in the retentive capacitor Cs from the signal line drive circuit 212 through the write transistor Tr2. In other words, on/off of the drive transistor Tr1 is controlled in accordance with a signal held in the retentive capacitor Cs, which causes a drive current Id to be injected into the light-emitting element 90, thereby emission of light by recombination of holes and electrons. This light passes through the anode 91 and the drive substrate 211 in case of bottom light emission (bottom emission), and passes through the cathode 96, the color filter, and a counter substrate in a case of top light emission (top emission), and is extracted.

### 2-3. Workings and Effects

In the light-emitting element 90 according to the embodiment, one or both of the hole transport layer 92 and the light-emitting layer 93 are formed using at least one of the benzodithiophene derivative represented by the general formula (1) or the naphthodithiophene derivative represented by the general formula (2). Thus, the hole transport layer 92 and the light-emitting layer 93 having moderate intermolecular interaction are formed. This is described below.

Recently, research and development of electronic devices using organic semiconductors having high crystallinity have been progressing. A material having high crystallinity has high intermolecular interaction, and has a superior potential for carrier transportability. However, in a case where a thin film is formed by using the material having high crystallinity alone or by mixing the material with another material, aggregation occurs, and it is difficult to form a high-quality thin film. As a result, the element using the thin film has an issue that it is not possible to take full advantage of the potential and it is not possible to obtain favorable electrical characteristics. Meanwhile, using a material having weak intermolecular interaction makes it possible to form a high-quality thin film having superior flatness, but has low mobility. In a case where the element is formed using the thin film, expected electrical characteristics are not obtained.

In contrast, in the present embodiment, one or both of the hole transport layer 92 and the light-emitting layer 93 are formed using at least one of the benzodithiophene derivative represented by the general formula (1) or the naphthodithiophene derivative represented by the general formula (2). The benzodithiophene derivative represented by the above-described general formula (1) and the naphthodithiophene derivative represented by the general formula (2) have a moderate crystal density in a case where organic semiconductor powder that forms the thin film is subjected to X-ray structural analysis, and have a broad peak in a case where a thin film formed using only one of them is subjected to XRD measurement. Thus, the hole transport layer 92 and the light-emitting layer 93 having moderate intermolecular interaction are formed, and it is possible to form a favorable thin film having less aggregation and less film defects. This leads to an improvement in carrier (hole) mobility in the thin film.

As described above, in the light-emitting element 90 according to the present embodiment, the p-buffer layer 14 is formed using at least one of the benzodithiophene derivative represented by the general formula (1) or the naphthodithiophene derivative represented by the general formula (2) that has moderate interaction between molecules in a layer, which improves carrier (hole) mobility in the hole transport layer 92 and the light-emitting layer 93. This makes it possible to improve, for example, light emission external quantum efficiency and element characteristics such as light emission electric power efficiency.

It is to be noted that the present technology is not limited to the configuration of the light-emitting element 90 described in the embodiment described above, and is applicable to a light-emitting element having a so-called tandem structure in which two or more light-emitting layers are stacked.

### 4. APPLICATION EXAMPLES

### Application Example 1

FIG. 24 illustrates an example of an entire configuration of an imaging device (imaging device 100) including the imaging element (e.g., the imaging element 1A) illustrated in FIG. 4 and the like.

The imaging device 100 is, for example, a CMOS image sensor. The imaging device 100 takes in incident light (image light) from a subject through an optical lens system (not illustrated). The imaging device 100 converts the amount of incident light of which an image is formed on an imaging plane into electric signals on a pixel-by-pixel basis and outputs the electric signals as pixel signals. The imaging device 100 includes a pixel section 100A serving as an imaging area on the semiconductor substrate 30. The imaging device 100 includes, for example, a vertical drive circuit 111, a column signal processing circuit 112, a horizontal drive circuit 113, an output circuit 114, a control circuit 115, and an input/output terminal 116 in a peripheral region of this pixel section 100A.

The pixel section 100A includes, for example, a plurality of unit pixels P that is two-dimensionally disposed in rows and columns. The unit pixels P are wired with pixel drive lines Lread (specifically, row selection lines and reset control lines) for respective pixel rows, and are wired vertical signal lines Lsig for respective pixel columns. The pixel drive lines Lread are for transmitting drive signals for signal reading from the pixels. The pixel drive lines Lread each have one end coupled to a corresponding one of output ends, corresponding to the respective rows, of the vertical drive circuit 111.

The vertical drive circuit 111 includes a shift register, an address decoder, and the like, and is a pixel driver that drives the respective unit pixels P of the pixel section 100A, for example, on a row-by-row basis. The signals outputted from the respective unit pixels P in the pixel rows selectively scanned by the vertical drive circuit 111 are supplied to the column signal processing circuits 112 through the respective vertical signal lines Lsig. Each of the column signal processing circuits 112 includes an amplifier, a horizontal selection switch, and the like that are provided for each of the vertical signal lines Lsig.

The horizontal drive circuit 113 includes a shift register, an address decoder, and the like, and drives the respective horizontal selection switches of the column signal processing circuits 112 in order while scanning the horizontal selection switches. This selective scanning by the horizontal drive circuit 113 causes the signals of the respective pixels transmitted through the respective vertical signal lines Lsig to be outputted in sequence to a horizontal signal line 121 and transmitted to outside of the semiconductor substrate 30 through the horizontal signal line 121.

The output circuit 114 performs signal processing on the signals sequentially supplied from the respective column signal processing circuits 112 through the horizontal signal line 121 and outputs the signals. The output circuit 114 performs, for example, only buffering in some cases and performs black level adjustment, column variation correction, various kinds of digital signal processing, and the like in other cases.

The circuit portions including the vertical drive circuit 111, the column signal processing circuits 112, the horizontal drive circuit 113, the horizontal signal line 121, and the output circuit 114 may be formed directly on the semiconductor substrate 30 or may be provided in external control IC. Alternatively, those circuit portions may be formed in any other substrate coupled by a cable or the like.

The control circuit 115 receives a clock given from the outside of the semiconductor substrate 30, data for an instruction about an operation mode, and the like, and also outputs data such as internal information of the imaging device 100. The control circuit 115 further includes a timing generator that generates various timing signals, and performs drive control of peripheral circuits such as the vertical drive circuit 111, the column signal processing circuit 112, and the horizontal drive circuit 113 on the basis of the various timing signals generated by the timing generator.

The input/output terminal 116 exchanges signals with the outside.

### Application Example 2

The imaging device 100 or the like described above is applicable to various kinds of electronic apparatuses having imaging functions. Examples of the electronic apparatuses include camera systems such as digital still cameras and video cameras and mobile phones having the imaging functions. FIG. 25 illustrates a schematic configuration of an electronic apparatus 1000.

The electronic apparatus 1000 includes, for example, a lens group 1001, the imaging device 100, a DSP (Digital Signal Processor) circuit 1002, a frame memory 1003, a display section 1004, a recording section 1005, an operation section 1006, and a power supply section 1007, which are coupled to each other through a bus line 1008.

The lens group 1001 captures incident light (image light) from a subject to form an image on the imaging plane of the imaging device 100. The imaging device 100 converts the light amount of the incident light of which the image is formed on the imaging plane by the lens group 1001 into an electric signal on a pixel-by-pixel basis, and supplies the electrical signal as a pixel signal to the DSP circuit 1002.

The DSP circuit 1002 is a signal processing circuit that processes a signal supplied from the imaging device 100. The DSP circuit 1002 outputs image data obtained by processing the signal from the imaging device 100. The frame memory 1003 temporarily holds the image data processed by the DSP circuit 1002 on a frame-by-frame basis.

The display section 1004 includes, for example, a panel-type display device such as a liquid crystal panel or an organic EL (Electro Luminescence), and records image data of a moving image or a still image captured by the imaging device 100, on a recording medium such as a semiconductor memory or a hard disk.

In accordance with an operation by a user, the operation section 1006 outputs an operation signal concerning various functions of the electronic apparatus 1000. The power supply section 1007 supplies the DSP circuit 1002, the frame memory 1003, the display section 1004, the recording section 1005, and the operation section 1006 with various types of power as power for operating these supply targets as appropriate.

### (Module)

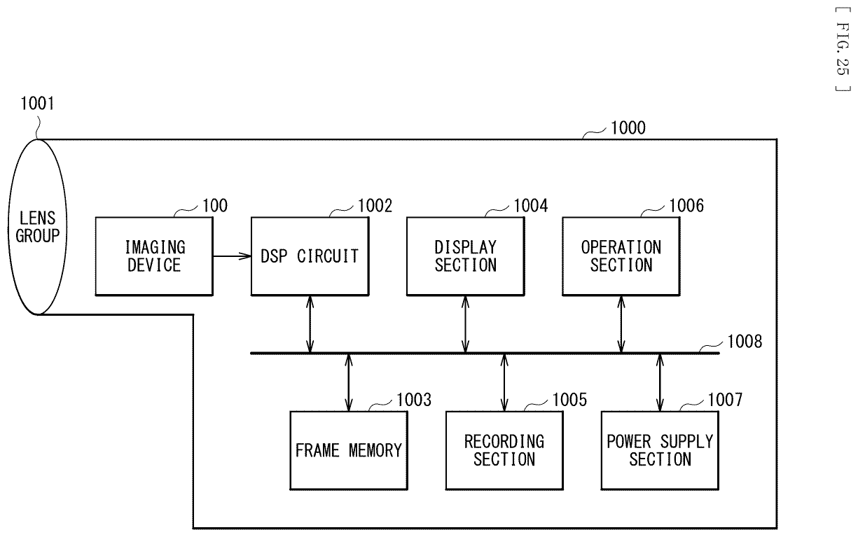

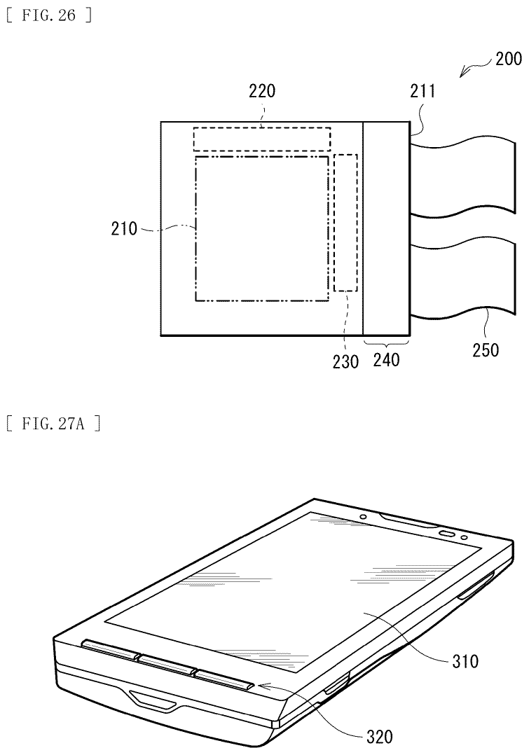

The display device 2 according to the second embodiment described above is mounted, for example, as a module 200 as illustrated in FIG. 26 in any of various electronic apparatuses in application examples 3 to 9 to be described below, and the like. This module 200 is provided with, for example, a region 240 exposed from a sealing substrate 220 on one side of a drive substrate 210, and an external coupling terminal (not illustrated) is formed in the exposed region 240 by extending wiring lines of the signal line drive circuit 212 and the scanning line drive circuit 213. A flexible printed circuit (FPC) 250 for signal input/output may be provided at the external coupling terminal.

### Application Example 3

FIGS. 27A and 27B illustrate an appearance of a smartphone according to the application example 3. This smartphone includes a display section 310 and an operation section 320 on front side, and includes a camera 330 on back side. The display device 2 according to the second embodiment described above is mounted in the display section 310.

### Application Example 4

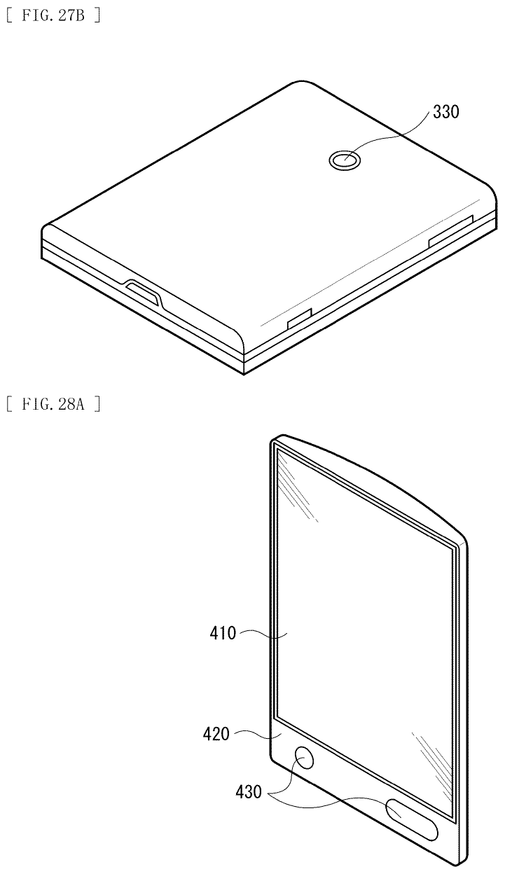

FIGS. 28A and 28B illustrates an appearance configuration of a tablet terminal. This tablet terminal includes, for example, a display section 410 (the display device 2) and a non-display section (housing) 420, and an operation section 430. The operation section 430 may be provided on a front surface of the non-display section 420 as illustrated in FIG. 28A, or may be provided on an upper surface as illustrated in FIG. 28B.

### Application Example 5

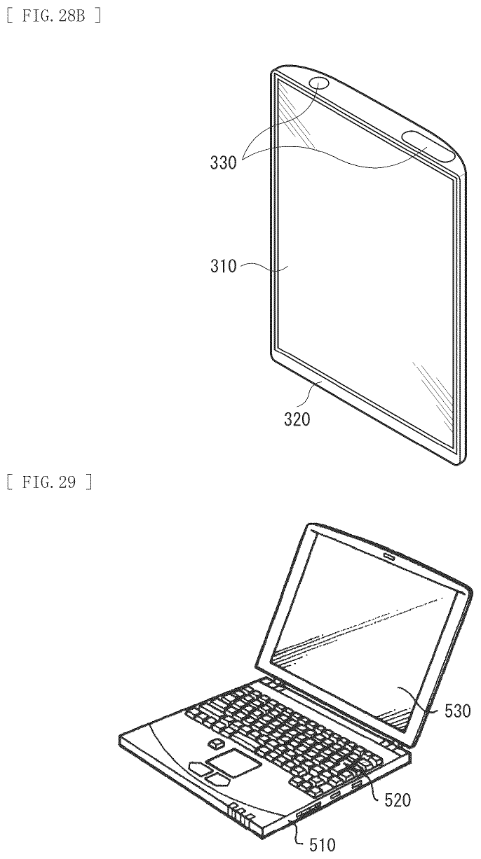

FIG. 29 illustrates an appearance configuration of a notebook personal computer. This personal computer includes, for example, a main body 510, a keyboard 520 for an operation of inputting characters and the like, and a display section 530 (the display device 2) that displays an image.

### Application Example 6

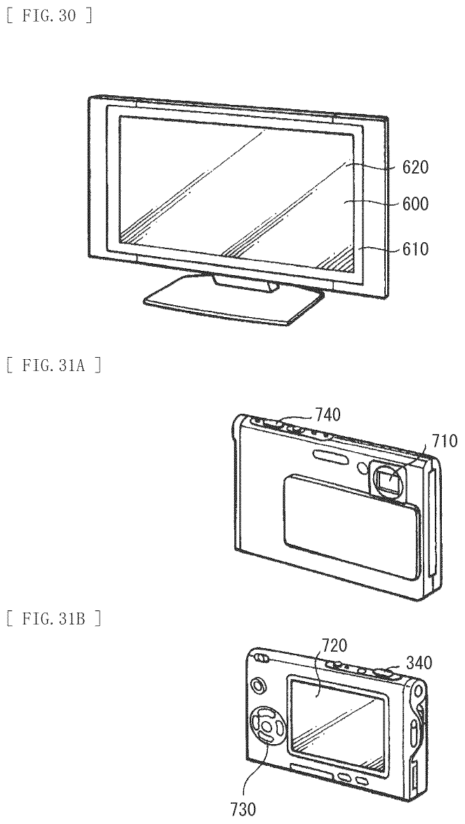

FIG. 30 illustrates an appearance configuration of a television device. This television device includes, for example, an image display screen section 630 (the display device 2) including a front panel 610 and a filter glass 620.

### Application Example 7

FIGS. 31A and 31B illustrate an appearance configuration of a digital still camera, and respectively illustrates a front surface and a back surface. This digital still camera includes, for example, a light-emitting section 710 for a flash, a display section 720 (the display device 2), a menu switch 730, and a shutter button 740.

### Application Example 8

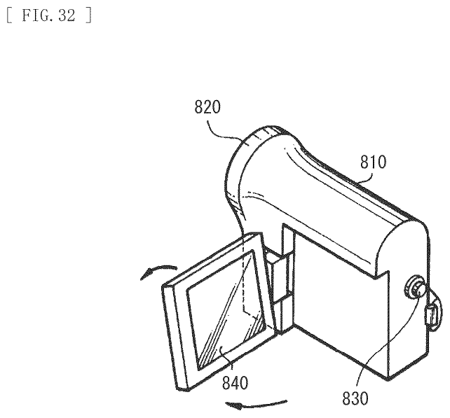

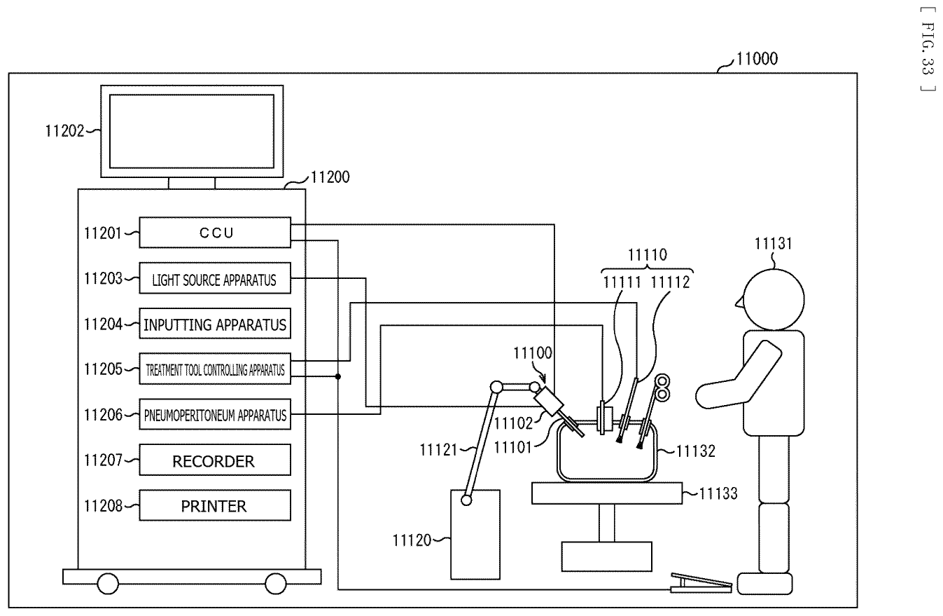

FIG. 32 illustrates an appearance configuration of a video camera. This video camera includes, for example, a main body section 810, a lens 820 for subject shooting provided a front side surface of the main body section 810, a start/stop switch 830 for shooting, and a display section 840 (the display device 2).

### 5. Practical Application Examples

### (Practical Application Example to Endoscopic Surgery System)

The technology according to the present disclosure (present technology) is applicable to various products. For example, the technology according to the present disclosure may be applied to an endoscopic surgery system.

FIG. 33 is a view depicting an example of a schematic configuration of an endoscopic surgery system to which the technology according to an embodiment of the present disclosure (present technology) can be applied.

In FIG. 33, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

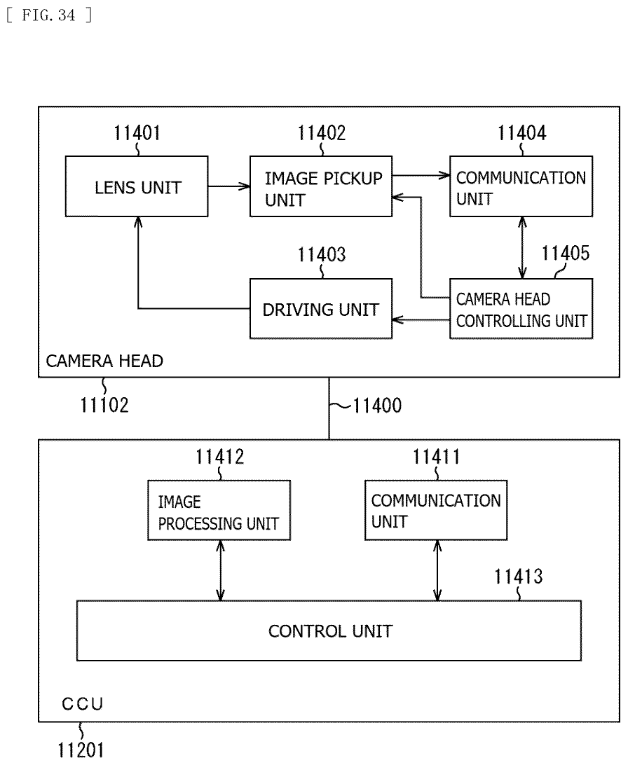

FIG. 34 is a block diagram depicting an example of a functional configuration of the camera head 11102 and the CCU 11201 depicted in FIG. 33.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of the endoscopic surgery system to which the technology according to the present disclosure may be applied has been described above. The technology according to the present disclosure may be applied to, for example, the image pickup unit 11402 among the configurations described above. Applying the technology according to the present disclosure to the image pickup unit 11402 makes it possible to improve detection accuracy.

It is to be noted that the endoscopic surgery system has been described here as an example, but the technology according to the present disclosure may be additionally applied to, for example, a microscopic surgery system and the like.

### (Practical Application Example to Mobile Body)

The technology according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, a robot, a construction machine, and an agricultural machine (tractor).

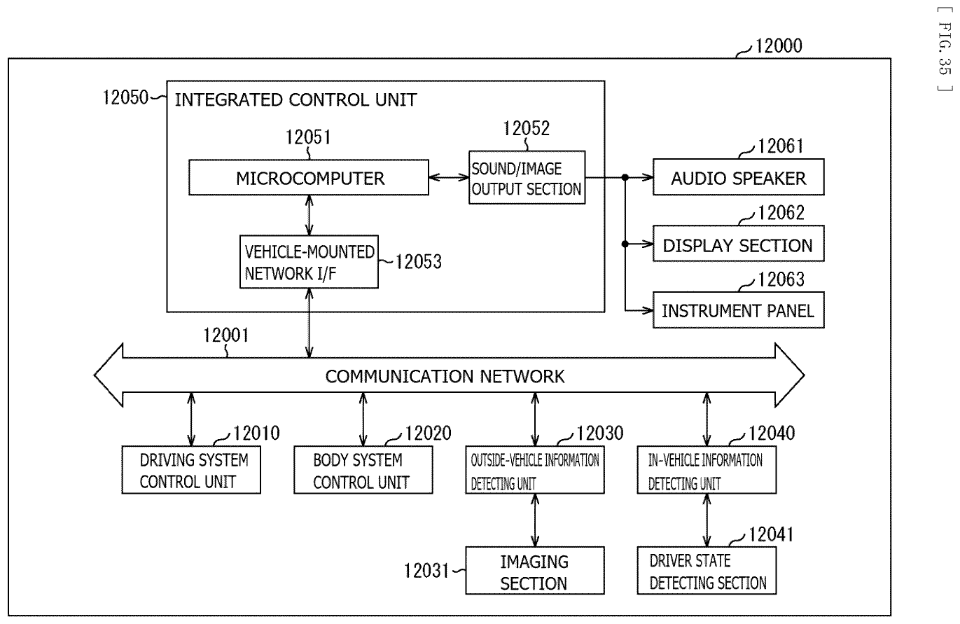

FIG. 35 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 35, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 35, an audio speaker 12061, a display section 12062, and an instrument panel 12063 are illustrated as the output device. The display section 12062 may, for example, include at least one of an on-board display and a head-up display.

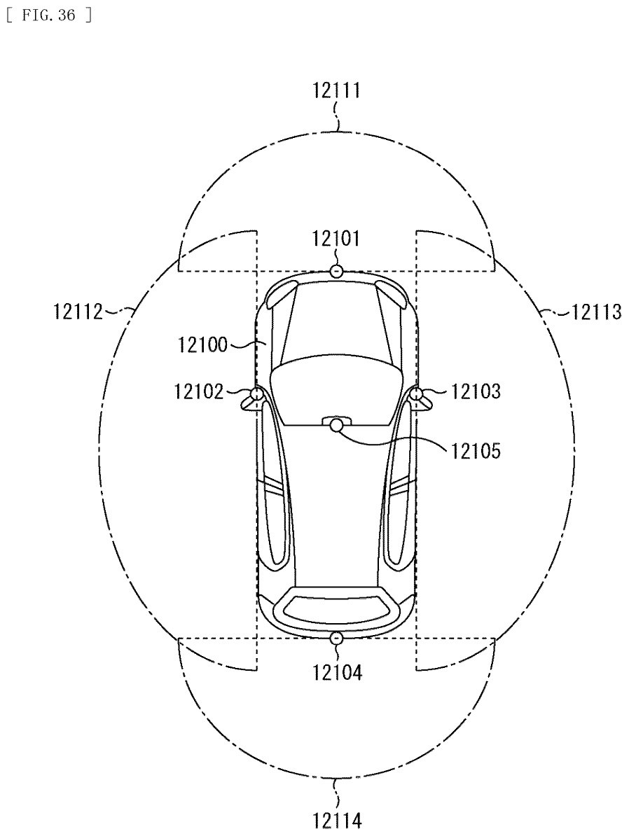

FIG. 36 is a diagram depicting an example of the installation position of the imaging section 12031.

In FIG. 36, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 36 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure may be applied has been described above. The technology according to the present disclosure is applicable to the imaging section 12031 among the configurations described above. Specifically, the imaging element (e.g., the imaging element 1A) according to any of the embodiments described above and the modification examples thereof is applicable to the imaging section 12031. Applying the technology according to the present disclosure to the imaging section 12031 makes it possible to obtain a high-definition shot image with less noise. This makes it possible to perform highly accurate control with use of the shot image in the mobile body control system.

### 6. Examples

Next, description is given of examples of the present disclosure.

### Experiment 1

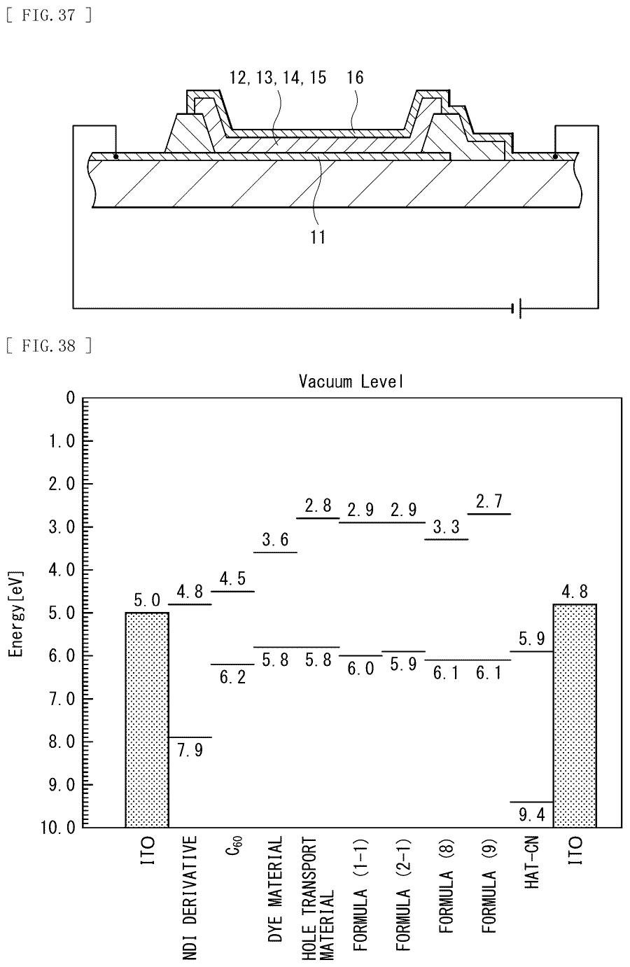

In an experiment 1, an evaluation element having a configuration similar to that of the photoelectric conversion element 10 described above was fabricated, and dark current characteristics after annealing, external quantum efficiency, and afterimage characteristics were evaluated. FIG. 37 schematically illustrates the configuration of the evaluation element.

### Experimental Example 1

First, an ITO film having a film thickness of 120 nm was formed on a quartz substrate with use of a sputtering device. This ITO film was processed by lithography technology using a photomask to form the lower electrode 11. Next, an insulating film was formed on the quartz substrate and the lower electrode 11, and a 1 mm-square opening allowing the lower electrode 11 to be exposed was formed by lithography technology. Subsequently, a surface thereof was cleaned by ultrasonic cleaning sequentially using a neutral detergent, acetone, and ethanol. Next, after drying, the quartz substrate was further subjected to UV/ozone treatment for 10 minutes, and then the quartz substrate was brought into a vacuum deposition machine. A vapor deposition chamber was decompressed to a pressure of 5.5×10⁻⁵ Pa or less. Subsequently, the n-buffer layer 12, the photoelectric conversion layer 13, the p-buffer layer 14, and the work function adjustment layer 15 were sequentially formed by vacuum deposition film formation using a shadow mask. Specifically, a film of a naphthalene diimide (NDI) derivative represented by the following formula (4) was formed with a film thickness of 10 nm to serve as the n-buffer layer 12. Next, 2Ph-BTBT represented by the following formula (5), a subphthalocyanine derivative represented by the following formula (6), fullerene Co represented by the following formula (7) were co-deposited at a vapor deposition rate ratio of 4:4:2 to form a film with a film thickness of 170 nm as the photoelectric conversion layer 13. Subsequently, a film of a BDT derivative (2,6-bis[4-(pyridine-4-yl)phenyl]benzo[1,2-b:4,5-b′]dithiophene: PyP-BDT) represented by the following formula (8) was formed with a film thickness of 10 nm to serve as the p-buffer layer 14. Next, a film of HAT-CN represented by the above-described formula (3) was formed with a film thickness of 10 nm to serve as the work function adjustment layer 15. Subsequently, the quartz substrate was put into a container that was transportable in an inert atmosphere, and was brought into a sputtering device. An ITO film with a film thickness of 50 nm was formed on the work function adjustment layer 15 to serve as the upper electrode 16. After that, the quartz substrate was subjected to annealing treatment at 150° C. for 3.5 h in a nitrogen atmosphere. The quartz substrate served as an evaluation element.

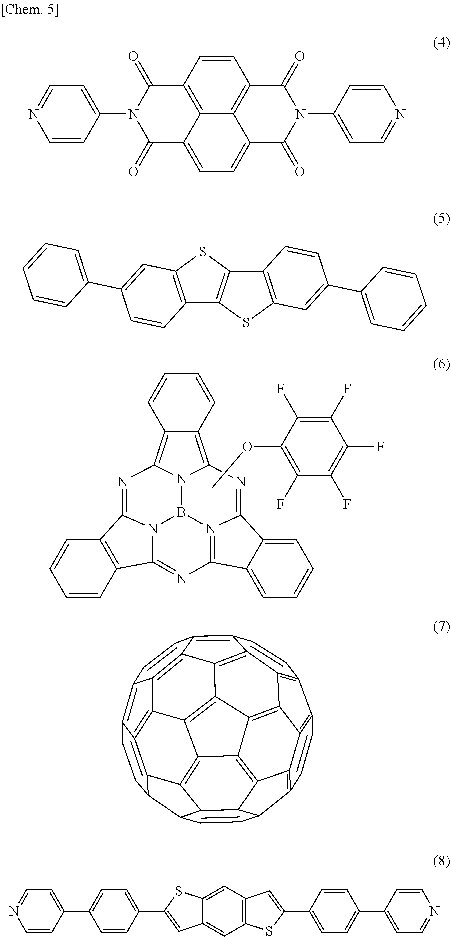

### Experimental Example 2

An evaluation element was fabricated with use of a method similar to that in the experimental example 1, except that the annealing treatment performed in the experimental example 1 was omitted.

### Experimental Example 3

An evaluation element was fabricated with use of a method similar to that in the experimental example 1, except that a compound represented by the following formula (9) (9,9′-(9,9-dimethyl-9H-fluorene-2,7-diyl)bis(9H-carbazole): DMFL-CBP) was used in place of PyP-BDT represented by the formula (8) used in the experimental example 1.

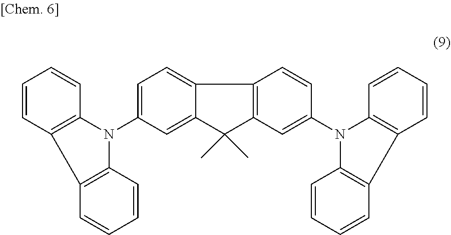 [SMILES: CC1(C)c2cc(-n3c4ccccc4c4ccccc43)ccc2-c2ccc(-n3c4ccccc4c4ccccc43)cc21]

### Experimental Example 4

An evaluation element was fabricated with use of a method similar to that in the experimental example 1, except that the BDT derivative represented by the above-described formula (1-1) was used in place of PyP-BDT represented by the formula (8) used in the experimental example 1.

### Experimental Example 5

An evaluation element was fabricated with use of a method similar to that in the experimental example 1, except that the NDT derivative represented by the above-described formula (2-1) was used in place of PyP-BDT represented by the formula (8) used in the experimental example 1.

### Experimental Example 6

An evaluation element was fabricated with use of a method similar to that in the experimental example 1, except that a BDT derivative represented by the following formula (1-2) was used in place of PyP-BDT represented by the formula (8) used in the experimental example 1.

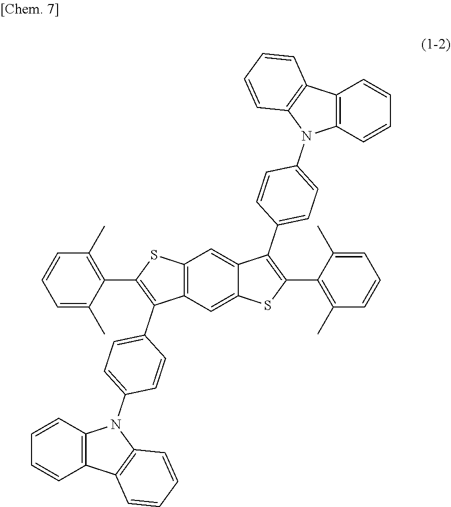 [SMILES: Cc1cccc(C)c1-c1sc2cc3c(-c4ccc(-n5c6ccccc6c6ccccc65)cc4)c(-c4c(C)cccc4C)sc3cc2c1-c1ccc(-n2c3ccccc3c3ccccc32)cc1]

### (Physical Property Value of Organic Semiconductor)

A film of each of the organic semiconductors described above was formed with a film thickness of 20 nm on a Si substrate, and a surface of the thin film was measured by ultraviolet photoelectron spectroscopy (UPS) to determine each of HOMO levels (ionization potentials) of the formula (1-1), the formula (1-2), the formula (8), and the formula (9). An optical energy gap was calculated from an absorption end of an absorption spectrum of each of the thin films of the organic semiconductors, and a LUMO level was calculated from a difference between the HOMO level and the energy gap (LUMO=−1*|HOMO−energy gap|).

### Evaluation of Photoelectric Conversion Element: External Quantum Efficiency and Dark Current

Each of the evaluation elements was placed on a prober stage, and while a voltage of 2.6 V was applied between the lower electrode 11 and the upper electrode 16, each of the evaluation elements was irradiated with light on conditions of a wavelength of 560 nm and 2 μW/cm² to measure a light current. After that, light irradiation was stopped, and a dark current was measured. Next, in accordance with the following expression, external quantum efficiency (EQE=((light current−dark current)×100/(2×10⁻⁶))×(1240/560)×100) was determined from the light current and the dark current.

### Evaluation of Photoelectric Conversion Element: Afterimage Evaluation 1

As for an afterimage evaluation 1, while a voltage of 2.6 V was applied between the lower electrode 11 and the upper electrode 16, each of the evaluation elements was irradiated with light of a wavelength of 560 nm and 1.62 μW/cm². Subsequently, when light irradiation was stopped, the amount of a current flowing between the lower electrode 11 and the upper electrode 16 immediately before the light irradiation was stopped was I₀ and time from stop of the light irradiation until the current amount reached (0.03×I₀) was afterimage time (T₀).

### Evaluation of Photoelectric Conversion Element: Afterimage Evaluation 2

Each of photoelectric conversion elements was irradiated with light of a wavelength of 560 nm and 162 μW/cm² from a green light-emitting diode (LED) through a bandpass filter, and a voltage to be applied to an LED driver was controlled with a function generator. Each of the evaluation elements was irradiated with pulsed light from side of the upper electrode 16. Each of the evaluation elements was irradiated with pulsed light in a state in which for a bias voltage to be applied between the electrodes of each of the evaluation elements, a voltage of 2.6 V was applied to the lower electrode 11 with respect to the upper electrode 16. An oscilloscope was used to observe an attenuated waveform of a current. A coulomb amount in course of attenuating the current after 1 ms to 110 ms immediately after light pulse irradiation was measured. The coulomb amount was an index for an afterimage amount.

The following table 1 summarizes the organic semiconductors used for the p-buffer layer 14 in the experimental examples 1 to 6 and HOMO levels thereof, crystal densities thereof in powder form upon X-ray structural analysis, XRD half widths of single-layer thin films, film densities of the single-layer thin films, annealing conditions, and element characteristics (dark current, external quantum efficiency, afterimage evaluations 1 and 2) of the experimental examples 1 to 6. FIG. 38 illustrates energy levels of respective materials used for the evaluation elements fabricated in the experimental examples 1 to 6. It is to be noted that the values of the dark current, the external quantum efficiency, and the afterimage evaluations 1 and 2 summarized in the table 1 are relative values in a case where values in the experimental example 3 are taken as reference values (1.0).

TABLE 1

| | | | | | | | | Crystal | | |
|---|---|---|---|---|---|---|---|---|---|---|
| | | | | | | | | Density in | | Film |
| | | | | | | | | Powder | XRD Half | Density |
| | | | | | | | | Form upon | Width of | of Single- |
| | Organic | | | | | | | X-ray | Single- | layer |
| | Semi- | | | | External | Afterimage | Afterimage | Structural | layer | Thin |
| | conductor | Annealing | HOMO | Dark | Quantum | Evaluation | Evaluation | Analysis | Thin Film | Film |
| | Material | Conditions | (eV) | Current | Efficiency | 1 | 2 | (g/cm³) | (degree) | (g/cm²) |
| Experimental | (8) | 150°C, 3.5 h | 6.1 | — | — | — | — | 1.46 | 1.0 | ≥1.20 |
| Example 1 | | | | | | | | | | |
| Experimental | (8) | Adeo. | 6.1 | 175000 | — | — | — | 1.46 | 1.0 | ≥1.20 |
| Example 2 | | | | | | | | | | |
| Experimental | (9) | 150° C., 3.5 h | 6.1 | 1.0 | 1.0 | 1.0 | 1.0 | 1.26 | Not | ≥1.20 |
| Example 3 | | | | | | | | | measurable | |
| Experimental | (1-1) | 150° C., 3.5 h | 6.0 | 0.8 | 1.2 | 1.0 | 0.1 | 1.32 | 3.7 | ≥1.20 |
| Example 4 | | | | | | | | | | |
| Experimental | (2-1) | 150° C., 3.5 h | 5.9 | 3.7 | 1.1 | 0.8 | 0.2 | 1.35 | 7.2 | ≥1.20 |
| Example 5 | | | | | | | | | | |
| Experimental | (1-2) | 150° C., 3.5 h | 6.0 | 490 | — | — | — | 1.23 | Not | 1.18 |
| Example 6 | | | | | | | | | measurable | |

In the experimental example 1, the annealing treatment caused a short in the element, which resulted in a state in which the element characteristics were not measurable. In the experimental example 2 in which a configuration similar to that of the experimental example 1 was adopted and the element characteristics were measured without performing the annealing treatment, the dark current was extremely large, and the external quantum efficiency and the afterimage evaluations 1 and 2 were not accurately evaluated; therefore, evaluation was not performed. In the experimental example 4 in which the BDT derivative represented by the general formula (1) (specifically, the formula (1-1)) according to the present technology was used, as compared with the experimental example 3, the dark current was reduced by about 20%, and the external quantum efficiency was improved by about 20%. In addition, as for the afterimage evaluation 2, a 10 times better result was obtained. In the experimental example 5 in which the NDT derivative represented by the general formula (2) (specifically, the formula (2-1)) according to the present technology was used, as compared with the experimental example 3, while the dark current was increased by 3.7 times, the external quantum efficiency was improved by about 10%. In addition, the afterimage evaluation 1 was improved by about 20%, and as for the afterimage evaluation 2, a five times better result was obtained. In the experimental example 6 in which the BDT derivative represented by the general formula (1) (specifically, the formula (1-2)) according to the present technology was used, as compared with the experimental example 3, the dark current became worse by 490 times.

Conceivable reasons for the results in the experimental examples 1 to 6 are as follows. First, in the experimental examples 1 and 2 in which PyP-BDT represented by the formula (8) was used, it is assumed from results before and after annealing that PyP-BDT was aggregated in the p-buffer layer 14 even in a state in which annealing treatment was not performed, and there was a portion where the photoelectric conversion layer 13 and HAT-CN included in the work function adjustment layer 15 were in direct contact with each other. In addition, it is assumed that aggregation of PyP-BDT in the p-buffer layer 14 was further accelerated, thereby causing element breakdown to progress. Meanwhile, as for DMFL-CBP represented by the formula (9) used in the experimental example 3, in a case where X-ray diffraction (XRD) of a single-layer thin film thereof was measured, a peak was hardly confirmed, and the crystal density thereof in powder form was small; therefore, it is conceivable that the DMFL-CBP is a material having extremely low intermolecular interaction. Accordingly, in the experimental example 3, it is assumed that DMFL-CBP was not aggregated in the p-buffer layer 14 and element breakdown did not occur. As for the BDT derivative represented by the formula (1-1) and the NDT derivative represented by the formula (2-1) used in the experimental examples 4 and 5 that obtained element characteristics superior to those in the experimental example 3, an XRD peak was broad, but the crystal density in powder form had an intermediate value between the values of PyP-BDT and DMFL-CBP. For this reason, it is conceivable that the BDT derivative represented by the formula (1-1) and the NDT derivative represented by the formula (2-1) have moderate intermolecular interaction. Accordingly, it is assumed that, in addition to favorable dark current characteristics, the external quantum efficiency and the afterimage evaluations 1 and 2 were improved, as compared with the experimental example 3. Meanwhile, in the experimental example 6, in spite of using the BDT derivative represented by the general formula (1) (specifically, the formula (1-2)), a significant decrease in the dark current was observed. It is assumed that a reason for this is that a single-layer thin film thereof was a low-packing film having a film density of 1.18 g/cm², as compared with the other experimental examples 1 to 5; therefore, there was a portion where the photoelectric conversion layer 13 and the work function adjustment layer 15 including HAT-CN were in direct contact with each other.

### Experiment 2

In an experiment 2, an evaluation element having a configuration similar to that of the light-emitting element 90 described above was fabricated, and an applied voltage, light emission external quantum efficiency, and light emission electric power efficiency were evaluated.

### Experiment 7

First, an ITO film having a film thickness of 100 nm was formed on an alkali-free glass substrate with use of a sputtering device. This ITO film was processed by lithography technology using a photomask to form an anode. Next, an insulating film was formed on the alkali-free glass substrate and the anode, and the insulating film was processed by lithography technology to expose a 2 mm-square anode, thereby forming a pixel. Subsequently, a surface was cleaned by ultrasonic cleaning sequentially using a neutral detergent, acetone, and ethanol. Next, after drying, the alkali-free glass substrate was further subjected to UV/ozone treatment for 10 minutes, and then the alkali-free glass substrate was brought into to a vacuum deposition machine. A vapor deposition chamber was decompressed to a pressure of 5.5×10⁻⁵ Pa or less. Subsequently, a hole transport layer, a light-emitting layer, an electron transport layer, and an electron injection layer were sequentially formed by vacuum deposition film formation using a shadow mask. Specifically, a film of α-NPD represented by the following formula (10) was formed with a film thickness of 40 nm to serve as the hole transport layer. Next, DMFL-CBP represented by the above-described formula (9) and Pt(TPBP) represented by the following formula (11) were co-deposited at a vapor deposition rate ratio of 96:4 to form a film with a film thickness of 25 nm as the light-emitting layer. Subsequently, a film of BCP represented by the following formula (12) was formed with a film thickness of 40 nm to serve as the electron transport layer. Next, a film of lithium fluoride (LiF) was formed with a film thickness of 0.5 nm to serve as the electron injection layer. Subsequently, a film of AlSiCu was formed with a film thickness of 100 nm to serve as the cathode. After that, a sealing glass provided with a drying material was bonded to the surface with use of an ultraviolet curing resin in a nitrogen atmosphere. The alkali-free glass substrate served as an evaluation element.

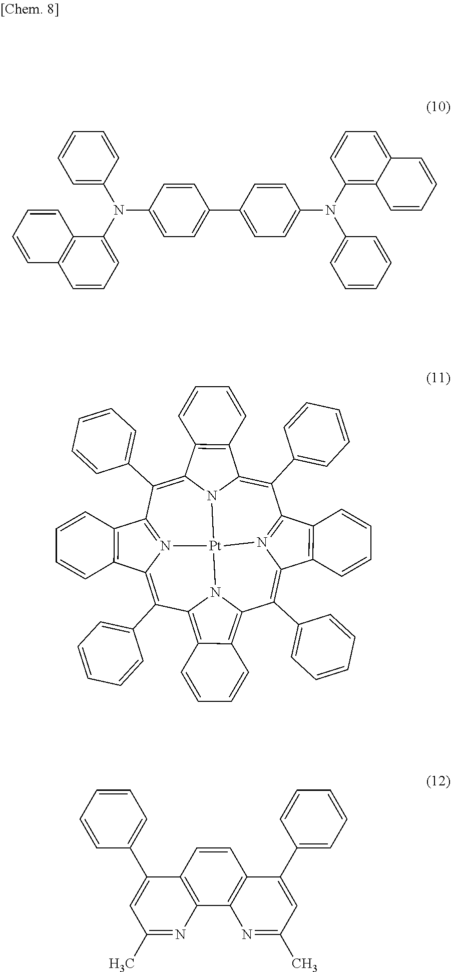

### Experimental Example 8

An evaluation element was fabricated with use of a method similar to that in the experimental example 7, except that the NDT derivative represented by the above-described formula (2-1) was used in place of DMFL-CBP represented by the formula (9) used in the experimental example 7.

### (Physical Property Value of Organic Semiconductor)

Each of HOMO levels (ionization potentials) of DMFL-CBP represented by the formula (9), and the NDT derivative represented by the above-described formula (2-1) was determined by forming a film of each of the organic semiconductors described above with a film thickness of 20 nm on a Si substrate and measuring a surface of the thin film by ultraviolet photoelectron spectroscopy (UPS). An optical energy gap was calculated from an absorption end of an absorption spectrum of each of the thin films of the organic semiconductors, and a LUMO level was calculated from a difference between the HOMO level and the energy gap (LUMO=−1*|HOMO−energy gap|).

### Evaluation of Light-Emitting Element: Light Emission External Quantum Efficiency

Each of the evaluation elements was driven with a direct current of 100 mA/cm² with use of a source meter, and a spectrum of emitted light from the evaluation element was measured using a fiber spectrometer via an integrating sphere. Subsequently, a radiant flux of the same emitted light was measured using a power meter, and the total photon number of the emitted light was calculated. After that, the lit emission external quantum efficiency was calculated with use of the following mathematical formula (2).

$$\begin{matrix}( Math . 2 ) & \\ Light emission external quantum efficiency ( \% ) = ( the total photon number of light emitted from the element / the number of carriers injected into the element determined from a current value ) \times 100 & ( 2 )\end{matrix}$$

### Evaluation of Light-emitting Element: Light Emission Electric Power Efficiency

Each of the evaluation elements was driven with a direct current of 100 mA/cm² with use of a source meter, and a voltage to be applied to the evaluation element was measured. Subsequently, a radiant flux of the same emitted light was measured using a power meter. After that, the light emission electric power efficiency was calculated with use of the following mathematical formula (3).

$$\begin{matrix}( Math . 3 ) & \\ Light emission electric power efficiency ( \% ) = \{ the radiant flux of light emitted from the element / ( a current flowing through the element \times the voltage applied to the element ) \} \times 100 & ( 3 )\end{matrix}$$

The following table 2 summarizes the organic semiconductors used for the light-emitting layer, the applied voltage, the light emission external quantum efficiency, and light emission electric power efficiency in the experimental example 7 and the experimental example 8. It is to be noted that the values of the light emission external quantum efficiency and the light emission electric power efficiency summarized in the table 2 are relative values in a case where values in the experimental example 7 are taken as reference values (1.0).

TABLE 2

| | | | Light Emission | |
|---|---|---|---|---|
| | Organic | Applied | External | Light Emission |
| | Semiconductor | Voltage | Quantum | Electric Power |
| | Material | (V) | Efficiency | Efficiency |
| Experimental | (9) | 10.4 | 1.0 | 1.0 |
| Example 7 | | | | |
| Experimental | (2-1) | 9.1 | 2.3 | 2.3 |
| Example 8 | | | | |

The evaluation elements fabricated in the experimental examples 7 and 8 both exhibited light emission in a near-infrared wavelength region having a peak at about 770 nm. The measured applied voltage was 10.4 V in the experimental example 7 using DMFL-CBP represented by in the formula (9), and 9.1 V in the experimental example 8 using the NDT derivative represented by the formula (2-1). The voltage in the experimental example 8 was lowered by 1.3 V. In addition, both the light emission external quantum efficiency and the light emission electric power efficiency were improved by 2.3 times in the experimental example 8, as compared with the experimental example 7.

It was found from these results that the NDT derivative represented by the formula (2-1) made it possible to achieve both a decrease in voltage and an improvement in light emission efficiency in the light-emitting element. In addition, there is no significant difference in the HOMO level and the LUMO level between the NDT derivative represented by the formula (2-1) and DMFL-CBP represented by the formula (9); therefore, it is assumed that the influence of the energy level on the element characteristics is small. Meanwhile, as described in the experiment 1, as for DMFL-CBP represented by the formula (9), in a case where X-ray diffraction (XRD) of a single-layer thin film thereof was measured, a peak was hardly confirmed, and the crystal density thereof in powder form was small. In contrast, as for the NDT derivative represented by the formula (2-1), an XRD peak thereof was broad, but the crystal density thereof in powder form had an intermediate value between the values of PyP-BDT and DMFL-CBP. It is assumed from this that a reason why favorable element characteristics were obtained in the experimental example 8 is that molecules in the light-emitting layer interacted moderately with each other.

### Experiment 3

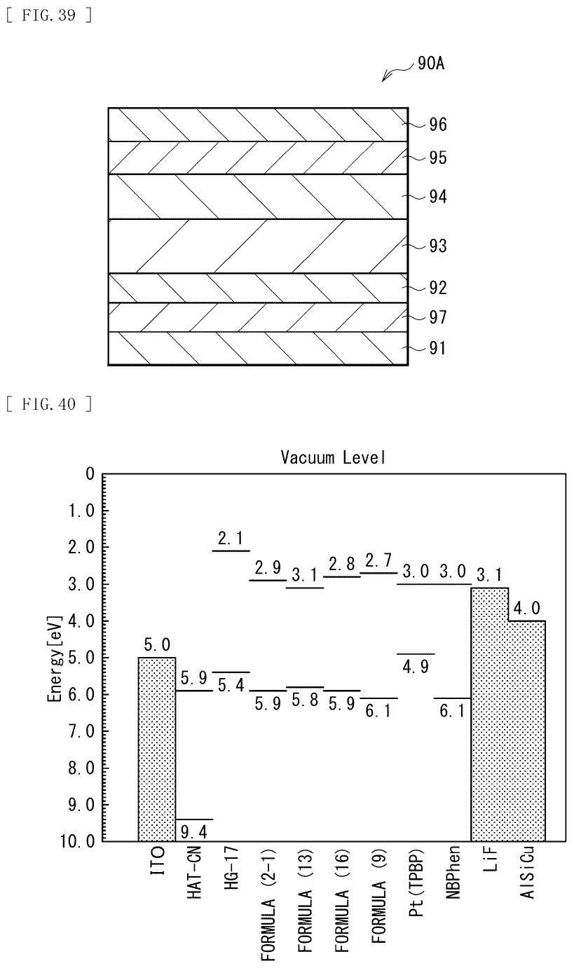

In an experiment 3, an evaluation element (light-emitting element 90A) having a configuration illustrated in FIG. 39 was fabricated, and physical property values (HOMO, crystal density in powder form upon X-ray structural analysis, an XRD half width of a single-layer thin film) were measured, and an applied voltage, light emission external quantum efficiency, and light emission electric power efficiency were evaluated.

### Experimental Example 9

First, an ITO film having a film thickness of 100 nm was formed on an alkali-free glass substrate with use of a sputtering device. This ITO film was processed by lithography technology using a photomask to form the anode 91. Next, an insulating film was formed on the alkali-free glass substrate and the anode 91, and the insulating film was processed by lithography technology to expose a 2 mm-square anode, thereby forming a pixel. Subsequently, a surface was cleaned by ultrasonic cleaning sequentially using a neutral detergent, acetone, and ethanol. Next, after drying, the alkali-free glass substrate was further subjected to UV/ozone treatment for 10 minutes, and then the alkali-free glass substrate was brought into a vacuum deposition machine. A vapor deposition chamber was decompressed to a pressure of to 5.5×10⁻⁵ Pa or less. Subsequently, the hole injection layer 97, the hole transport layer 92, the light-emitting layer 93, the electron transport layer 94, and the electron injection layer 95 were sequentially formed by vacuum deposition film formation using a shadow mask. Specifically, a film of HAT-CN represented by the above-described formula (3) was formed with a film thickness of 10 nm to serve as the hole injection layer 97. Next, a film of HG-17 represented by the following formula (14) was formed with a film thickness of 30 nm to serve as the hole transport layer 92. Subsequently, the NDT derivative represented by the above-described formula (2-1) and Pt(TPBP) represented by the above-described formula (11) were co-deposited at a vapor deposition rate ratio of 99:1 to form a film with a film thickness of 45 nm as the light-emitting layer 93. Subsequently, a film of NBPhen represented by the following formula (15) was formed with a film thickness of 20 nm to serve as the electron transport layer 94. Next, a film of lithium fluoride (LiF) was formed with a film thickness of 0.5 nm to serve as the electron injection layer 95. Subsequently, a film of AlSiCu was formed with a film thickness of 100 nm to serve as the cathode 96. After that, a sealing glass provided with a drying material was bonded to the alkali-free glass substrate with use of an ultraviolet curing resin in a nitrogen atmosphere to cover the light-emitting element 90A. The alkali-free glass substrate served as an evaluation element.

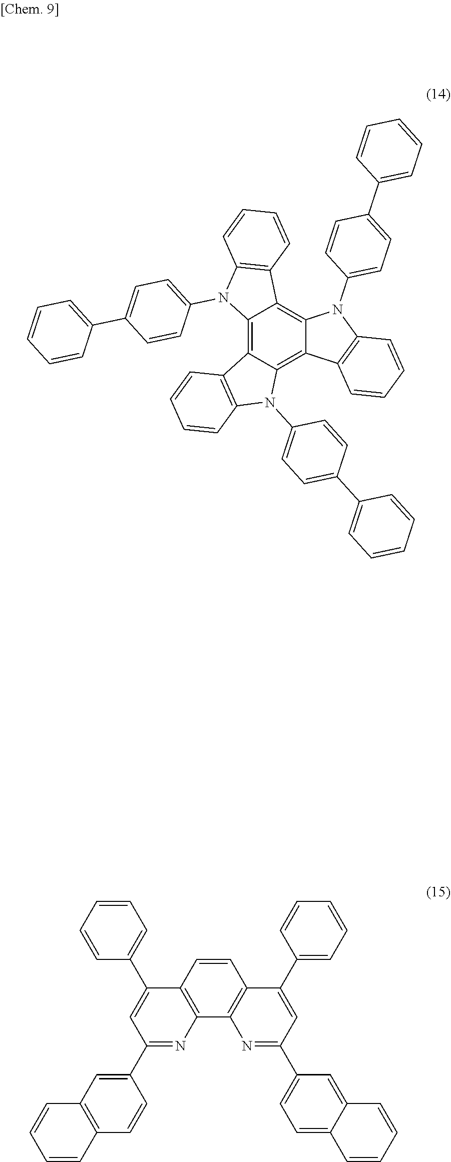 [SMILES: c1ccc(-c2ccc(-n3c4ccccc4c4c3c3c5ccccc5n(-c5ccc(-c6ccccc6)cc5)c3c3c5ccccc5n(-c5ccc(-c6ccccc6)cc5)c43)cc2)cc1 ; c1ccc(-c2cc(-c3ccc4ccccc4c3)nc3c2ccc2c(-c4ccccc4)cc(-c4ccc5ccccc5c4)nc23)cc1]

### Experimental Example 10

An evaluation element was fabricated with use of a method similar to that in the experimental example 9, except that an anthracene derivative represented by the following forma (13) was used in place of the NDT derivative represented by the formula (2-1) used in the experimental example 9.

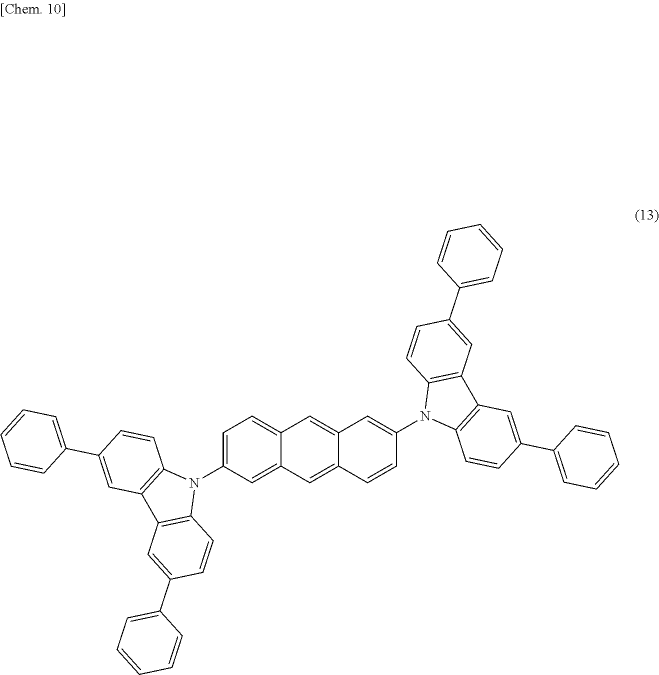 [SMILES: c1ccc(-c2ccc3c(c2)c2cc(-c4ccccc4)ccc2n3-c2ccc3cc4cc(-n5c6ccc(-c7ccccc7)cc6c6cc(-c7ccccc7)ccc65)ccc4cc3c2)cc1]

### Experimental Example 11

An evaluation element was fabricated with use of a method similar to that in the experimental example 9, except that a pyrene derivative represented by the following formula (16) was used in place of the NDT derivative represented by the formula (2-1) used in the experimental example 9.

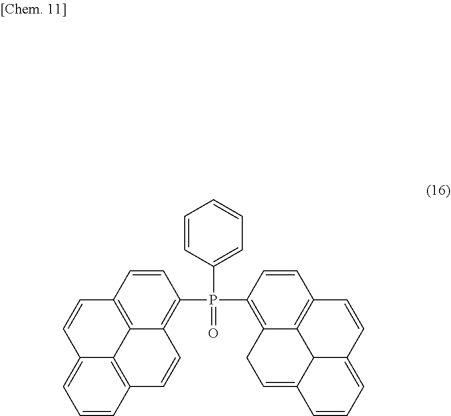 [SMILES: O=P(c1ccccc1)(c1ccc2c3c1CC=C1C=CC=C(C=C2)C13)c1ccc2ccc3cccc4ccc1c2c34]

### Experimental Example 12

An evaluation element was fabricated with use of a method similar to that in the experimental example 9, except that DMFL-CBP represented by the above-described formula (9) was used in place of the NDT derivative represented by the formula (2-1) used in the experimental example 9.

### (Physical Property Values of Organic Semiconductor)

Calculation was performed with use of a method similar to that in the experiment 2.

### Evaluation of Light-Emitting Element: Light Emission External Quantum Efficiency

Each of the evaluation elements was driven with a direct current of 2.5 MA/cm² with use of a source meter, and a spectrum of emitted light from the evaluation element was measured using a fiber spectrometer via an integrating sphere, Subsequently, a radiant flux of light emitted from the element was measured using a spectral total radiant flux standard LED (manufactured by Nichia Corporation), and the total photon number of the emitted light was calculated. After that, the light emission external quantum efficiency was calculated with use of the above-described mathematical formula (2).

### Evaluation of Light-Emitting Element: Light Emission Electric Power Efficiency

Each of the evaluation elements was driven with a direct current of 2.5 mA/cm² with use of a source meter, and a voltage to be applied to the evaluation element was measured Subsequently, a spectrum of emitted light was measured using a fiber spectrometer via an integrating sphere, and a radiant flux of light emitted from the element was measured using a spectral total radiant flux standard LED (manufactured by Nichia Corporation). After that, the light emission electric power efficiency was calculated with use of the above-described mathematical formula (3).

A table 3 summarizes organic semiconductor materials (host materials) used for the light-emitting layer 93 in the experimental examples 9 to 12, physical property values (a HOMO level, crystal density in powder form upon X-ray structural analysis, an XRD half width of a single-layer thin film) of the organic semiconductor materials, an applied voltage, light emission external quantum efficiency, and light emission electric power efficiency. It is to be noted that the values of the light emission external quantum efficiency and the light emission electric power efficiency are relative values in a case where values in the experimental example 12 are taken as reference values (1.0). FIG. 10 illustrates energy levels of the light-emitting elements fabricated in the experimental example 9 to 12. FIG. 40 illustrates energy levels of materials included in the respective components 91 to 97 of the evaluation elements fabricated in this experiment.

TABLE 3

| | | | | XRD | | | |
|---|---|---|---|---|---|---|---|
| | | | Crystal | Half | | | |
| | | | Density in | Width | | | |
| | | | Power | of | | | |
| | | | Form upon | Single- | | Light | Light |
| | | | X-ray | layer | | Emission | Emission |
| | Organic | | Structural | Thin | Applied | External | Electric |
| | Semiconductor | HOMO | Analysis | Film | Voltage | Quantum | Power |
| | Material | (eV) | (g/cm³) | (degree) | (V) | Efficiency | Efficiency |
| Experimental | (2-1) | 5.9 | 1.35 | 7.2 | 5.8 | 1.4 | 2.5 |
| Example 9 | | | | | | | |
| Experimental | (13) | 5.8 | 1.29 | 5.9 | 4.5 | 1.3 | 3.3 |
| Example 10 | | | | | | | |
| Experimental | (16) | 5.9 | 1.35 | 4.7 | 3.7 | 1.8 | 5.3 |
| Example 11 | | | | | | | |
| Experimental | (9) | 6.1 | 1.26 | — | 10.6 | 1.0 | 1.0 |
| Example 12 | | | | | | | |

All the evaluation elements in the experimental examples 9 to 12 exhibited light emission in a near-infrared wavelength region having a peak at about 770 nm. In a case where comparison is made in a condition that a current of 2.5 mA/cm² flowed through each of the evaluation elements, while a drive voltage in the experimental example 12 using DMFL-CBP represented by the formula (9) was 10.6 V, drive voltages in the experimental examples 9 to 11 using the NDT derivative represented by the formula (2-1), the anthracene derivative represented by the formula (13), and the pyrene derivative represented by the formula (16) were respectively 5.8 V, 4.5 V, and 3.7 V. In addition, in a case where the light emission external quantum efficiency in the experimental example 12 using DMFL-CBP represented by the formula (9) was taken as 1.0, the light emission external quantum efficiency in the experimental examples 9 to 11 using the NDT derivative represented by the formula (2-1), the anthracene derivative represented by the formula (13), and the pyrene derivative represented by the formula (16) were respectively 1.4, 1.3, and 1.8. Furthermore, in a case where the light emission electric power efficiency in the experimental example 12 using DMFL-CBP represented by the formula (9) was taken as 1.0, the light emission electric power efficiency in the experimental examples 9 to 11 using the NDT derivative represented by the formula (2-1), the anthracene derivative represented by the formula (13), and the pyrene derivative represented by the formula (16) were respectively 2.5, 3.3, and 5.3.

In other words, in the experimental Example 9 using the NDT derivative represented by the formula (2-1) as the host material as compared with the experimental example 12 using DMFL-CBP represented by the formula (9), the voltage was lowered by 4.8 V, and the light emission external quantum efficiency and the light emission electric power efficiency were respectively increased by 1.4 times and 2.5 times. In addition, in the experimental example 10 using the anthracene derivative represented by the formula (13) as the host material, as compared with the experimental example 12 using DMFL-CBP represented by the formula (9), the voltage was lowered by 6.1 V, and the light emission external quantum efficiency and the light emission electric power efficiency were respectively increased by 1.3 times and 3.3 times. Furthermore, in the experimental example 11 using the pyrene derivative represented by the formula (16) as the host material, as compared to the experimental example 12 using DMFL-CBP represented by the formula (9), the voltage was lowered by 6.9 V, and the light emission external quantum efficiency and the light emission electric power efficiency were respectively increased by 1.8 times and 5.3 times. It was found from the above that the NDT derivative (the experimental example 9), the anthracene derivative (the experimental example 10), and the pyrene derivative (the experimental example 11) of the present invention are superior host materials for the light-emitting layer that makes it possible to achieve both a decrease in voltage and an increase in efficiency of light emission.

In addition, as illustrated in FIG. 40, there is no large difference in the HOMO level and the LUMO level among the NDT derivative represented by the formula (2-1), the anthracene derivative represented by the formula (13), the pyrene derivative represented by the formula (16), and the DMFL-CBP represented by the formula (9); therefore, it is assumed that the influence of the energy level on the element characteristics is small. Meanwhile, as illustrated in the table 3, as for DMFL-CBP represented by the formula (9), in a case where X-ray diffraction (XRD) of a single-layer thin film thereof was measured, a peak was hardly confirmed, and the crystal density thereof in powder form was small. In contrast, as for the NDT derivative represented by the formula (2-1), an XRD peak thereof was broad, and the crystal density thereof in powder form had an intermediate value between pyp-BDT represented by the formula (8) and DMFL-CBP represented by the formula (9). The anthracene derivative represented by the formula (13) and the pyrene derivative represented by the formula (16) also have properties similar to those of this NDT derivative. Accordingly, it is assumed that a reason why favorable element characteristics were obtained in the experimental examples 9 to 11 is that the molecules in the light-emitting layer 93 interacted moderately with each other.

Although the present technology has been described with reference to the first and second embodiments, the modification examples 1 to 4, the examples, the application examples, and the practical application examples, the contents of the present disclosure are not limited to the embodiments and the like described above, and may be modified in a variety of ways. For example, in the embodiments described above, an example has been described in which electrons are read out from side of the lower electrode 11 as signal electric charges, but this is not limitative. Holes may be read out from side of the lower electrode 11 as signal electric charges. In this case, the work function adjustment layer 15 and the p-buffer layer 14 are stacked in this order from side of the lower electrode 11 between the lower electrode 11 and the photoelectric conversion layer 13, and the n-buffer layer 12 is formed between the upper electrode 16 and the photoelectric conversion layer 13.

In addition, in the embodiments described above, the imaging element 1A has a configuration in which the organic photoelectric converter (photoelectric conversion element 10) that detects the green light (G) and the inorganic photoelectric converter 32B and the inorganic photoelectric converter 32R that respectively detect the blue light (B) and the red light (R) are stacked. However, the contents of the present disclosure are not limited to such a structure. That is, the organic photoelectric converter may detect the red light (R) or the blue light (B), and the inorganic photoelectric converter may detect the green light (G).

Furthermore, the numbers of these organic photoelectric converters and inorganic photoelectric converters and the ratio thereof are not limited. Furthermore, without limitation to a configuration in which the organic photoelectric converter and the inorganic photoelectric converters are stacked in the longitudinal direction, the organic photoelectric converter and the inorganic photoelectric converters may be disposed in parallel along a substrate surface.

In addition, in the embodiments described above, an example has been described in which the inorganic photoelectric converters 32R and 32B are formed in the Si substrate (semiconductor substrate 30), but this is not limitative. For example, the inorganic photoelectric converters 32R and 32B may be formed using, for example, amorphous silicon, non-crystalline silicon, crystalline selenium, or amorphous selenium, other than crystalline silicon. In addition, the inorganic photoelectric converters 32R and 32B may be formed using a chalcopyrite-based compound such as CIGS (CuInGaSe), CIS (CuInSe₂), CuInS₂, CuAlS₂, CuAlSe₂, CuGaS₂, CuGaSe₂, AgAlS₂, AgAlSe₂, AgInS₂, or AgInSe₂, a group III-V compound such as GaAs, InP, AlGaAs, InGaP, AlGaInP, or InGaAsP, or a compound semiconductor such as CdSe, CdS, In₂Se₃, In₂S₃, Bi₂Se₃, Bi₂S₃, ZnSe, ZnS, PbSe, or PbS. In addition, it is possible to form the inorganic photoelectric converters 32R and 32B by using quantum dots including any of these materials.

Furthermore, in the embodiments and the like described above, the configuration of the back-illuminated imaging element is exemplified, but the contents of the present disclosure are applicable to a front-illuminated imaging element.

Furthermore, the photoelectric conversion element 10, the imaging element 1A, and the like, and the imaging device 100 may not necessarily include all the components described in the embodiments described above. or contrarily may include any other component. For example, in the imaging device 100, a shutter for controlling entry of light into the imaging element 1A may be disposed, or an optical cut filter may be provided according to the purpose of the imaging device. In addition, arrangement of pixels (Pr, Pg, and Pb) that detect the red light (R), the green light (G), and the blue light B) may be an interline arrangement, a G stripe RB checkered arrangement, a G stripe RB full checkered arrangement, a checkered complementary color arrangement, a stripe arrangement, a diagonal stripe arrangement, a primary color difference arrangement, a field color difference sequential arrangement, a frame color difference sequential arrangement, a MOS arrangement, an improved MOS arrangement, a frame interleave arrangement, or a field interleave arrangement, in place of the Bayer arrangement.

In addition, in the embodiments and the like described above, an example has been described in which the photoelectric conversion element 10 is used as an imaging element; but the photoelectric conversion element 10 of the present disclosure may be applied to a solar battery. In a case where the photoelectric conversion element 10 is applied to a solar battery, it is preferable that the photoelectric conversion layer be designed to broadly absorb wavelengths of 400 nm to 800 nm, for example.

Furthermore, the photoelectric conversion element (e.g., the photoelectric conversion element 10) according to the first embodiment described above and the light-emitting element 90 according to the second embodiment described above may be combined. For example, a combination of a light-emitting element that emits visible light, and a light-receiving element that receives visible light may be applied to a sheet-type scanner, a biometric authentication device typified by fingerprint imaging, a vital sensing device typified by pulse wave measurement, for example, beauty sensors that detect skin conditions such as skin texture, and the like. In addition, a combination of a light-emitting element that emits near-infrared light and a light-receiving element that receives near-infrared light is applicable to optical touchless sensors, human-detecting sensors, and vital sensing devices typified by oxygen saturation measurement. Furthermore, it is possible to use the combination for finger, arm, earlobe, nose, and forehead vein imagining devices, In addition, the combination is applicable to authentication by imaging of irises and faces, imaging of lymph and sweat glands, and is further applicable to an X-ray plate, mammography, a night vision, a security sensor, an in-vehicle sensor, a aircraft sensor, a factory automation sensor, a gas sensor, a biosensor, and an implant device (such as a blood flow meter and photodynamic therapy).

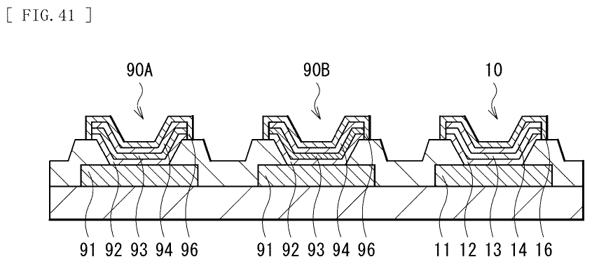

Furthermore, as illustrated in FIG. 41, for example, a combination of the light-emitting elements 90A and 90B and the photoelectric conversion element 10 having different light emission wavelengths makes it possible to exhibit functions described above in the same substrate and the same device. In this case, only a functional layer such as the light-emitting layer and the photoelectric conversion layer is changed by selecting an organic electroluminescent element and an organic photoelectric conversion element each using an organic material, thereby allowing for device manufacturing in which addition of processes is suppressed. It is to be noted that the functional layer is not limited to organic materials, and is able to exhibit various functions by changing the kind of material such as a quantum dot material and a perovskite material.

The effects described herein are merely illustrative and non-limiting, and other effects may be provided.

It is to be noted that the present disclosure may have the following configurations. According to the present technology having the following configurations, an organic semiconductor layer including an organic semiconductor material is formed. The organic semiconductor material has a crystal density of greater than 1.26 g/cm³ and less than 1.5 g/cm³ by X-ray structural analysis, and a molecular weight of 1200 or less, and is available for vacuum deposition film formation. In addition, the benzodithiophene derivative represented by the above-described general formula (1) or the naphthodithiophene derivative represented by the above-described general formula (2) is used to form the organic semiconductor layer. Accordingly, the organic semiconductor layer having moderate intermolecular interaction is formed, which makes it possible to improve element characteristics.
[1]
   A semiconductor element including:
   a first electrode;
   a second electrode disposed to be opposed the first electrode; and
   an organic semiconductor layer that is provided between the first electrode and the second electrode, and including an organic semiconductor material, the organic semiconductor material having a crystal density of greater than 1.26 g/cm³ and less than 1.50 g/cm³ in powder form by X-ray structure analysis, and a molecular weight of 1200 or less, and being available for vacuum deposition film formation.
[2]
   The semiconductor element according to [1], in which the organic semiconductor material includes at least one of a benzodithiophene derivative represented by the following general formula (1) or a naphthodithiophene derivative represented by the following general formula (2).

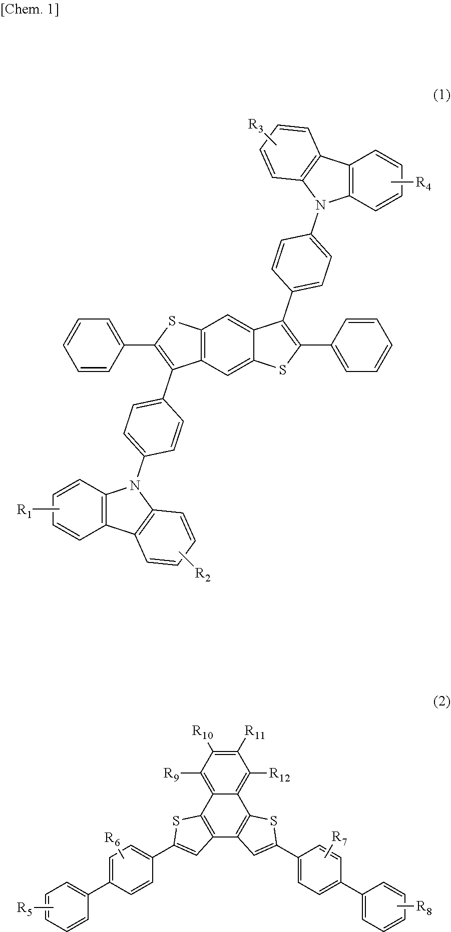

R1 to R12 are each independently a hydrogen atom, a halogen atom, a straight-chain or branched alkyl group, a straight-chain or branched alkoxy group, an aryl group, an aryloxy group, a heteroaryl group, a heteroaryloxy group, or a derivative thereof, aryl sites of the aryl group and the aryloxy group are each one of a phenyl group, a biphenyl group, a naphthyl group, a naphthyl phenyl group, a phenyl naphthyl group, a tolyl group, a xylyl group, a terphenyl group, and a phenanthryl group that are unsubstituted or substituted by one of an alkyl group, a halogen atom, and a trifluoromethyl group; and heteroaryl sites of the heteroaryl group and the heteroaryloxy group are each one of a thienyl group, a thiazolyl group, an isothiazolyl group, a furanyl group, an oxazolyl group, an oxadiazolyl group, an isoxazolyl group, a benzothienyl group, a benzofuranyl group, a pyridinyl group, a quinolinyl group, an isoquinolyl group, an acridinyl group, an indole group, an imidazole group, a benzimidazol group, a carbazolyl group, a dibenzofuranyl group, and a dibenzothiophenyl group that are unsubstituted or substituted by one of an alkyl group, a halogen atom, and a trifluoromethyl group.)
[3]
   The semiconductor element according to [2], in which the benzodithiophene derivative represented by the general formula (1) and the naphthodithiophene derivative represented by the general formula (2) each have a broad peak with a half width of greater than 1° in a case where an organic film formed using powder thereof by a vacuum deposition method is subjected to X-ray diffraction measurement with use of CuKα radiation.
[4]
   The semiconductor element according to [2] or [3], in which the benzodithiophene derivative includes a compound represented by the following formula (1-1).

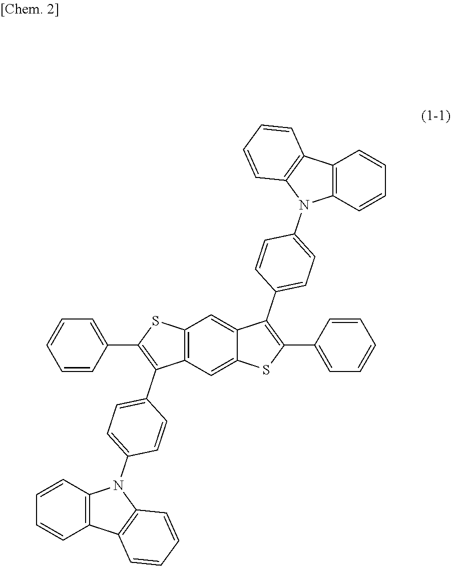 [SMILES: c1ccc(-c2sc3cc4c(-c5ccc(-n6c7ccccc7c7ccccc76)cc5)c(-c5ccccc5)sc4cc3c2-c2ccc(-n3c4ccccc4c4ccccc43)cc2)cc1]

[5]
   The semiconductor element according to [2] or [3], in which the naphthodithiophene derivative includes a compound represented by the following formula (2-1).

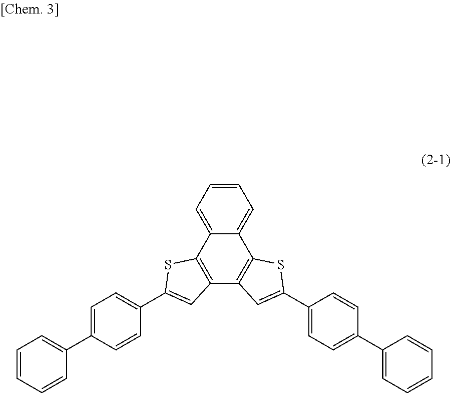 [SMILES: c1ccc(-c2ccc(-c3cc4c5cc(-c6ccc(-c7ccccc7)cc6)sc5c5ccccc5c4s3)cc2)cc1]

[6]
   The semiconductor element according to [2] or [3], in which the organic semiconductor layer includes a single material of the benzodithiophene derivative represented by the general formula (1) or the naphthodithiophene derivative represented by the general formula (2).
[7]
   The semiconductor element according to any one of [1] to [6], in which the organic semiconductor layer is formed using a single material of a benzodithiophene derivative represented by the following formula (1-1) or a naphthodithiophene derivative represented by the following formula (2-1).

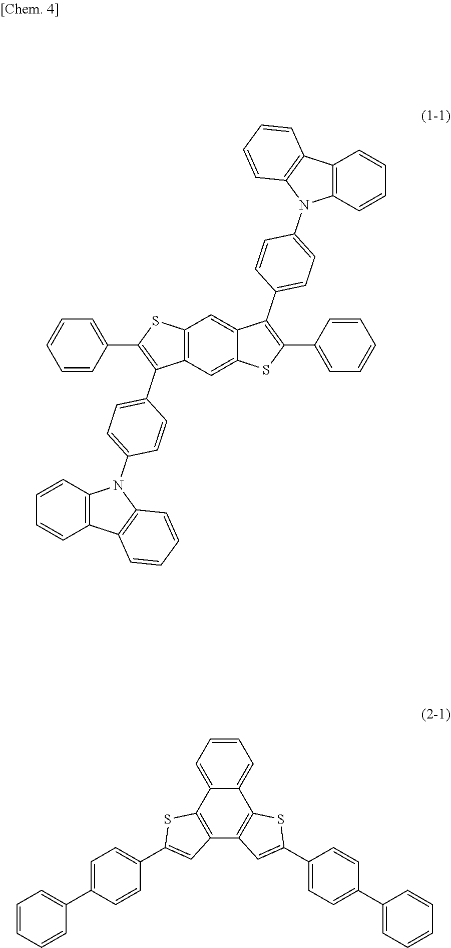 [SMILES: c1ccc(-c2sc3cc4c(-c5ccc(-n6c7ccccc7c7ccccc76)cc5)c(-c5ccccc5)sc4cc3c2-c2ccc(-n3c4ccccc4c4ccccc43)cc2)cc1 ; c1ccc(-c2ccc(-c3cc4c5cc(-c6ccc(-c7ccccc7)cc6)sc5c5ccccc5c4s3)cc2)cc1]

[8]
   The semiconductor element according to any one of [2] to [7], in which the benzodithiophene derivative represented by the general formula (1) and the naphthodithiophene derivative represented by the general formula (2) each have a Highest Occupied Molecular Orbital level of 6.0±0.5 eV.
[9]
   The semiconductor element according to any one of [1] to [8], in which the organic semiconductor layer includes a light-emitting layer.
[10]
   The semiconductor element according to any one of [2] to [9], in which the organic semiconductor layer includes a light-emitting layer, and includes the benzodithiophene derivative represented by the general formula (1) or the naphthodithiophene derivative represented by the general formula (2).
[11]
   The semiconductor element according to any one of [1] to [8], in which the organic semiconductor layer includes a carrier transport layer or a carrier blocking layer.
[12]
   The semiconductor element according to any one of [7] to [11], in which the organic semiconductor layer includes a carrier transport layer or a carrier blocking layer, and includes a compound represented by the formula (1-1) or a compound represented by the formula (2-1).
[13]
   The semiconductor element according to any one of [1] to [12], in which the organic semiconductor material has a broad peak with a half width of greater than 1° in a case where an organic film formed by a vacuum deposition method is subjected to X-ray diffraction measurement with use of CuKα radiation.
[14]
   The semiconductor element according to any one of [1] to [13], further including a work function adjustment layer or a hole injection layer, and a photoelectric conversion layer or a light-emitting layer between the first electrode and the second electrode, in which
   the work function adjustment layer and the hole injection layer have electron affinity or a work function larger than work functions of the first electrode and the second electrode, and
   the organic semiconductor layer, the work function adjustment layer or the hole injection layer, and the photoelectric conversion layer or the light-emitting layer are stacked in order of the photoelectric conversion layer or the light-emitting layer, the organic semiconductor layer, and the work function adjustment layer or the hole injection layer from side of the first electrode.
[15]
   The semiconductor element according to [14], in which the organic semiconductor layer has a film density of 1.20 g/cm³ or more.
[16]
   The semiconductor element according to [14] or [15], in which a difference between a Highest Occupied Molecular Orbital level of a material included in the photoelectric conversion layer and a Highest Occupied Molecular Orbital level of a material included in the organic semiconductor layer is within a range of ±0.4 eV.
[17]
   The semiconductor element according to any one of [14] to [16], in which the first electrode, the photoelectric conversion layer, the organic semiconductor layer, the work function adjustment layer, and the second electrode are stacked in this order.
[18]
   The semiconductor element according to [1], in which the organic semiconductor material includes at least one of an anthracene derivative represented by the following general formula (3) or a pyrene derivative represented by the following general formula (4).

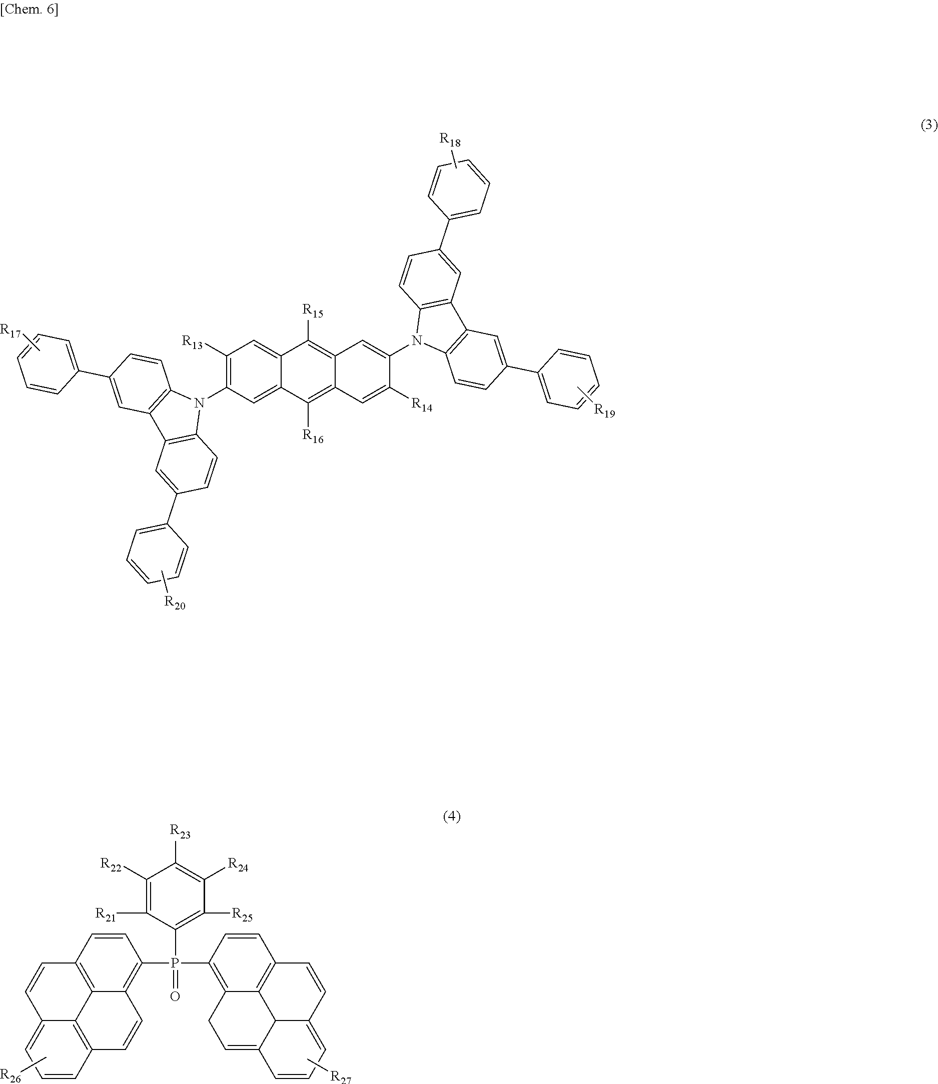

(R13 to R20 are each independently a hydrogen atom, a halogen atom, a straight-chain or branched alkyl group, a straight-chain or branched alkoxy group, an aryl group, an aryloxy group, a heteroaryl group, a heteroaryloxy group, or a derivative thereof, aryl sites of the aryl group and the aryloxy group are each one of a phenyl group, a biphenyl group, a naphthyl group, a naphthyl phenyl group, a phenyl naphthyl group, a tolyl group, a xylyl group, a terphenyl group, and a phenanthryl group that are unsubstituted or substituted by one of an alkyl group, a halogen atom, and a trifluoromethyl group; heteroaryl sites of the heteroaryl group and the heteroaryloxy group are each one of a thienyl group, a thiazolyl group, an isothiazolyl group, a furanyl group, an oxazolyl group, an oxadiazolyl group, an isoxazolyl group, a benzothienyl group, a benzofuranyl group, a pyridinyl group, a quinolinyl group, an isoquinolyl group, an acridinyl group, an indole group, an imidazole group, a benzimidazol group, a carbazolyl group, a dibenzofuranyl group, and a dibenzothiophenyl group that are unsubstituted or substituted by one of an alkyl group, a halogen atom, and a trifluoromethyl group; R21 to R27 are each independently a hydrogen atom, a halogen atom, a straight-chain or branched alkyl group, a straight-chain or branched alkoxy group, an aryl group, an aryloxy group, a heteroaryl group, a heteroaryloxy group, or a derivative thereof; aryl sites of the aryl group and the aryloxy group are each one of a phenyl group, a biphenyl group, a naphthyl group, a naphthyl phenyl group, a phenyl naphthyl group, a tolyl group, a xylyl group, a terphenyl group, and a phenanthryl group that are unsubstituted or substituted by one of an alkyl group, a halogen atom, and a trifluoromethyl group; and heteroaryl sites of the heteroaryl group and the heteroaryloxy group are each one of a thienyl group, a thiazolyl group, an isothiazolyl group, a furanyl group, an oxazolyl group, an oxadiazolyl group, an isoxazolyl group, a benzothienyl group, a benzofuranyl group, a pyridinyl group, a quinolinyl group, an isoquinolyl group, an acridinyl group, an indole group, an imidazole group, a benzimidazol group, a carbazolyl group, a dibenzofuranyl group, and a dibenzothiophenyl group that are unsubstituted or substituted by one of an alkyl group, a halogen atom, and a trifluoromethyl group.)
[19]
   A semiconductor device provided with one or a plurality of semiconductor elements, the semiconductor elements each including:
   a first electrode;
   a second electrode disposed to be opposed the first electrode; and
   an organic semiconductor layer that is provided between the first electrode and the second electrode, and including an organic semiconductor material, the organic semiconductor material having a crystal density of greater than 1.26 g/cm³ and less than 1.50 g/cm³ in powder form by X-ray structure analysis, and a molecular weight of 1200 or less, and being available for vacuum deposition film formation.
[20]
   The semiconductor device according to [18], in which the one or plurality of semiconductor elements includes at least one of a light-emitting element or a photoelectric conversion element.
[21]
   A semiconductor element including:
   a first electrode;
   a second electrode disposed to be opposed the first electrode; and
   an organic semiconductor layer that is provided between the first electrode and the second electrode, and includes at least one of a benzodithiophene derivative represented by the following general formula (1) or a naphthodithiophene derivative represented by the following general formula (2).

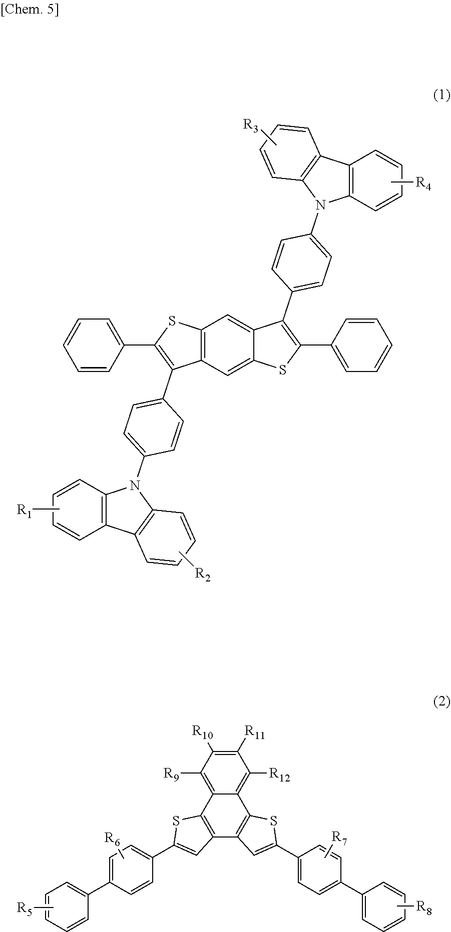

(R1 to R12 are each independently a hydrogen atom, a halogen atom, a straight-chain or branched alkyl group, a straight-chain or branched alkoxy group, an aryl group, an aryloxy group, a heteroaryl group, a heteroaryloxy group, or a derivative thereof, aryl sites of the aryl group and the aryloxy group are each one of a phenyl group, a biphenyl group, a naphthyl group, a naphthyl phenyl group, a phenyl naphthyl group, a tolyl group, a xylyl group, a terphenyl group, and a phenanthryl group that are unsubstituted or substituted by one of an alkyl group, a halogen atom, and a trifluoromethyl group; and heteroaryl sites of the heteroaryl group and the heteroaryloxy group are each one of a thienyl group, a thiazolyl group, an isothiazolyl group, a furanyl group, an oxazolyl group, an oxadiazolyl group, an isoxazolyl group, a benzothienyl group, a benzofuranyl group, a pyridinyl group, a quinolinyl group, an isoquinolyl group, an acridinyl group, an indole group, an imidazole group, a benzimidazol group, a carbazolyl group, a dibenzofuranyl group, and a dibenzothiophenyl group that are unsubstituted or substituted by one of an alkyl group, a halogen atom, and a trifluoromethyl group.)

This application claims the priority on the basis of Japanese Patent Application No. 2021-109551 filed on Jun. 30, 2021 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A semiconductor element comprising:
a first electrode;
a second electrode disposed to be opposed the first electrode; and
an organic semiconductor layer that is provided between the first electrode and the second electrode, and including an organic semiconductor material, the organic semiconductor material having a crystal density of greater than 1.26 g/cm³ and less than 1.50 g/cm³ in powder form by X-ray structure analysis, and a molecular weight of 1200 or less, and being available for vacuum deposition film formation.

2. The semiconductor element according to claim 1, wherein the organic semiconductor material includes at least one of a benzodithiophene derivative represented by the following general formula (1) or a naphthodithiophene derivative represented by the following general formula (2). 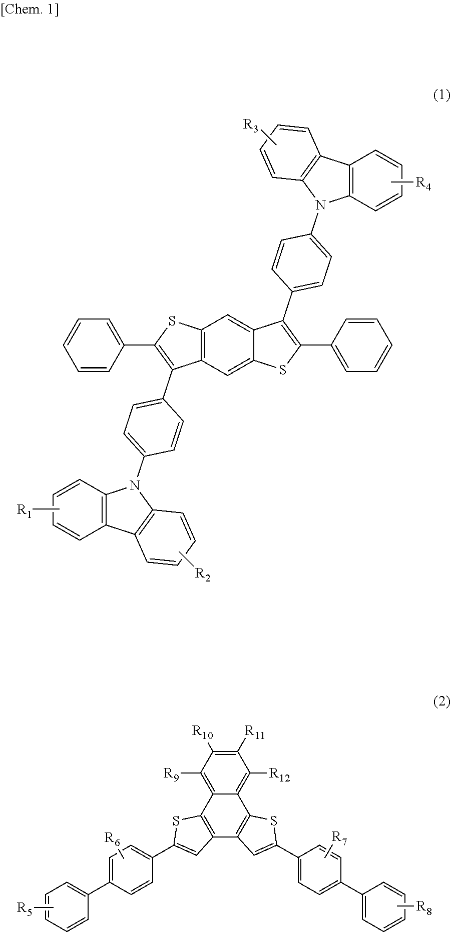
R1 to R12 are each independently a hydrogen atom, a halogen atom, a straight-chain or branched alkyl group, a straight-chain or branched alkoxy group, an aryl group, an aryloxy group, a heteroaryl group, a heteroaryloxy group, or a derivative thereof, aryl sites of the aryl group and the aryloxy group are each one of a phenyl group, a biphenyl group, a naphthyl group, a naphthyl phenyl group, a phenyl naphthyl group, a tolyl group, a xylyl group, a terphenyl group, and a phenanthryl group that are unsubstituted or substituted by one of an alkyl group, a halogen atom, and a trifluoromethyl group; and heteroaryl sites of the heteroaryl group and the heteroaryloxy group are each one of a thienyl group, a thiazolyl group, an isothiazolyl group, a furanyl group, an oxazolyl group, an oxadiazolyl group, an isoxazolyl group, a benzothienyl group, a benzofuranyl group, a pyridinyl group, a quinolinyl group, an isoquinolyl group, an acridinyl group, an indole group, an imidazole group, a benzimidazol group, a carbazolyl group, a dibenzofuranyl group, and a dibenzothiophenyl group that are unsubstituted or substituted by one of an alkyl group, a halogen atom, and a trifluoromethyl group.)

3. The semiconductor element according to claim 2, wherein the benzodithiophene derivative represented by the general formula (1) and the naphthodithiophene derivative represented by the general formula (2) each have a broad peak with a half width of greater than 1° in a case where an organic film formed using powder thereof by a vacuum deposition method is subjected to X-ray diffraction measurement with use of CuKα radiation.

4. The semiconductor element according to claim 2, wherein the benzodithiophene derivative comprises a compound represented by the following formula (1-1).

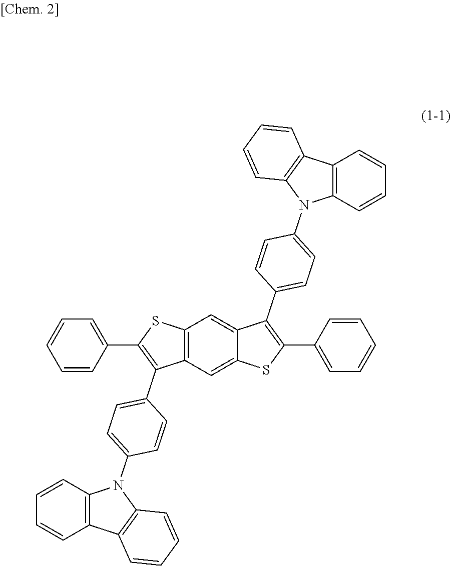 [SMILES: c1ccc(-c2sc3cc4c(-c5ccc(-n6c7ccccc7c7ccccc76)cc5)c(-c5ccccc5)sc4cc3c2-c2ccc(-n3c4ccccc4c4ccccc43)cc2)cc1]

5. The semiconductor element according to claim 2, wherein the naphthodithiophene derivative comprises a compound represented by the following formula (2-1).

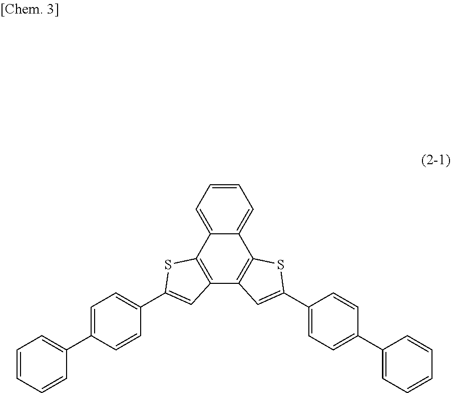 [SMILES: c1ccc(-c2ccc(-c3cc4c5cc(-c6ccc(-c7ccccc7)cc6)sc5c5ccccc5c4s3)cc2)cc1]

6. The semiconductor element according to claim 2, wherein the organic semiconductor layer includes a single material of the benzodithiophene derivative represented by the general formula (1) or the naphthodithiophene derivative represented by the general formula (2).

7. The semiconductor element according to claim 1, wherein the organic semiconductor layer is formed using a single material of a benzodithiophene derivative represented by the following formula (1-1) or a naphthodithiophene derivative represented by the following formula (2-1).

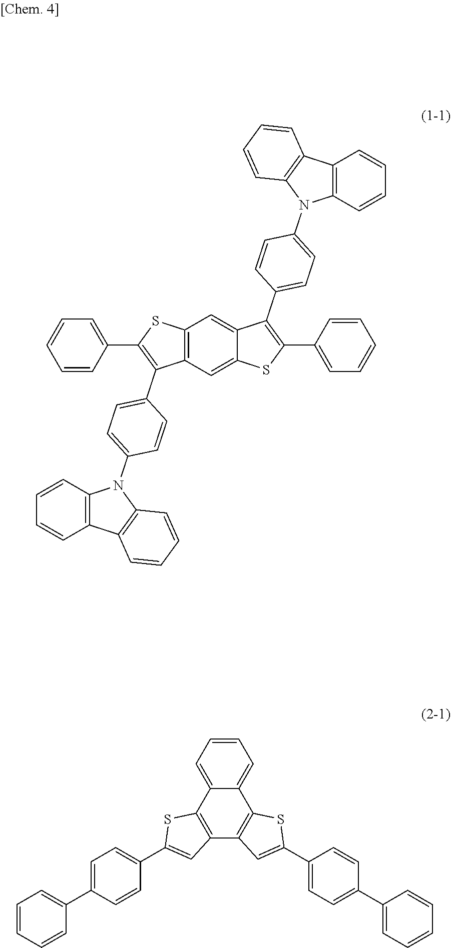 [SMILES: c1ccc(-c2sc3cc4c(-c5ccc(-n6c7ccccc7c7ccccc76)cc5)c(-c5ccccc5)sc4cc3c2-c2ccc(-n3c4ccccc4c4ccccc43)cc2)cc1 ; c1ccc(-c2ccc(-c3cc4c5cc(-c6ccc(-c7ccccc7)cc6)sc5c5ccccc5c4s3)cc2)cc1]

8. The semiconductor element according to claim 2, wherein the benzodithiophene derivative represented by the general formula (1) and the naphthodithiophene derivative represented by the general formula (2) each have a Highest Occupied Molecular Orbital level of 6.0±0.5 eV.

9. The semiconductor element according to claim 1, wherein the organic semiconductor layer comprises a light-emitting layer.

10. The semiconductor element according to claim 2, wherein the organic semiconductor layer comprises a light-emitting layer, and includes the benzodithiophene derivative represented by the general formula (1) or the naphthodithiophene derivative represented by the general formula (2).

11. The semiconductor element according to claim 1, wherein the organic semiconductor layer comprises a carrier transport layer or a carrier blocking layer.

12. The semiconductor element according to claim 7, wherein the organic semiconductor layer comprises a carrier transport layer or a carrier blocking layer, and includes a compound represented by the formula (1-1) or a compound represented by the formula (2-1).

13. The semiconductor element according to claim 1, wherein the organic semiconductor material has a broad peak with a half width of greater than 1° in a case where an organic film formed by a vacuum deposition method is subjected to X-ray diffraction measurement with use of CuKα radiation.

14. The semiconductor element according to claim 1, further comprising a work function adjustment layer or a hole injection layer, and a photoelectric conversion layer or a light-emitting layer between the first electrode and the second electrode, wherein
the work function adjustment layer and the hole injection layer have electron affinity or a work function larger than work functions of the first electrode and the second electrode, and
the organic semiconductor layer, the work function adjustment layer or the hole injection layer, and the photoelectric conversion layer or the light-emitting layer are stacked in order of the photoelectric conversion layer or the light-emitting layer, the organic semiconductor layer, and the work function adjustment layer or the hole injection layer from side of the first electrode.

15. The semiconductor element according to claim 14, wherein the organic semiconductor layer has a film density of 1.20 g/cm³ or more.

16. The semiconductor element according to claim 14, wherein a difference between a Highest Occupied Molecular Orbital level of a material included in the photoelectric conversion layer and a Highest Occupied Molecular Orbital level of a material included in the organic semiconductor layer is within a range of ±0.4 eV.

17. The semiconductor element according to claim 14, wherein the first electrode, the photoelectric conversion layer, the organic semiconductor layer, the work function adjustment layer, and the second electrode are stacked in this order.

18. A semiconductor device provided with one or a plurality of semiconductor elements, the semiconductor elements each comprising:
a first electrode;
a second electrode disposed to be opposed the first electrode; and
an organic semiconductor layer that is provided between the first electrode and the second electrode, and including an organic semiconductor material, the organic semiconductor material having a crystal density of greater than 1.26 g/cm³ and less than 1.50 g/cm³ in powder form by X-ray structure analysis, and a molecular weight of 1200 or less, and being available for vacuum deposition film formation.

19. The semiconductor device according to claim 18, wherein the one or plurality of semiconductor elements includes at least one of a light-emitting element or a photoelectric conversion element.

20. A semiconductor element comprising:
a first electrode;
a second electrode disposed to be opposed the first electrode; and
an organic semiconductor layer that is provided between the first electrode and the second electrode, and includes at least one of a benzodithiophene derivative represented by the following general formula (1) or a naphthodithiophene derivative represented by the following general formula (2). 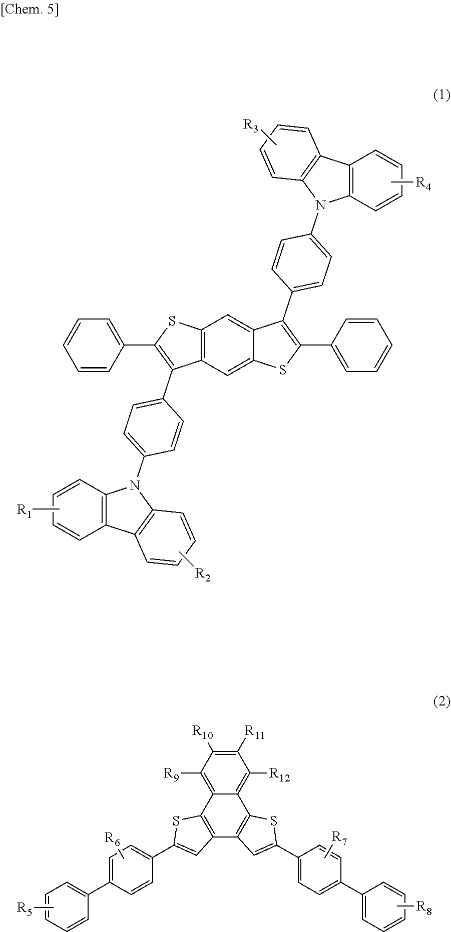
(R1 to R12 are each independently a hydrogen atom, a halogen atom, a straight-chain or branched alkyl group, a straight-chain or branched alkoxy group, an aryl group, an aryloxy group, a heteroaryl group, a heteroaryloxy group, or a derivative thereof, aryl sites of the aryl group and the aryloxy group are each one of a phenyl group, a biphenyl group, a naphthyl group, a naphthyl phenyl group, a phenyl naphthyl group, a tolyl group, a xylyl group, a terphenyl group, and a phenanthryl group that are unsubstituted or substituted by one of an alkyl group, a halogen atom, and a trifluoromethyl group; and heteroaryl sites of the heteroaryl group and the heteroaryloxy group are each one of a thienyl group, a thiazolyl group, an isothiazolyl group, a furanyl group, an oxazolyl group, an oxadiazolyl group, an isoxazolyl group, a benzothienyl group, a benzofuranyl group, a pyridinyl group, a quinolinyl group, an isoquinolyl group, an acridinyl group, an indole group, an imidazole group, a benzimidazol group, a carbazolyl group, a dibenzofuranyl group, and a dibenzothiophenyl group that are unsubstituted or substituted by one of an alkyl group, a halogen atom, and a trifluoromethyl group.)
